(19) United States
(12) Patent Application Publication
(10) Pub. No.: US 2019/0157570 A1
(43) Pub. Date: May 23, 2019

(54) COMPOSITION, THIN FILM INCLUDING THE COMPOSITION, AND ORGANIC LIGHT-EMITTING DEVICE INCLUDING THE THIN FILM

(71) Applicant: Samsung Electronics Co., Ltd., Suwon-si (KR)

(72) Inventors: Myungsun SIM, Suwon-si (KR); Sooghang IHN, Hwaseong-si (KR); Jongsoo KIM, Seoul (KR); Joonghyuk KIM, Seoul (KR); Hiroshi MIYAZAKI, Hwaseong-si (KR); Hasup LEE, Seoul (KR); Soonok JEON, Suwon-si (KR); Yeonsook CHUNG, SEOUL (KR)

(21) Appl. No.: 16/197,787

(22) Filed: Nov. 21, 2018

(30) Foreign Application Priority Data
Nov. 22, 2017 (KR) 10-2017-0156612
Nov. 14, 2018 (KR) 10-2018-0140098

(51) Int. Cl. H01L 51/00; C09K 11/06

(52) U.S. Cl. CPC H01L 51/0072; H01L 51/5016; C09K 11/06; H01L 51/0067

(57) ABSTRACT

A composition including a first compound represented by Formula 1, a second compound represented by Formula 2, and a third compound satisfying a specified condition:

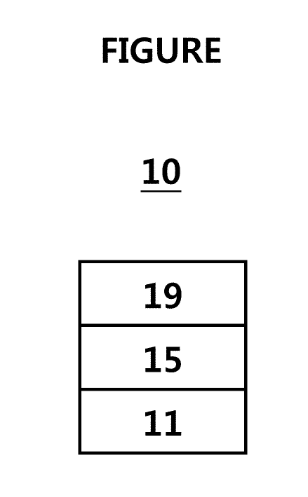

A₁₁-L₁₁-A₁₂ Formula 1

A₂₁-(L₂₁)ₐ₂₁-A₂₂ Formula 2

wherein, in Formulae 1 and 2, A₁₁, A₁₂, A₂₁, A₂₂, L₁₁, L₂₁, and a21 are the same as described in the specification.

### CROSS-REFERENCE TO RELATED APPLICATION

This application claims priority to Korean Patent Application No. 10-2017-0156612, filed on Nov. 22, 2017, and Korean Patent Application No. 10-2018-0140098, filed on Nov. 14, 2018, in the Korean Intellectual Property Office, and all the benefits accruing therefrom under 35 U.S.C. § 119, the content of which is incorporated herein in its entirety by reference.

### BACKGROUND

### 1. Field

One or more embodiments relate to a composition, a thin film including the composition, and an organic light-emitting device including the thin film.

### 2. Description of the Related Art

Organic light-emitting devices (OLEDs) are self-emission devices that produce full-color images, and that also have wide viewing angles, high contrast ratios, short response times, and excellent characteristics in terms of brightness, driving voltage, and response speed, compared to devices in the art.

In an example, an organic light-emitting device includes an anode, a cathode, and an organic layer disposed between the anode and the cathode, wherein the organic layer includes an emission layer. A hole transport region may be disposed between the anode and the emission layer, and an electron transport region may be disposed between the emission layer and the cathode. Holes provided from the anode may move toward the emission layer through the hole transport region, and electrons provided from the cathode may move toward the emission layer through the electron transport region. The holes and the electrons recombine in the emission layer to produce excitons. These excitons transit from an excited state to a ground state, thereby generating light.

Various types of organic light emitting devices are known. However, there still remains a need in OLEDs having low driving voltage, high efficiency, high brightness, and long lifespan.

### SUMMARY

Aspects of the present disclosure provide a composition including a predetermined first compound, a predetermined second compound, and a predetermined third compound, a thin film including the composition, and an organic light-emitting device including the thin film.

Additional aspects will be set forth in part in the description which follows and, in part, will be apparent from the description, or may be learned by practice of the presented embodiments.

An aspect of the present description provides a composition including:

a first compound represented by Formula 1;

a second compound represented by Formula 2;

a third compound satisfying Condition 1, and

the second compound is different from the first compound:

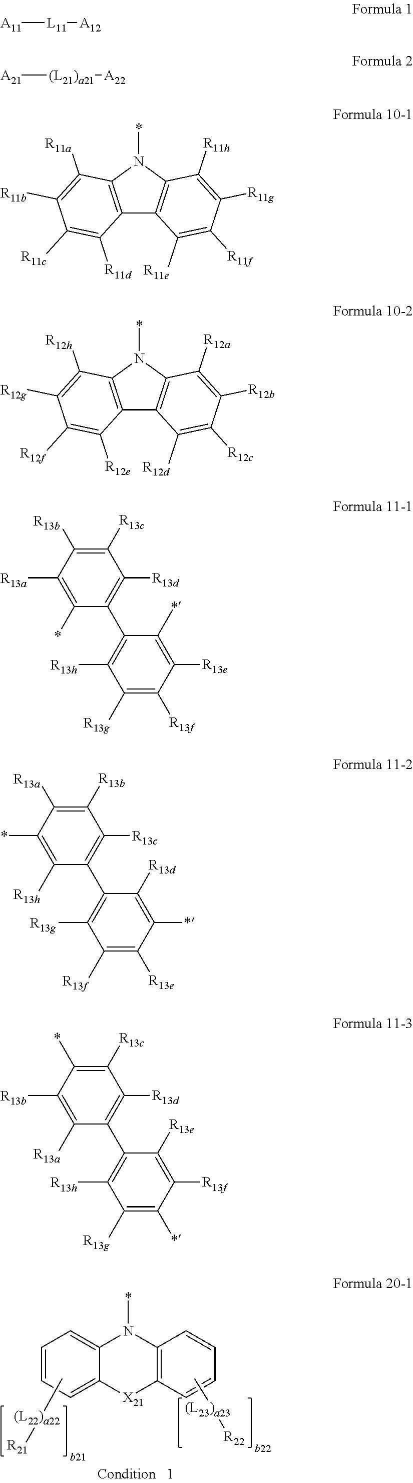

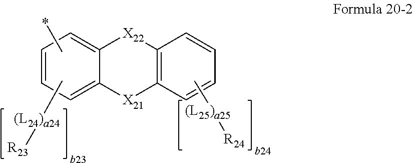

0 electron volts ≤E_{S1}(C3)-E_{T1}(C3)≤0.3 electron volts.

In Condition 1,

E_{S1}(C3) is a lowest excitation singlet energy level of the third compound,

E_{T1}(C3) is a lowest excitation triplet energy level of the third compound, and

E_{S1}(C3) and E_{T1}(C3) are evaluated by using a DFT method structurally optimized at a level of B3LYP/6-31G(d,p).

In Formulae 1 and 2,

A₁₁ may be a group represented by Formula 10-1,

A₁₂ may be a group represented by Formula 10-2,

L₁₁ may be a group represented by one selected from Formulae 11-1 to 11-3,

A₂₁ may be a group represented by one selected from Formulae 20-1 and 20-2;

A₂₂ may be selected from groups represented by Formulae 20-1 and 20-2, a phenyl group, a naphthyl group, and a benzimidazolyl group; and

a phenyl group, a naphthyl group, and a benzimidazolyl group, each substituted with at least one selected from deuterium, a hydroxyl group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a carbazolyl group, a dibenzofuranyl group, and a dibenzothiophenyl group,

X₂₁ may be selected from a single bond, C[(L₂₇)ₐ₂₇-R₂₆][(L₂₈)ₐ₂₈-R₂₇], O, and S,

X₂₂ may be selected from N[(L₂₆)ₐ₂₆-R₂₅], C[(L₂₉)ₐ₂₉-R₂₈][(L₃₀)ₐ₃₀-R₂₉], O, and S,

L₂₁ to L₃₀ may each independently be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

a21 to a30 may each independently be selected from 0, 1, 2, 3, 4, and 5,

R₁₁ₐ to R₁₁ₕ, R₁₂ₐ to R₁₂ₕ, R₁₃ₐ to R₁₃ₕ, and R₂₁ to R₂₉ may each independently be selected from hydrogen, deuterium, —F, —Cl, —Br, —I, a hydroxyl group, a cyano group (CN), a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ aryl alkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroaryl alkyl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₁)(Q₂), and —B(Q₁)(Q₂), two or more selected from R₂₁ to R₂₉ are optionally linked to form a ring,

at least one selected from R₁₁ₐ to R₁₁ₕ, R₁₂ₐ to R₁₂ₕ, and R₁₃ₐ to R₁₃ₕ may be a cyano group,

b21, b22, and b24 may each independently be selected from 1, 2, 3, and 4,

b23 may be selected from 1, 2, and 3,

Q₁ to Q₃ may each independently be selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, and a terphenyl group, and

* and *′ each indicate a binding site to a neighboring atom.

Another aspect provides a thin film including the composition.

Another aspect provides an organic light-emitting device including:

a first electrode;

a second electrode; and

an organic layer disposed between the first electrode and the second electrode, wherein the organic layer includes the thin film. The thin film in the organic light-emitting device may be an emission layer.

### BRIEF DESCRIPTION OF THE DRAWING

These and/or other aspects will become apparent and more readily appreciated from the following description of the embodiments, taken in conjunction with the FIGURE which is a schematic view of an organic light-emitting device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on” another element, it can be directly in contact with the other element or intervening elements may be present therebetween. In contrast, when an element is referred to as being “directly on” another element, there are no intervening elements present.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

The terminology used herein is for the purpose of describing particular embodiments only and is not intended to be limiting. As used herein, the singular forms “a,” “an,” and “the” are intended to include the plural forms as well, unless the context clearly indicates otherwise.

The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

A composition may include: a first compound represented by Formula 1; a second compound represented by Formula 2 which is different from the first compound; and a third compound satisfying Condition 1:

A₁₁-L₁₁-A₁₂ Formula 1

A₂₁-(L₂₁)ₐ₂₁-A₂₂ Formula 2

0 eV≤E_{S1}(C3)-E_{T1}(C3)≤0.3 eV. Condition 1

In Condition 1, E_{S1}(C3) is a lowest excitation singlet energy level of the third compound, and E_{T1}(C3) is a lowest excitation triplet energy level of the third compound.

E_{S1}(C3) and E_{T1}(C3) are evaluated by using a DFT method structurally optimized at a level of B3LYP/6-31G(d,p). E_{S1}(C3) and E_{T1}(C3) may be evaluated by using the Gaussian program.

In Formula 1, A₁₁ may be a group represented by Formula 10-1, and A₁₂ may be a group represented by Formula 10-2:

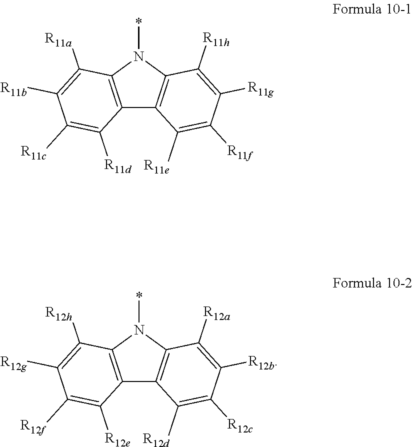

In Formulae 10-1 and 10-2, R₁₁ₐ to R₁₁ₕ and R₁₂ₐ to R₁₂ₕ may each independently be the same as described herein, and * indicates a binding site to a neighboring atom.

In Formula 1, L₁₁ may be a group represented by one selected from Formulae 11-1 to 11-3:

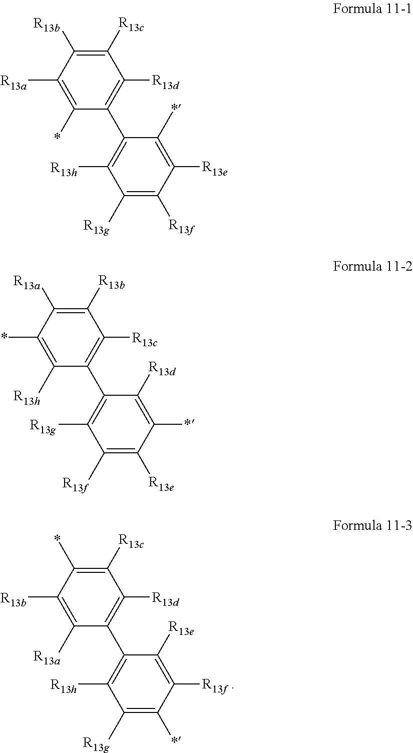

In Formulae 11-1 to 11-3, R₁₃ₐ to R₁₃ₕ may each independently be the same as described herein, and * indicates a binding site to a neighboring atom.

For example, in Formula 1, L₁₁ may be a group represented by Formula 11-1, but embodiments of the present disclosure are not limited thereto.

In Formulae 10-1, 10-2, and 11-1 to 11-3, R₁₁ₐ to R₁₁ₕ, R₁₂ₐ to R₁₂ₕ, and R₁₃ₐ to R₁₃ₕ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted heterocycloalkyl group, a substituted or unsubstituted C₃-C₁₀ cycloalkenyl group, a substituted or unsubstituted heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ aryl alkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroaryl alkyl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₁)(Q₂), and —B(Q₁)(Q₂),

at least one selected from R₁₁ₐ to R₁₁ₕ, R₁₂ₐ to R₁₂ₕ, and R₁₃ₐ to R₁₃ₕ may be a cyano group, and

Q₁ to Q₃ may each independently be selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, and a terphenyl group.

For example, in Formulae 10-1, 10-2, and 11-1 to 11-3, one, two, or three selected from R₁₁ₐ to R₁₁ₕ, R₁₂ₐ to R₁₂ₕ, and R₁₃ₐ to R₁₃ₕ may be a cyano group, but embodiments of the present disclosure are not limited thereto.

In an embodiment, in Formulae 10-1, 10-2, and 11-1 to 11-3, R₁₁ₐ to R₁₁ₕ, R₁₂ₐ to R₁₂ₕ, and R₁₃ₐ to R₁₃ₕ may each independently be selected from:

hydrogen, deuterium, a cyano group, a C₁-C₁₀ alkyl group, and a C₁-C₁₀ alkoxy group;

a C₁-C₁₀ alkyl group and a C₁-C₁₀ alkoxy group, each substituted with at least one selected from deuterium and a cyano group;

a phenyl group, a biphenyl group, a terphenyl group, a naphthyl group, a fluorenyl group, a pyridinyl group, a pyrazinyl group, a pyrimidinyl group, a carbazolyl group, a dibenzofuranyl group, and a dibenzothiophenyl group; and

a phenyl group, a biphenyl group, a terphenyl group, a naphthyl group, a fluorenyl group, a pyridinyl group, a carbazolyl group, a dibenzofuranyl group, and a dibenzothiophenyl group, each substituted with at least one selected from deuterium, a cyano group, a Ci-Cio alkyl group, a Ci-Cio alkoxy group, a phenyl group, a biphenyl group, a terphenyl group, a naphthyl group, a fluorenyl group, a pyridinyl group, a pyrazinyl group, a pyrimidinyl group, a carbazolyl group, a dibenzofuranyl group, and a dibenzothiophenyl group, but embodiments of the present disclosure are not limited thereto.

In an embodiment, in Formulae 10-1, 10-2, and 11-1 to 11-3, R₁₁ₐ to R₁₁ₕ, R₁₂ₐ to R₁₂ₕ, and R₁₃ₐ to R₁₃ₕ may each independently be selected from:

hydrogen, deuterium, a cyano group, a methyl group, an ethyl group, an n-propyl group, an iso-propyl group, an n-butyl group, an iso-butyl group, a sec-butyl group, and a tert-butyl group;

a methyl group, an ethyl group, an n-propyl group, an iso-propyl group, an n-butyl group, an iso-butyl group, a sec-butyl group, and a tert-butyl group, each substituted with at least one selected from deuterium and a cyano group;

a phenyl group, a naphthyl group, a pyridinyl group, a pyrazinyl group, and a pyrimidinyl group; and

a phenyl group, a naphthyl group, a pyridinyl group, a pyrazinyl group, and a pyrimidinyl group, each substituted with at least one selected from deuterium, a cyano group, a methyl group, an ethyl group, an n-propyl group, an iso-propyl group, an n-butyl group, an iso-butyl group, a sec-butyl group, a tert-butyl group, a phenyl group, and a pyridinyl group, but embodiments of the present disclosure are not limited thereto.

In an embodiment, in Formula 1, A₁₁ may be represented by Formula 10-11, A₁₂ may be represented by Formula 10-21, and L₁₁ may be represented by one selected from Formulae 11-15 to 11-22, 11-27 to 11-34, and 11-37 to 11-40;

A₁₁ may be represented by one selected from Formulae 10-12 and 10-13, A₁₂ may be represented by one selected from Formulae 10-21 to 10-23, and L₁₁ may be represented by one selected from Formulae 11-11 to 11-40; or

A₁₁ may be represented by Formula 10-11, A₁₂ may be represented by one selected from Formulae 10-22 and 10-23, and L₁₁ may be represented by one selected from Formulae 11-11 to 11-40, but embodiments of the present disclosure are not limited thereto:

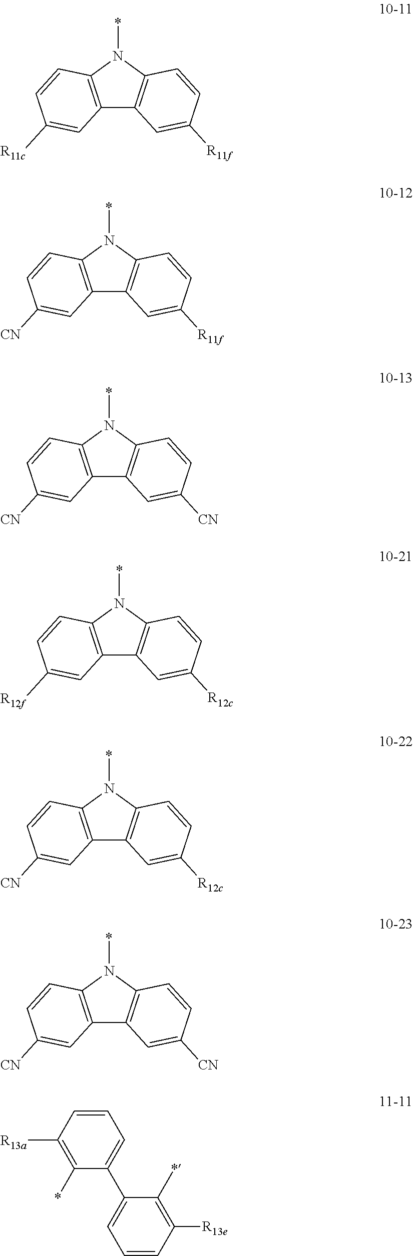

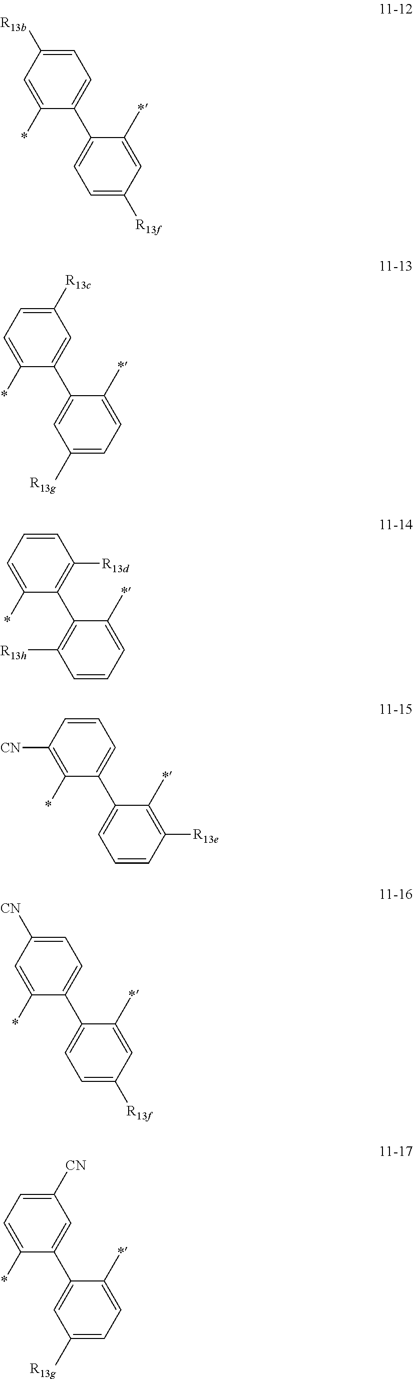

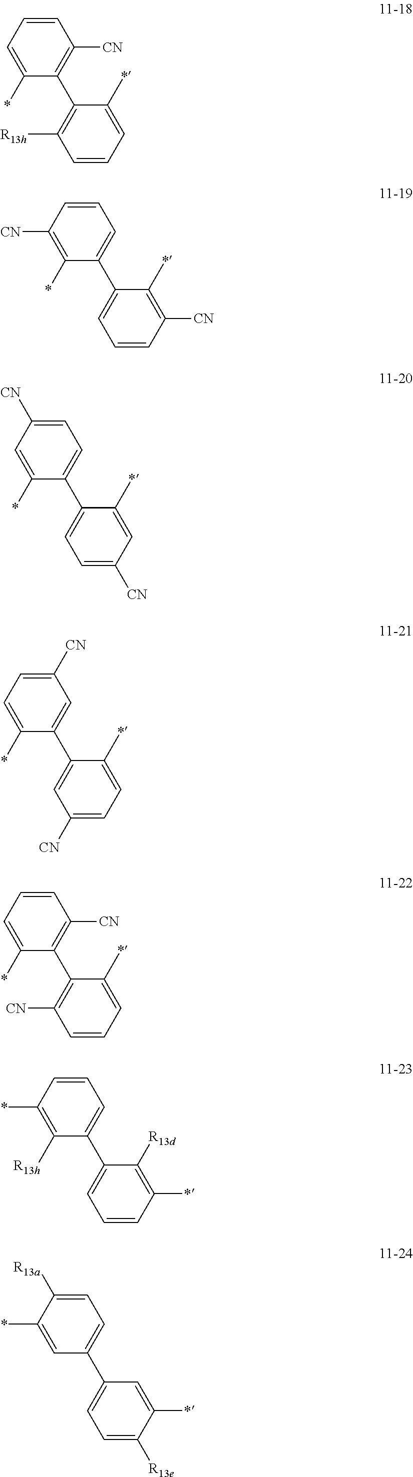

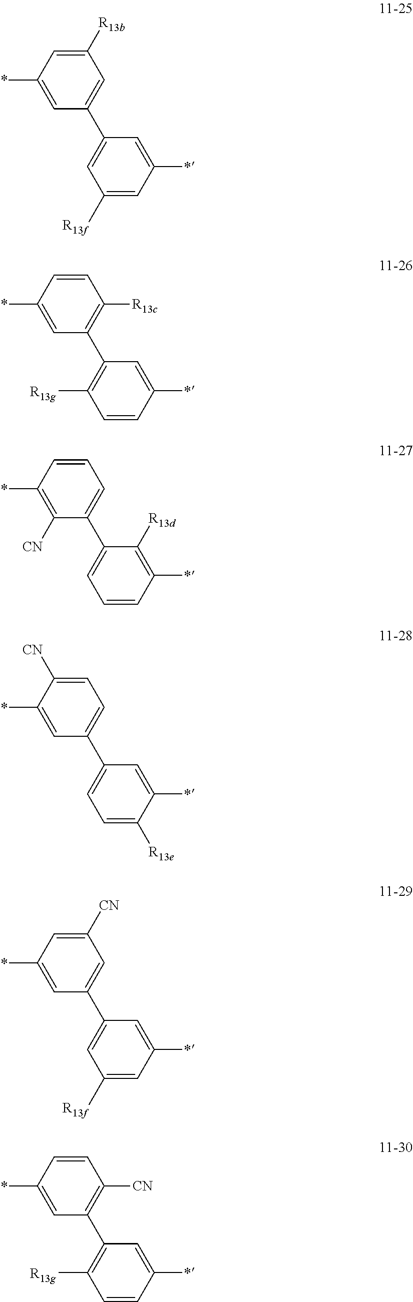

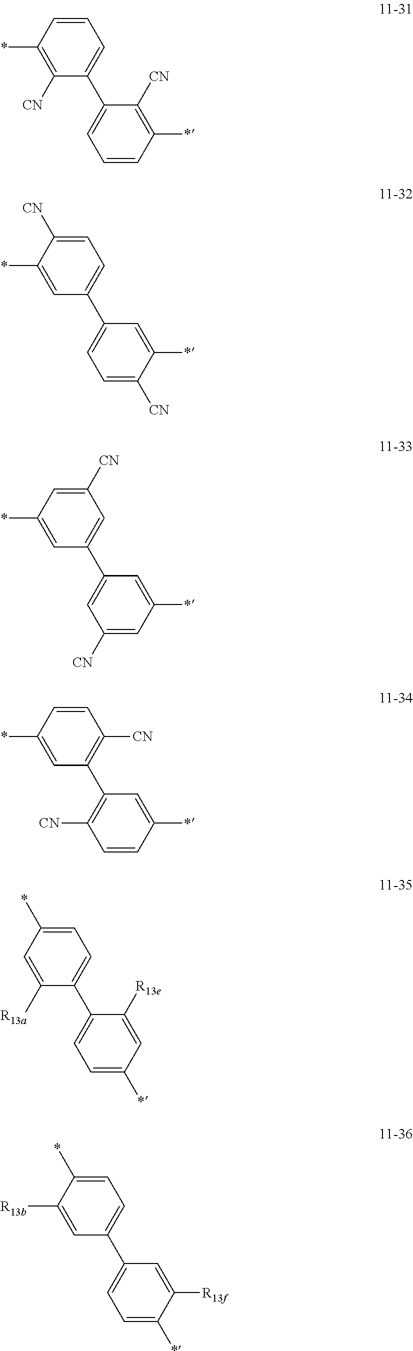

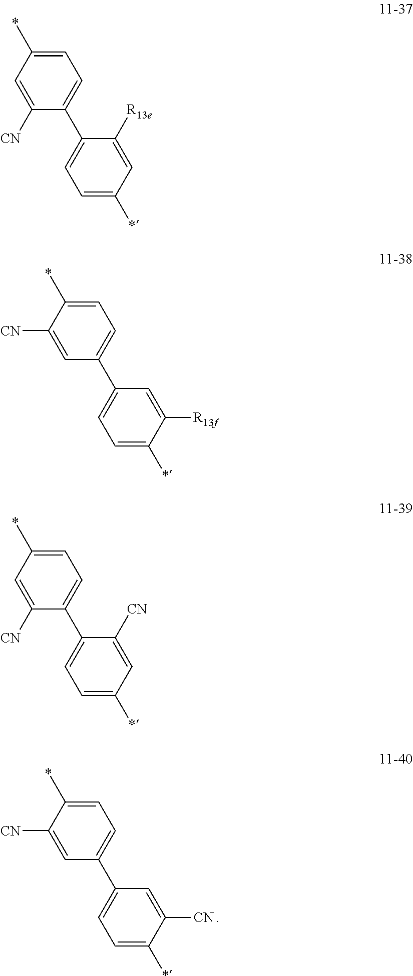

In Formulae 10-11 to 10-13, 10-21 to 10-23, and 11-11 to 11-40,

R_{11c}, R_{11f}, R_{12c}, R_{12f}, and R₁₃ₐ to R_{13f} may each independently be selected from:

hydrogen, deuterium, a C₁-C₁₀ alkyl group, a C₁-C₁₀ alkoxy group, a phenyl group, a biphenyl group, a terphenyl group, a naphthyl group, a fluorenyl group, a pyridinyl group, a pyrazinyl group, a pyrimidinyl group, a carbazolyl group, a dibenzofuranyl group, and a dibenzothiophenyl group;

a C₁-C₁₀ alkyl group and a C₁-C₁₀ alkoxy group, each substituted with deuterium; and

a phenyl group, a biphenyl group, a terphenyl group, a naphthyl group, a fluorenyl group, a pyridinyl group, a pyrazinyl group, a pyrimidinyl group, a carbazolyl group, a dibenzofuranyl group, and a dibenzothiophenyl group, each substituted with at least one selected from deuterium, a C₁-C₁₀ alkyl group, a C₁-C₁₀ alkoxy group, a phenyl group, a biphenyl group, a terphenyl group, a naphthyl group, a fluorenyl group, a pyridinyl group, a pyrazinyl group, a pyrimidinyl group, a carbazolyl group, a dibenzofuranyl group, and a dibenzothiophenyl group, and

* and *′ each indicate a binding site to a neighboring atom.

In one or more embodiments, in Formula 1, A₁₁ may be represented by Formula 10-11, A₁₂ may be represented by Formula 10-21, and L₁₁ may be represented by one selected from Formulae 11-27 to 11-34 and 11-37 to 11-40;

A₁₁ may be represented by one selected from Formula 10-12 and 10-13, A₁₂ may be represented by one selected from Formulae 10-21 to 10-23, and L₁₁ may be represented by one selected from Formulae 11-23 to 11-40; or

A₁₁ may be represented by Formula 10-11, A₁₂ may be represented by one selected from Formulae 10-22 and 10-23, and L₁₁ may be represented by one selected from Formulae 11-23 to 11-40, but embodiments of the present disclosure are not limited thereto.

In one or more embodiments, in Formula 1, A₁₁ may be represented by Formula 10-11, A₁₂ may be represented by Formula 10-21, and L₁₁ may be represented by one selected from Formulae 11-27 to 11-34 and 11-37 to 11-40;

A₁₁ may be represented by one selected from Formulae 10-12 and 10-13, A₁₂ may be represented by one selected from Formulae 10-21 to 10-23, and L₁₁ may be represented by one selected from Formulae 11-23 to 11-40; or

A₁₁ may be represented by Formula 10-11, A₁₂ may be represented by one selected from Formulae 10-22 and 10-23, and L₁₁ may be represented by one selected from Formulae 11-23 to 11-40.

In Formulae 10-11 to 10-13, 10-21 to 10-23, and 11-23 to 11-40, R_{11c}, R_{11f}, R_{12c}, R_{12f}, and R₁₃ₐ to R_{13f} may each independently be selected from:

hydrogen, deuterium, a methyl group, an ethyl group, an n-propyl group, an iso-propyl group, an n-butyl group, an iso-butyl group, a sec-butyl group, a tert-butyl group, a phenyl group, a naphthyl group, a pyridinyl group, a pyrazinyl group, and a pyrimidinyl group;

a methyl group, an ethyl group, an n-propyl group, an iso-propyl group, an n-butyl group, an iso-butyl group, a sec-butyl group, and a tert-butyl group, each substituted with deuterium; and

a phenyl group, a naphthyl group, a pyridinyl group, a pyrazinyl group, and a pyrimidinyl group, each substituted with at least one selected from deuterium, a methyl group, an ethyl group, an n-propyl group, an iso-propyl group, an n-butyl group, an iso-butyl group, a sec-butyl group, a tert-butyl group, a phenyl group, a naphthyl group, a pyridinyl group, a pyrazinyl group, and a pyrimidinyl group, but embodiments of the present disclosure are not limited thereto.

In detail, the first compound may be selected from Compounds E-1 to E-20, but embodiments of the present disclosure are not limited thereto:

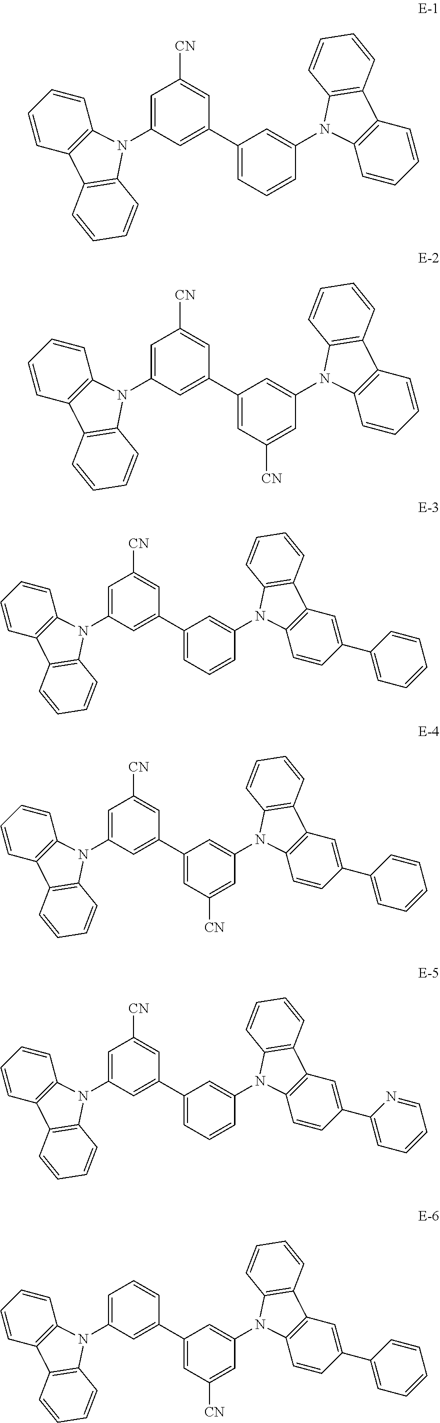 [SMILES: N#Cc1cc(-c2cccc(-n3c4ccccc4c4ccccc43)c2)cc(-n2c3ccccc3c3ccccc32)c1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4cc(-c5ccccc5)ccc43)c2)cc(-n2c3ccccc3c3ccccc32)c1 ; N#Cc1cc(-c2cc(C#N)cc(-n3c4ccccc4c4cc(-c5ccccc5)ccc43)c2)cc(-n2c3ccccc3c3ccccc32)c1 ; N#Cc1cc(-c2cccc(-n3c4ccccc4c4cc(-c5ccccn5)ccc43)c2)cc(-n2c3ccccc3c3ccccc32)c1 ; N#Cc1cc(-c2cccc(-n3c4ccccc4c4ccccc43)c2)cc(-n2c3ccccc3c3cc(-c4ccccc4)ccc32)c1]

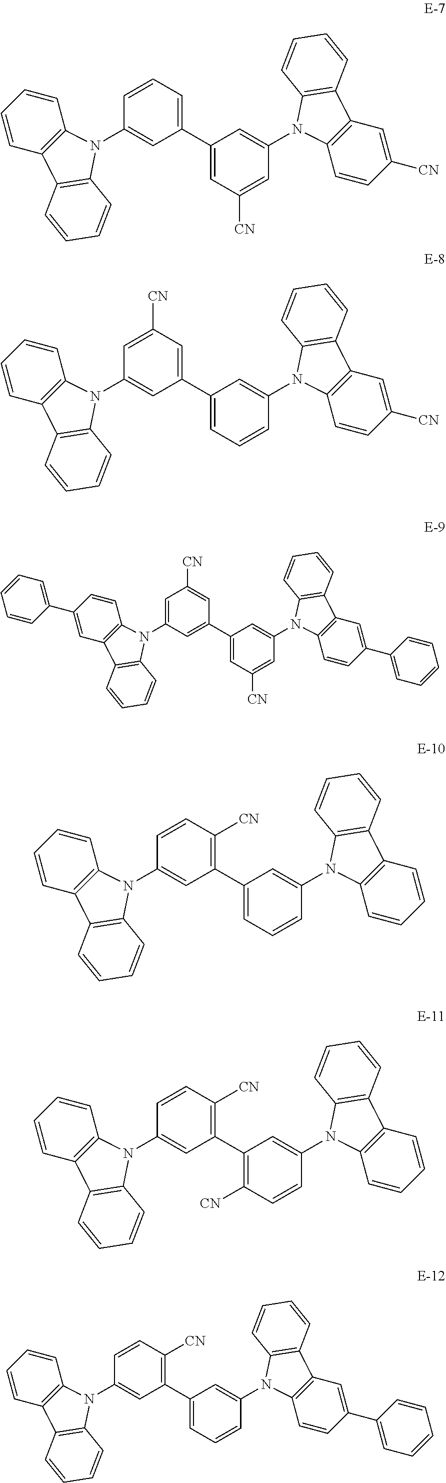

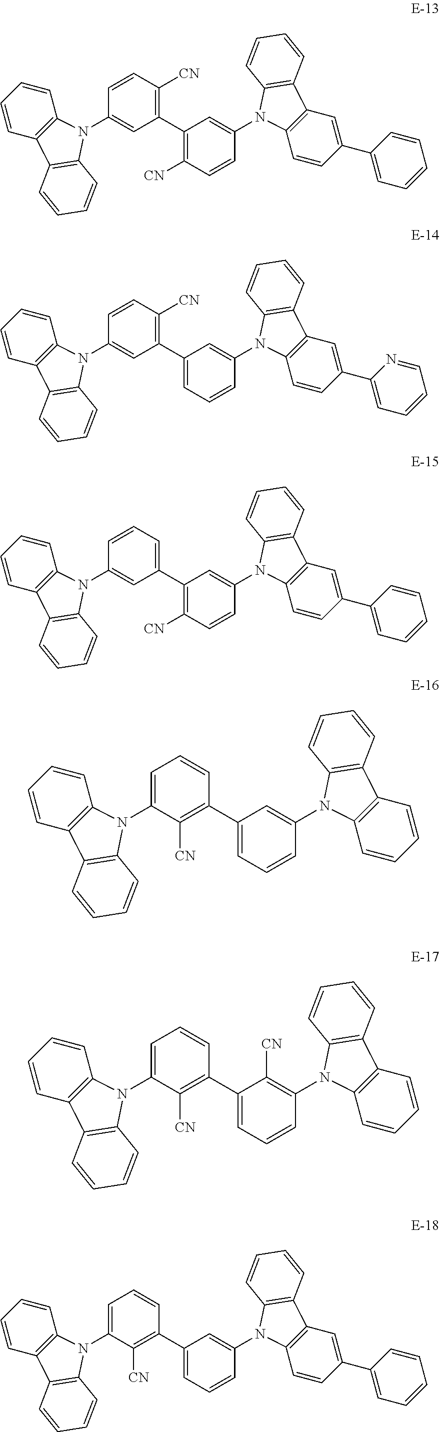

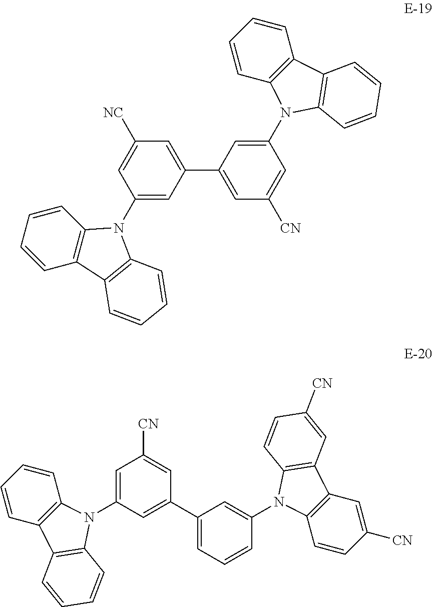 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccc(C#N)cc4c4cc(C#N)ccc43)c2)cc(-n2c3ccccc3c3ccccc32)c1]

In Formula 2, A₂₁ may be a group represented by one selected from Formulae 20-1 and 20-2;

A₂₂ may be selected from groups represented by Formulae 20-1 and 20-2, a phenyl group, a naphthyl group, and a benzimidazolyl group; and

a phenyl group, a naphthyl group, and a benzimidazolyl group, each substituted with at least one selected from deuterium, a hydroxyl group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a carbazolyl group, a dibenzofuranyl group, and a dibenzothiophenyl group:

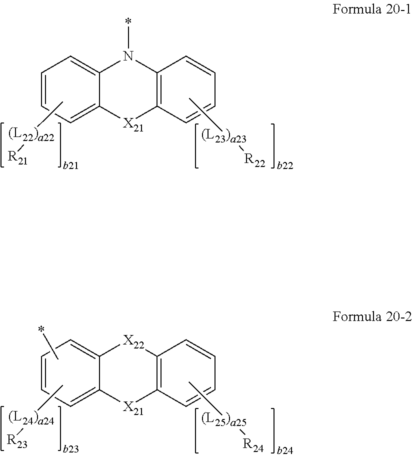

In Formulae 20-1 and 20-2, X₂₁ may be selected from a single bond, C[(L₂₇)ₐ₂₇-R₂₆][(L₂₈)ₐ₂₈-R₂₇], O, and S; X₂₂ may be selected from N[(L₂₆)ₐ₂₆-R₂₅], C[(L₂₉)ₐ₂₉-R₂₈][(L₃₀)ₐ₃₀-R₂₉], O, and S; L₂₂ to L₃₀, a22 to a30, R₂₁ to R₂₉, and b21 to b24 may each independently be the same as defined above; and * indicates a binding site to a neighboring atom.

For example, in Formulae 20-1 and 20-2, X₂₁ may be a single bond; and X₂₂ may be selected from N(R₂₅), C(R₂₈)(R₂₉), O, and S, but embodiments of the present disclosure are not limited thereto.

In Formulae 2, 20-1, and 20-2, L₂₂ to L₃₀ may each independently be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group.

For example, in Formulae 2, 20-1, and 20-2, L₂₁ to L₃₀ may each independently be selected from:

a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a divalent non-aromatic condensed polycyclic group, and a divalent non-aromatic condensed heteropolycyclic group; and

a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a divalent non-aromatic condensed polycyclic group, and a divalent non-aromatic condensed heteropolycyclic group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a biphenyl group, a terphenyl group, a C₁-C₆₀ heteroaryl group, a monovalent non-aromatic condensed polycyclic group, a monovalent non-aromatic condensed heteropolycyclic group, and —Si(Q₃₁)(Q₃₂)(Q₃₃), and

Q₃₁ to Q₃₃ may each independently be selected from hydrogen, a C₁-C₁₀ alkyl group, a C₆-C₃₀ aryl group, a biphenyl group, a terphenyl group, a C₁-C₃₀ heteroaryl group, a monovalent non-aromatic condensed polycyclic group, and a monovalent non-aromatic condensed heteropolycyclic group, but embodiments of the present disclosure are not limited thereto.

In an embodiment, in Formulae 2, 20-1, and 20-2, L₂₁ to L₃₀ may each independently be selected from:

a phenylene group, a naphthylene group, a pyridinylene group, a pyrazinylene group, a pyrimidinylene group, a quinolinylene group, an isoquinolinylene group, a fluorenylene group, a carbazolylene group, a dibenzofuranylene group, and a dibenzothiophenylene group; and

a phenylene group, a naphthylene group, a pyridinylene group, a pyrazinylene group, a pyrimidinylene group, a quinolinylene group, an isoquinolinylene group, a fluorenylene group, a carbazolylene group, a dibenzofuranylene group, and a dibenzothiophenylene group, each substituted with at least one selected from deuterium, —F, —Cl, —Br, —I, a cyano group, a C₁-C₁₀ alkyl group, a C₁-C₁₀ alkoxy group, a phenyl group, a biphenyl group, a terphenyl group, a naphthyl group, a fluorenyl group, a pyridinyl group, a pyrazinyl group, a pyrimidinyl group, a quinolinyl group, an isoquinolinyl group, a carbazolyl group, a dibenzofuranyl group, and a dibenzothiophenyl group, but embodiments of the present disclosure are not limited thereto.

In Formula 2, a21 indicates the number of repeated groups L₂₁, and may be selected from 0, 1, 2, 3, 4, and 5, wherein, when a21 is 0, (L₂₁)ₐ₂₁ may be a single bond, and when a21 is two or more, a plurality of groups L₂₁ may be identical to or different from each other.

Similarly, in Formulae 20-1 and 20-2, a22 to a30 may each independently be selected from 0, 1, 2, 3, 4, and 5.

For example, in Formulae 2, 20-1, and 20-2, a21 to a30 may each independently be selected from 0, 1 and 2, but embodiments of the present disclosure are not limited thereto.

In Formulae 2, 20-1, and 20-2, R₂₁ to R₂₉ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ aryl alkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₁-C₆₀ heteroaryl alkyl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₁)(Q₂), and —B(Q₁)(Q₂), two or more selected from R₂₁ to R₂₉ are optionally linked to form a ring; and

Q₁ to Q₃ may each independently be selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, and a terphenyl group.

For example, in Formulae 2, 20-1, and 20-2, R₂₁ to R₂₉ may each independently be selected from:

hydrogen, deuterium, —F, —Cl, —Br, —I, a cyano group, a C₁-C₁₀ alkyl group, a C₁-C₁₀ alkoxy group, a C₃-C₁₀ cycloalkyl group, and a C₁-C₁₀ heterocycloalkyl group;

a C₁-C₁₀ alkyl group, a C₁-C₁₀ alkoxy group, a C₃-C₁₀ cycloalkyl group, and a C₁-C₁₀ heterocycloalkyl group, each substituted with at least one selected from deuterium, —F, —Cl, —Br, —I, and a cyano group;

a C₆-C₃₀ aryl group, a biphenyl group, a terphenyl group, a C₆-C₃₀ aryloxy group, a C₆-C₃₀ arylthio group, a C₇-C₆₀ aryl alkyl group, a C₁-C₃₀ heteroaryl group, a C₁-C₆₀ heteroaryloxy group, a C₁-C₆₀ heteroarylthio group, a C₂-C₆₀ heteroaryl alkyl group, a monovalent non-aromatic condensed polycyclic group, and a monovalent non-aromatic condensed heteropolycyclic group;

a C₆-C₃₀ aryl group, a biphenyl group, a terphenyl group, a C₆-C₃₀ aryloxy group, a C₆-C₃₀ arylthio group, a C₇-C₆₀ aryl alkyl group, a C₁-C₃₀ heteroaryl group, a C₁-C₆₀ heteroaryloxy group, a C₁-C₆₀ heteroarylthio group, a C₂-C₆₀ heteroaryl alkyl group, a monovalent non-aromatic condensed polycyclic group, and a monovalent non-aromatic condensed heteropolycyclic group, each substituted with at least one selected from deuterium, —F, —Cl, —Br, —I, a cyano group, a C₁-C₁₀ alkyl group, a C₁-C₁₀ alkoxy group, a C₃-C₁₀ cycloalkyl group, a C₁-C₁₀ heterocycloalkyl group, a C₆-C₃₀ aryl group, a biphenyl group, a terphenyl group, a C₆-C₃₀ aryloxy group, a C₆-C₃₀ arylthio group, a C₇-C₆₀ aryl alkyl group, a C₁-C₃₀ heteroaryl group, a C₁-C₆₀ heteroaryloxy group, a C₁-C₆₀ heteroarylthio group, a C₂-C₆₀ heteroaryl alkyl group, a monovalent non-aromatic condensed polycyclic group, and a monovalent non-aromatic condensed heteropolycyclic group; and

—Si(Q₁)(Q₂)(Q₃), —N(Q₁)(Q₂), and —B(Q₁)(Q₂),

two or more selected from R₂₁ to R₂₉ are optionally linked to form a ring; and

Q₁ to Q₃ may each independently be selected from hydrogen, a C₁-C₁₀ alkyl group, a C₆-C₃₀ aryl group, a biphenyl group, a terphenyl group, a C₁-C₃₀ heteroaryl group, a monovalent non-aromatic condensed polycyclic group, and a monovalent non-aromatic condensed heteropolycyclic group, but embodiments of the present disclosure are not limited thereto.

In an embodiment, in Formulae 2, 20-1, and 20-2, R₂₁ to R₂₉ may each independently be selected from:

hydrogen, deuterium, —F, —Cl, —Br, —I, a cyano group, a methyl group, an ethyl group, an n-propyl group, an iso-propyl group, an n-butyl group, an iso-butyl group, a sec-butyl group, a tert-butyl group, a methoxy group, an ethoxy group, an n-propoxy group, an iso-propoxy group, an n-butoxy group, an iso-butoxy group, a sec-butoxy group, a tert-butoxy group, a cyclopentyl group, and a cyclohexyl group;

a methyl group, an ethyl group, an n-propyl group, an iso-propyl group, an n-butyl group, an iso-butyl group, a sec-butyl group, a tert-butyl group, a methoxy group, an ethoxy group, an n-propoxy group, an iso-propoxy group, an n-butoxy group, an iso-butoxy group, a sec-butoxy group, a tert-butoxy group, a cyclopentyl group, and a cyclohexyl group, each substituted with at least one selected from deuterium, —F, —Cl, —Br, —I and a cyano group;

a phenyl group, a biphenyl group, a terphenyl group, a naphthyl group, a fluorenyl group, a pyridinyl group, a pyrazinyl group, a pyrimidinyl group, a quinolinyl group, an isoquinolinyl group, a carbazolyl group, a dibenzofuranyl group, and a dibenzothiophenyl group;

a phenyl group, a biphenyl group, a terphenyl group, a naphthyl group, a fluorenyl group, a pyridinyl group, a pyrazinyl group, a pyrimidinyl group, a quinolinyl group, an isoquinolinyl group, a carbazolyl group, a dibenzofuranyl group, and a dibenzothiophenyl group, each substituted with at least one selected from deuterium, —F, —Cl, —Br, —I, a cyano group, a methyl group, an ethyl group, an n-propyl group, an iso-propyl group, an n-butyl group, an iso-butyl group, a sec-butyl group, a tert-butyl group, a methoxy group, an ethoxy group, an n-propoxy group, an iso-propoxy group, an n-butoxy group, an iso-butoxy group, a sec-butoxy group, a tert-butoxy group, a cyclopentyl group, a cyclohexyl group, a phenyl group, a biphenyl group, a terphenyl group, a naphthyl group, a fluorenyl group, a pyridinyl group, a pyrazinyl group, a pyrimidinyl group, a quinolinyl group, an isoquinolinyl group, a carbazolyl group, a dibenzofuranyl group, and a dibenzothiophenyl group; and

—Si(Q₁)(Q₂)(Q₃), —N(Q₁)(Q₂), and —B(Q₁)(Q₂),

two or more selected from R₂₁ to R₂₉ are optionally linked to form a ring; and

Q₁ to Q₃ may each independently be selected from hydrogen, a methyl group, an ethyl group, an n-propyl group, an iso-propyl group, an n-butyl group, an iso-butyl group, a sec-butyl group, a tert-butyl group, a phenyl group, a biphenyl group, a terphenyl group, a naphthyl group, a fluorenyl group, a pyridinyl group, a pyrazinyl group, a pyrimidinyl group, a quinolinyl group, an isoquinolinyl group, a carbazolyl group, a dibenzofuranyl group, and a dibenzothiophenyl group, but embodiments of the present disclosure are not limited thereto.

In Formula 20-1, b21 indicates the number of groups (L₂₂)ₐ₂₂-R₂₁, and may be selected from 1, 2, 3, and 4, wherein, when b21 is two or more, a plurality of groups (L22)ₐ₂₂-R₂₁ may be identical to or different from each other.

Similarly, b22 and b24 may each independently be selected from 1, 2, 3, and 4.

Similarly, b23 may be selected from 1, 2, and 3.

In an embodiment, in Formula 2,

A₂₁ and A₂₂ may each independently be represented by Formula 20-1;

A₂₁ may be represented by Formula 20-1, and A₂₂ may be represented by Formula 20-2; or

A₂₁ and A₂₂ may each independently be represented by Formula 20-2, but embodiments of the present disclosure are not limited thereto.

In one or more embodiments, the group represented by Formula 20-2 may be a group represented by one selected from Formulae 20-21 to 20-24, but embodiments of the present disclosure are not limited thereto:

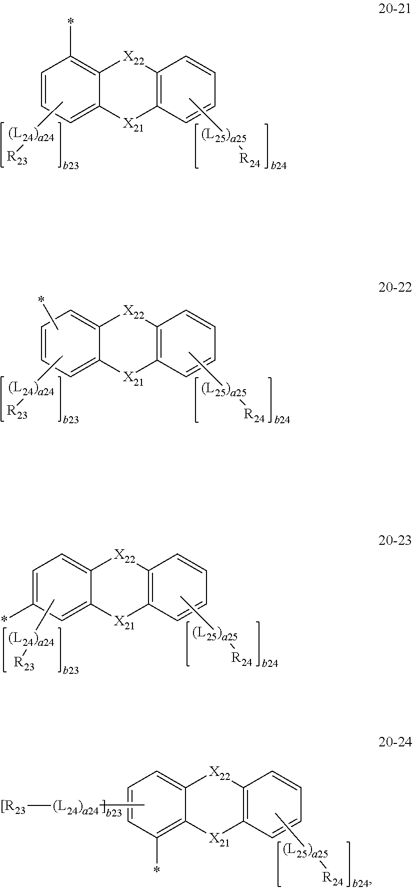

In Formulae 20-21 to 20-24, X₂₁, X₂₂, L₂₄, L₂₅, a24, a25, R₂₃, R₂₄, b23 and b24 may each independently be the same as described in connection with Formula 20-2,

* indicates a binding site to a neighboring atom.

In one or more embodiments, the second compound may be represented by one selected from Formulae 2-1 to 2-3, but embodiments of the present disclosure are not limited thereto:

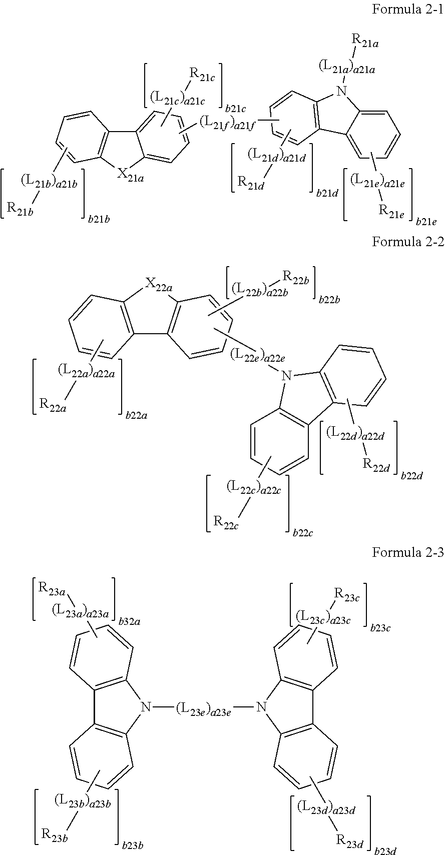

In Formulae 2-1 to 2-3,

X₂₁ₐ may be selected from N[(L_{21g})_{a21g}-R_{21f}], O, and S, and X₂₂ₐ may be selected from N[(L_{22f})_{a22f}-R₂₂ₑ], O, and S,

L₂₁ₐ to L_{21g}, L₂₂ₐ to L_{22f}, and L₂₃ₐ to L₂₃ₑ may each independently be defined the same as L₂₁ in Formula 2,

a21a to a21g, a22a to a22f, and a23a to a23e may each independently be defined the same as a21 in Formula 2,

R₂₁ₐ to R_{21f}, R₂₂ₐ to R₂₂ₑ, and R₂₃ₐ to R_{23d} may each independently be defined the same as R₂₁ in Formula 2,

b21b, b21e, b22a, b22c, b22d, and b23a to b23d may each independently be defined the same as b21 in Formula 2, and

b21c, b21d and b22b may each independently be defined the same as b23 in Formula 2.

For example, in Formula 2-3, (L₂₃ₑ)ₐ₂₃ₑ may be selected from groups represented by Formulae 9-1 to 9-6, but embodiments of the present disclosure are not limited thereto:

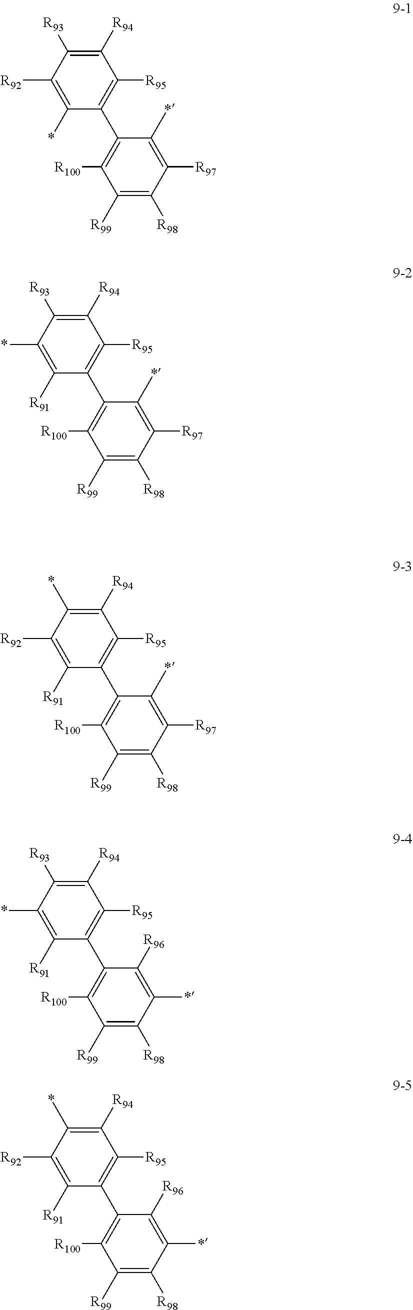

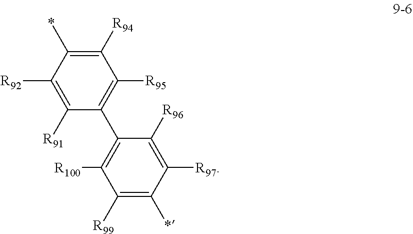

In Formulae 9-1 to 9-6,

R₉₁ to R₁₀₀ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a heterocycloalkenyl group, a C₆-C₆₀ aryl group, a biphenyl group, a terphenyl group, a C₁-C₆₀ heteroaryl group, a monovalent non-aromatic condensed polycyclic group, a monovalent non-aromatic condensed heteropolycyclic group, and —Si(Q₃₁)(Q₃₂)(Q₃₃), and

Q₃₁ to Q₃₃ may each independently be selected from hydrogen, a C₁-C₁₀ alkyl group, a C₆-C₃₀ aryl group, a biphenyl group, a terphenyl group, a C₂-C₃₀ heteroaryl group, a monovalent non-aromatic condensed polycyclic group, and a monovalent non-aromatic condensed heteropolycyclic group.

For example, in Formulae 9-1 to 9-6,

R₉₁ to R₁₀₀ may each independently be selected from hydrogen, deuterium, —F, —Cl, —Br, —I, a cyano group, a C₁-C₁₀ alkyl group, a C₁-C₁₀ alkoxy group, a phenyl group, a biphenyl group, a terphenyl group, a naphthyl group, a fluorenyl group, a pyridinyl group, a pyrazinyl group, a pyrimidinyl group, a quinolinyl group, an isoquinolinyl group, a carbazolyl group, a dibenzofuranyl group, and a dibenzothiophenyl group, but embodiments of the present disclosure are not limited thereto.

In one or more embodiments, the second compound may be represented by one selected from Formulae 2-11, 2-21, and 2-31 to 2-33, but embodiments of the present disclosure are not limited thereto:

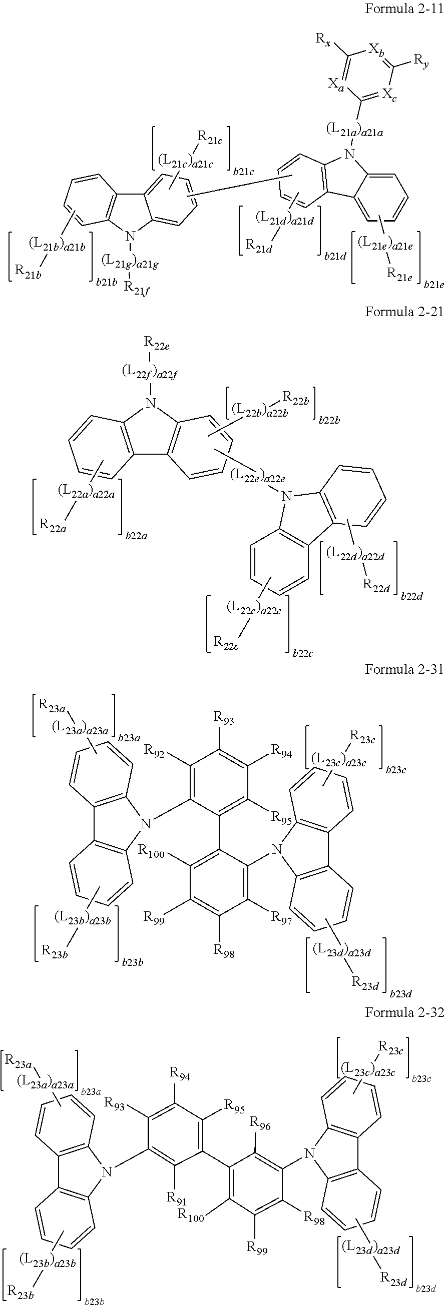

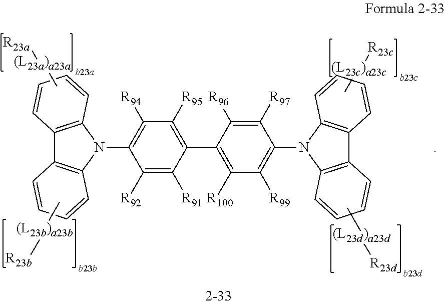

In Formulae 2-11, 2-21, and 2-31 to 2-33,

Xₐ, X_{b}, and X_{c} may each independently be selected from C and N(R_{z}),

Xₐ, X_{b}, and X_{c} may not be simultaneously N(R_{z}),

L₂₁ₐ to L₂₁ₑ, L_{21g}, L₂₂ₐ to L_{22f}, and L₂₃ₐ to L_{23d} may each independently be the same as described in connection with L₂₁ in Formula 2,

a21a to a21e, a21g, a22a to a22f, and a23a to a23d may each independently be the same as described in connection with a21 in Formula 2,

R_{21b} to R_{21f}, R₂₂ₐ to R₂₂ₑ, and R₂₃ₐ to R_{23d} may each independently be the same as described in connection with R₂₁ in Formula 2,

b21b, b21e, b22a, b22c, b22d, and b23a to b23d may each independently be the same as described in connection with b21 in Formula 2,

b21c, b21d, and b22b may each independently be the same as described in connection with b23 in Formula 2, and

R₉₁ to R₁₀₀, Rₓ, R_{y}, and R_{z} may each independently be selected from hydrogen, deuterium, —F, —Cl, —Br, —I, a cyano group, a methyl group, an ethyl group, an n-propyl group, an iso-propyl group, an n-butyl group, an iso-butyl group, a sec-butyl group, a tert-butyl group, a phenyl group, a biphenyl group, a terphenyl group, a naphthyl group, a fluorenyl group, a pyridinyl group, a pyrazinyl group, a pyrimidinyl group, a quinolinyl group, an isoquinolinyl group, a carbazolyl group, a dibenzofuranyl group, and a dibenzothiophenyl group.

In an embodiment, the second compound may be selected from Compounds H-1 to H-19, but embodiments of the present disclosure are not limited thereto:

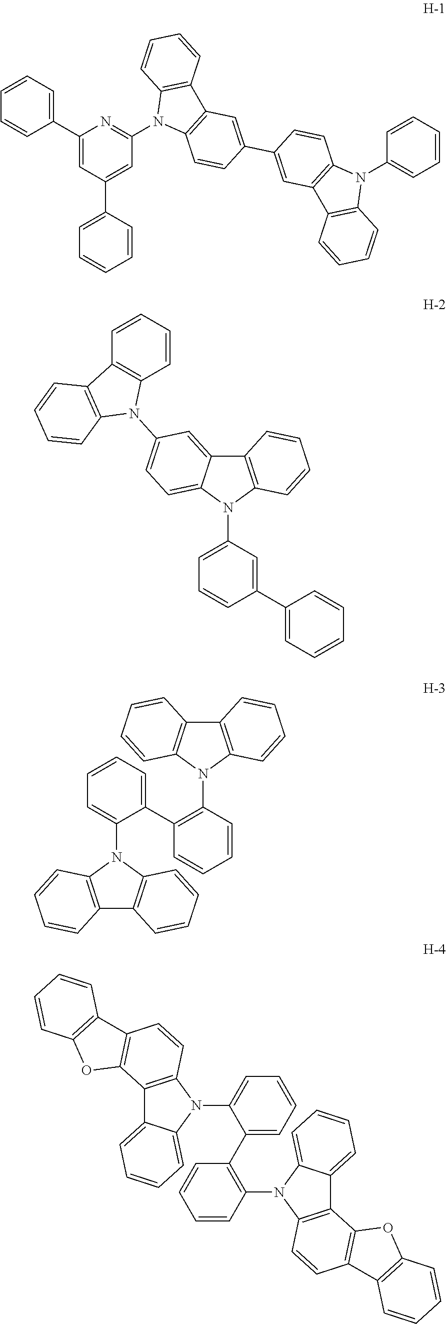

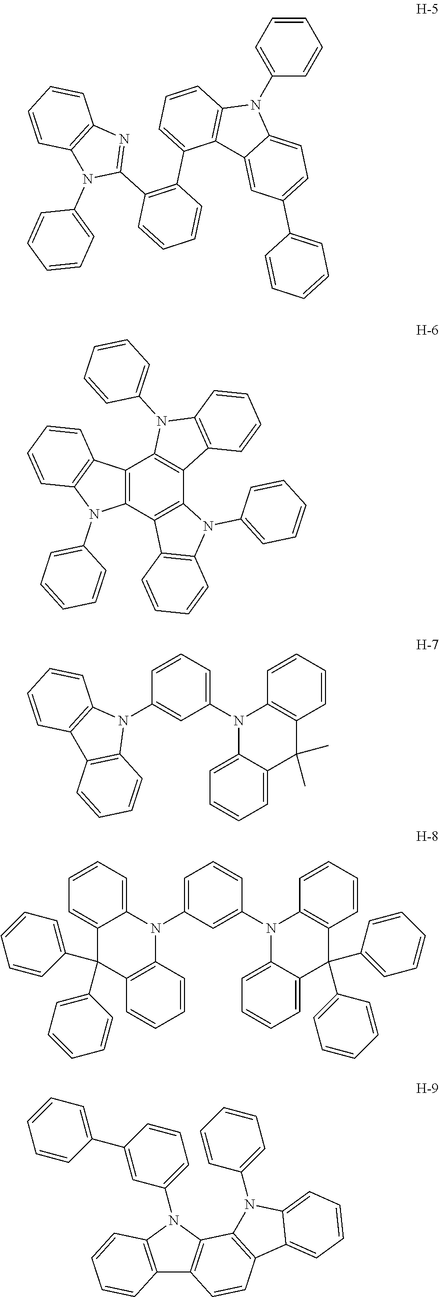

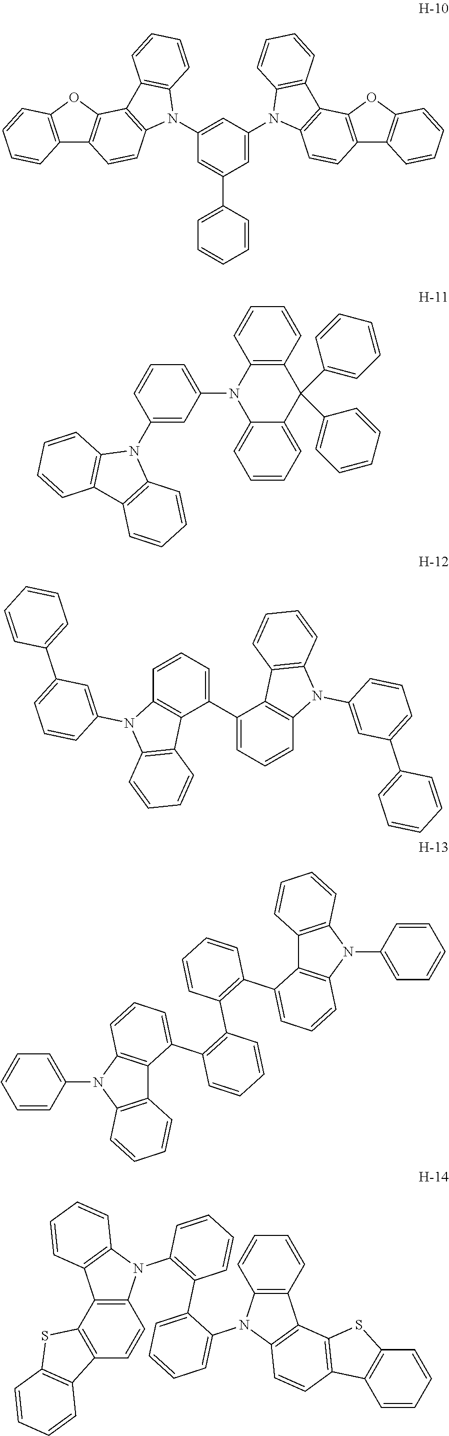 [SMILES: c1ccc(-c2cc(-n3c4ccccc4c4c5oc6ccccc6c5ccc43)cc(-n3c4ccccc4c4c5oc6ccccc6c5ccc43)c2)cc1 ; c1ccc(C2(c3ccccc3)c3ccccc3N(c3cccc(-n4c5ccccc5c5ccccc54)c3)c3ccccc32)cc1 ; c1ccc(-c2cccc(-n3c4ccccc4c4c(-c5cccc6c5c5ccccc5n6-c5cccc(-c6ccccc6)c5)cccc43)c2)cc1 ; c1ccc(-n2c3ccccc3c3c(-c4ccccc4-c4ccccc4-c4cccc5c4c4ccccc4n5-c4ccccc4)cccc32)cc1 ; c1ccc(-n2c3ccccc3c3c4sc5ccccc5c4ccc32)c(-c2ccccc2-n2c3ccccc3c3c4sc5ccccc5c4ccc32)c1]

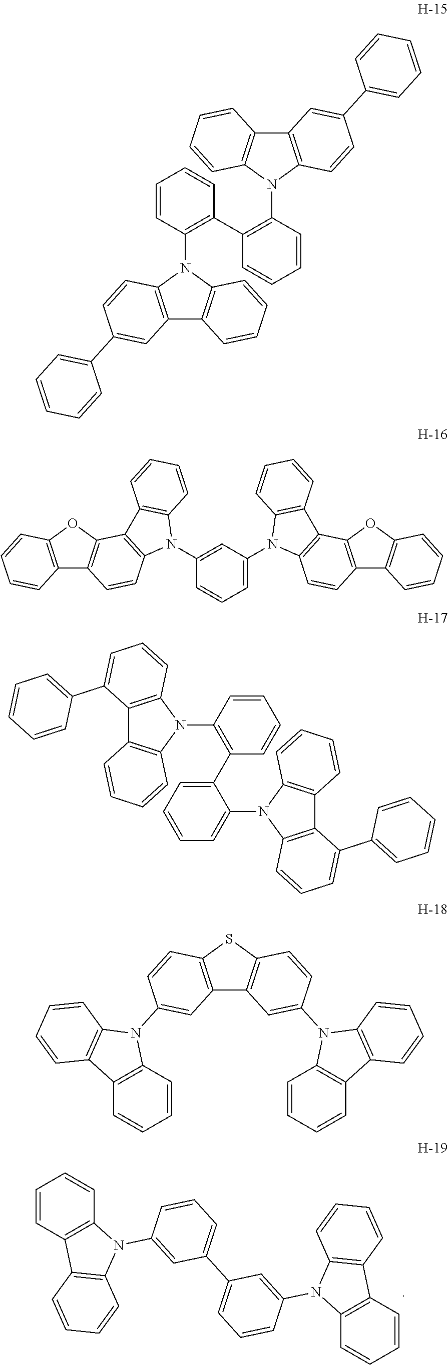 [SMILES: c1ccc(-c2ccc3c(c2)c2ccccc2n3-c2ccccc2-c2ccccc2-n2c3ccccc3c3cc(-c4ccccc4)ccc32)cc1 ; c1cc(-n2c3ccccc3c3c4oc5ccccc5c4ccc32)cc(-n2c3ccccc3c3c4oc5ccccc5c4ccc32)c1 ; c1ccc(-c2cccc3c2c2ccccc2n3-c2ccccc2-c2ccccc2-n2c3ccccc3c3c(-c4ccccc4)cccc32)cc1 ; c1ccc2c(c1)c1ccccc1n2-c1ccc2sc3ccc(-n4c5ccccc5c5ccccc54)cc3c2c1 ; c1cc(-c2cccc(-n3c4ccccc4c4ccccc43)c2)cc(-n2c3ccccc3c3ccccc32)c1]

For example, the third compound may emit delayed fluorescence.

In an embodiment, the third compound may be represented by one selected from Formulae 3 and 4, but embodiments of the present disclosure are not limited thereto:

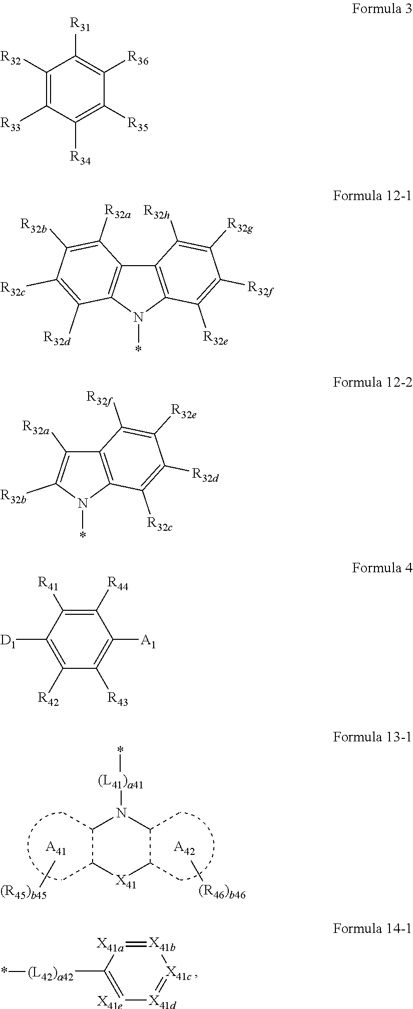

wherein, in Formulae 3, 4, 12-1, 12-2, 13-1, and 14-1,

R₃₁ to R₃₆ may each independently be selected from a group represented by Formula 12-1, a group represented by Formula 12-2, hydrogen, deuterium, —F, —Cl, —Br, —I, a hydroxyl group, a cyano group, a substituted or unsubstituted C₁-C₆₀ alkyl group, a substituted or unsubstituted C₁-C₆₀ alkoxy group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ aryl alkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, and a substituted or unsubstituted C₂-C₆₀ heteroaryl alkyl group,

at least one selected from R₃₁ to R₃₆ may be a cyano group,

at least one selected from R₃₁ to R₃₆ may be selected from a group represented by Formula 12-1 and a group represented by Formula 12-2,

D₁ may be a group represented by Formula 13-1,

A₁ may be a group represented by Formula 14-1,

X₄₁ may be selected from a single bond, O, S, N(R₄₇), and C(R₄₇)(R₄₈),

A₄₁ and A₄₂ may each independently be selected from a benzene group, a fluorene group, a carbazole group, a dibenzofuran group, a dibenzothiophene group, an indolofluorene group, an indolocarbazole group, an indolodibenzofuran group, an indolodibenzothiophene group, an indenofluorene group, an indenocarbazole group, an indenodibenzofuran group, an indenodibenzothiophene group, a benzofuranofluorene group, a benzofuranocarbazole group, a benzofuranodibenzofuran group, a benzofuranodibenzothiophene group, a benzothienofluorene group, a benzothienocarbazole group, a benzothienodibenzofuran group, and a benzothienodibenzothiophene group,

L₄₁ and L₄₂ may each independently be selected from a substituted or unsubstituted C₅-C₃₀ carbocyclic group and a substituted or unsubstituted C₁-C₃₀ heterocyclic group,

a41 and a42 may each independently be selected from 0, 1, 2, and 3,

X₄₁ₐ may be N or C(R₄₁ₐ); X_{41b} may be N or C(R_{41b}); X_{41c} may be N or C(R_{41c}); X_{41d} may be N or C(R_{41d}); and X₄₁ₑ may be N or C(R₄₁ₑ), wherein at least one selected from X₄₁ₐ to X₄₁ₑ is N,

R₃₂ₐ to R₃₂ₕ, R₄₁ to R_{48,} and R₄₁ₐ to R₄₁ₑ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ aryl alkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroaryl alkyl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₄)(Q₅), and —B(Q₆)(Q₇),

b45 and b46 may each independently be selected from 1, 2, 3, 4, 5, 6, 7, and 8,

Q₁ to Q₇ may each independently be selected from hydrogen, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and

* indicates a binding site to a neighboring atom.

For example, in Formula 3, one, two, or three selected from R₃₁ to R₃₆ may be a cyano group,

one, two, three, four, or five selected from R₃₁ to R₃₆ may be selected from a group represented by Formula 12-1 and a group represented by Formula 12-2, but embodiments of the present disclosure are not limited thereto.

In an embodiment, in Formula 3, one or two selected from R₃₁ to R₃₆ may be a cyano group,

one, two, three, four, or five selected from R₃₁ to R₃₆ may be selected from a group represented by Formula 12-1 and a group represented by Formula 12-2, but embodiments of the present disclosure are not limited thereto.

In an embodiment, in Formula 3, one selected from R₃₁ to R₃₆ may be a cyano group, and three, four, or five selected from R₃₁ to R₃₆ may be selected from a group represented by Formula 12-1 and a group represented by Formula 12-2; or

two selected from R₃₁ to R₃₆ may be a cyano group, and three or four selected from R₃₁ to R₃₆ may be selected from a group represented by Formula 12-1 and a group represented by Formula 12-2, but embodiments of the present disclosure are not limited thereto.

For example, in Formula 3, R₃₁ to R₃₆ may each independently be selected from a group represented by Formula 12-1, a group represented by Formula 12-2, hydrogen, deuterium, —F, —Cl, —Br, —I, a hydroxyl group, a cyano group, a C₁-C₁₀ alkyl group, and a alkoxy group, but embodiments of the present disclosure are not limited thereto.

In an embodiment, in Formula 3, R₃₁ to R₃₆ may each independently be selected from a group represented by Formula 12-1, a group represented by Formula 12-2, hydrogen, deuterium, —F, —Cl, —Br, —I, a hydroxyl group, a cyano group, a methyl group, an ethyl group, an n-propyl group, an iso-propyl group, an n-butyl group, an iso-butyl group, a sec-butyl group, a tert-butyl group, a methoxy group, an ethoxy group, an n-propoxy group, an iso-propoxy group, an n-butoxy group, an iso-butoxy group, a sec-butoxy group, and a tert-butoxy group, but embodiments of the present disclosure are not limited thereto.

For example, in Formulae 12-1 and 12-2, R₃₂ₐ to R₃₂ₕ may each independently be selected from hydrogen, deuterium, —F, —Cl, —Br, —I, a hydroxyl group, a cyano group, a methyl group, an ethyl group, an n-propyl group, an iso-propyl group, an n-butyl group, an iso-butyl group, a sec-butyl group, a tert-butyl group, a methoxy group, an ethoxy group, an n-propoxy group, an iso-propoxy group, an n-butoxy group, an iso-butoxy group, a sec-butoxy group, a tert-butoxy group, a phenyl group, a biphenyl group, a terphenyl group, a naphthyl group, a pyridinyl group, a pyrazinyl group, and a pyrimidinyl group, but embodiments of the present disclosure are not limited thereto.

In an embodiment, in Formula 13-1, A₄₁ may be a benzene group, and A₄₂ may be selected from a benzene group, a fluorene group, a carbazole group, a dibenzofuran group, a dibenzothiophene group, an indolofluorene group, an indolocarbazole group, an indolodibenzofuran group, an indolodibenzothiophene group, an indenofluorene group, an indenocarbazole group, an indenodibenzofuran group, an indenodibenzothiophene group, a benzofuranofluorene group, a benzofuranocarbazole group, a benzofuranodibenzofuran group, a benzofuranodibenzothiophene group, a benzothienofluorene group, a benzothienocarbazole group, a benzothienodibenzofuran group, and a benzothienodibenzothiophene group, but embodiments of the present disclosure are not limited thereto.

In an embodiment, in Formula 13-1, X₄₁ may be selected from a single bond, and C(R₄₇)(R₄₈), but embodiments of the present disclosure are not limited thereto.

In one or more embodiments, the third compound may be represented by one selected from Formulae 3-1 to 3-5, but embodiments of the present disclosure are not limited thereto:

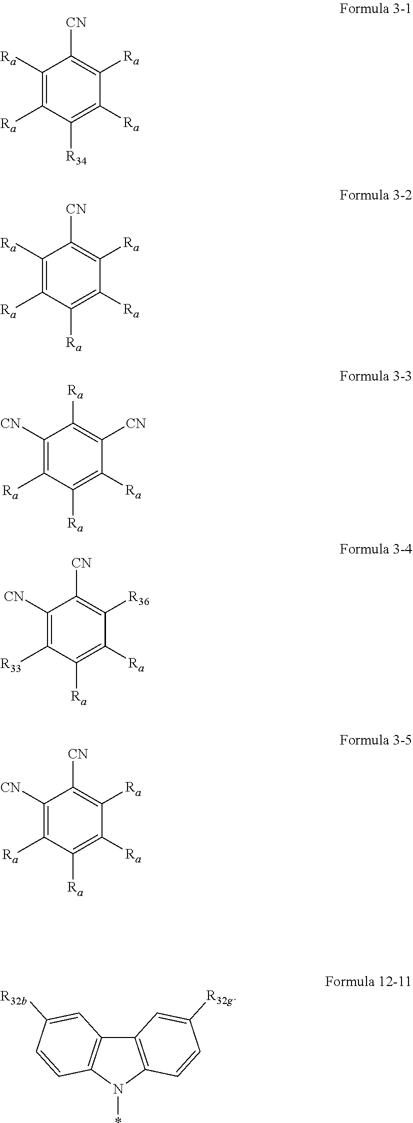

In Formulae 3-1 to 3-5, 12-1, and 12-2,

Rₐ may be a group represented by Formula 12-11,

R₃₃, R₃₄, and R₃₆ may each independently be selected from hydrogen, deuterium, —F, —Cl, —Br, —I, a hydroxyl group, a C₁-C₁₀ alkyl group, and a C₁-C₁₀ alkoxy group,

R_{32b} and R_{32g} may each independently be selected from hydrogen, deuterium, —F, —Cl, —Br, —I, a hydroxyl group, a C₁-C₁₀ alkyl group, a C₁-C₁₀ alkoxy group, a C₆-C₃₀ aryl group, and a C₁-C₃₀ heteroaryl group, and

* indicates a binding site to a neighboring atom.

In one or more embodiments, the third compound may be selected from Compounds D-1 to D-23, but embodiments of the present disclosure are not limited thereto:

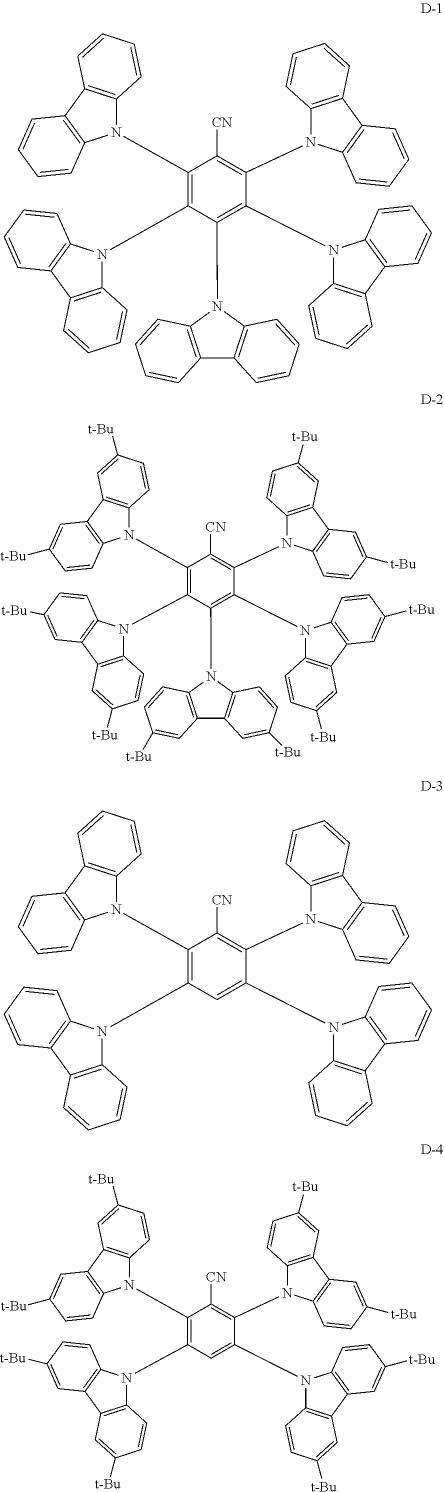

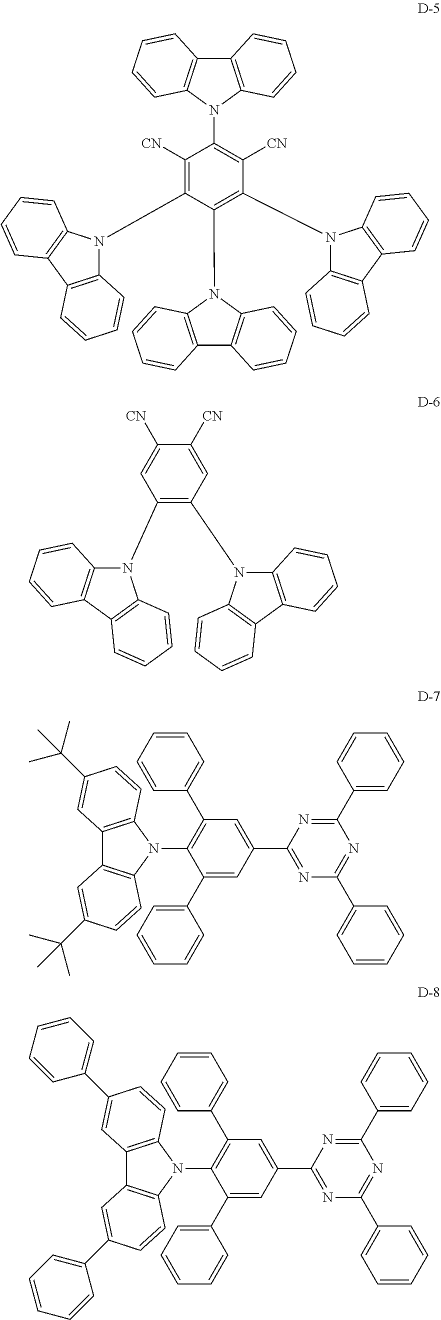

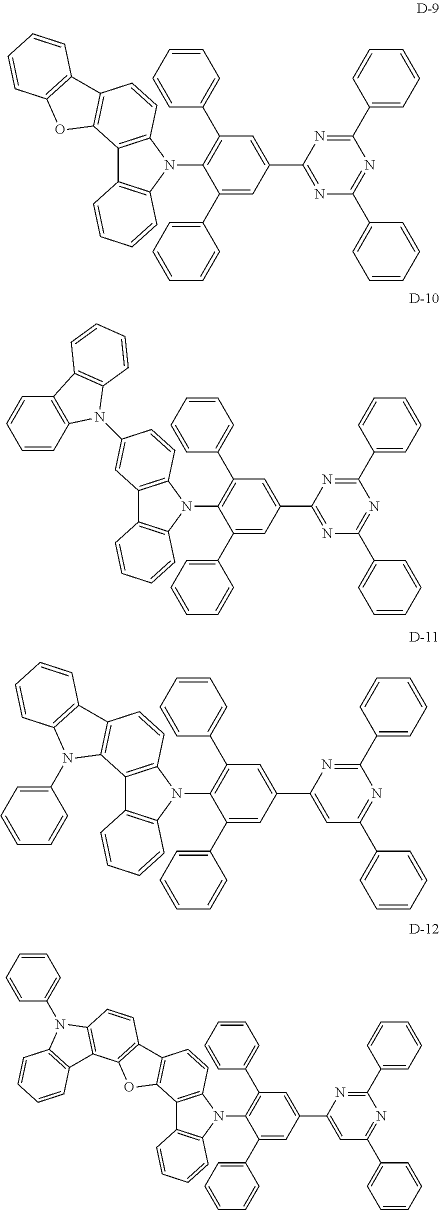 [SMILES: c1ccc(-c2nc(-c3ccccc3)nc(-c3cc(-c4ccccc4)c(-n4c5ccccc5c5c6oc7ccccc7c6ccc54)c(-c4ccccc4)c3)n2)cc1 ; c1ccc(-c2nc(-c3ccccc3)nc(-c3cc(-c4ccccc4)c(-n4c5ccccc5c5cc(-n6c7ccccc7c7ccccc76)ccc54)c(-c4ccccc4)c3)n2)cc1 ; c1ccc(-c2cc(-c3cc(-c4ccccc4)c(-n4c5ccccc5c5c4ccc4c6ccccc6n(-c6ccccc6)c45)c(-c4ccccc4)c3)nc(-c3ccccc3)n2)cc1 ; c1ccc(-c2cc(-c3cc(-c4ccccc4)c(-n4c5ccccc5c5c6oc7c(ccc8c7c7ccccc7n8-c7ccccc7)c6ccc54)c(-c4ccccc4)c3)nc(-c3ccccc3)n2)cc1]

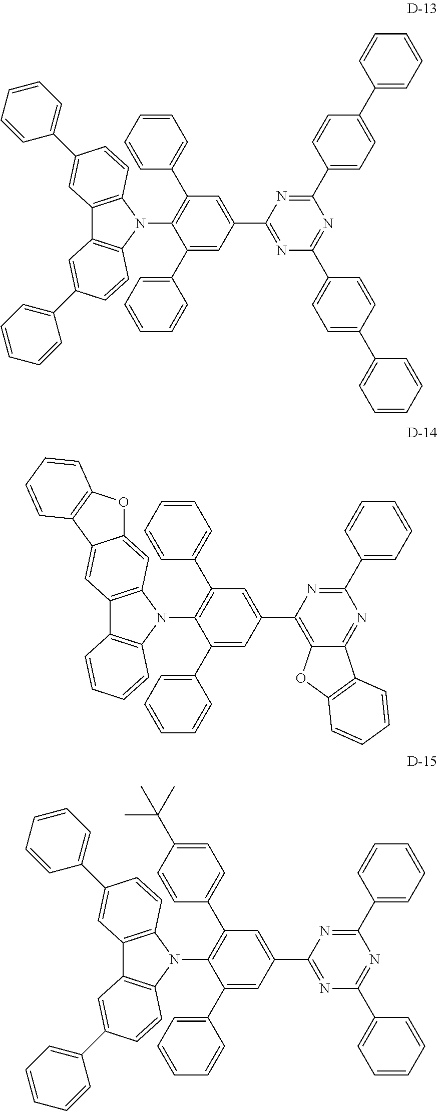 [SMILES: c1ccc(-c2ccc(-c3nc(-c4ccc(-c5ccccc5)cc4)nc(-c4cc(-c5ccccc5)c(-n5c6ccc(-c7ccccc7)cc6c6cc(-c7ccccc7)ccc65)c(-c5ccccc5)c4)n3)cc2)cc1 ; c1ccc(-c2nc(-c3cc(-c4ccccc4)c(-n4c5ccccc5c5cc6c(cc54)oc4ccccc46)c(-c4ccccc4)c3)c3oc4ccccc4c3n2)cc1 ; CC(C)(C)c1ccc(-c2cc(-c3nc(-c4ccccc4)nc(-c4ccccc4)n3)cc(-c3ccccc3)c2-n2c3ccc(-c4ccccc4)cc3c3cc(-c4ccccc4)ccc32)cc1]

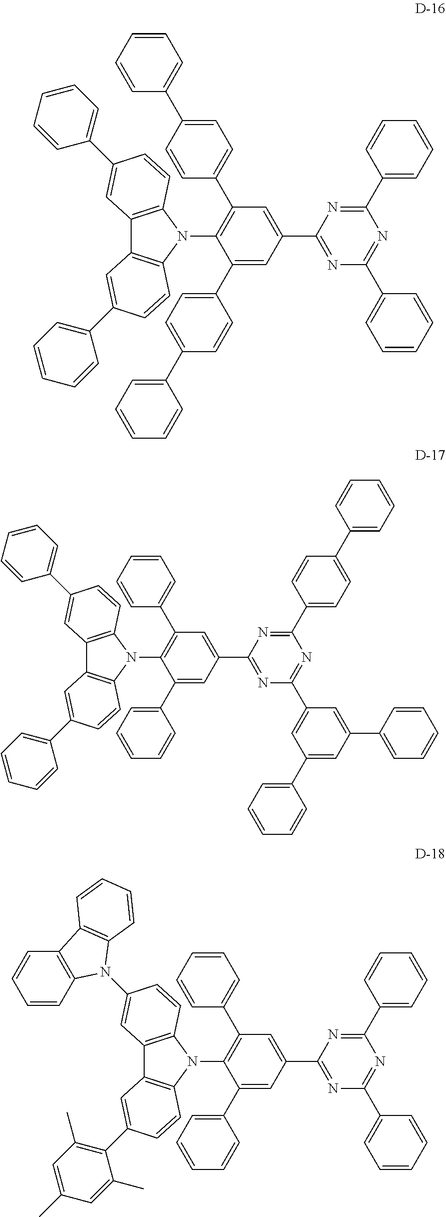 [SMILES: c1ccc(-c2ccc(-c3cc(-c4nc(-c5ccccc5)nc(-c5ccccc5)n4)cc(-c4ccc(-c5ccccc5)cc4)c3-n3c4ccc(-c5ccccc5)cc4c4cc(-c5ccccc5)ccc43)cc2)cc1 ; c1ccc(-c2ccc(-c3nc(-c4cc(-c5ccccc5)cc(-c5ccccc5)c4)nc(-c4cc(-c5ccccc5)c(-n5c6ccc(-c7ccccc7)cc6c6cc(-c7ccccc7)ccc65)c(-c5ccccc5)c4)n3)cc2)cc1 ; Cc1cc(C)c(-c2ccc3c(c2)c2cc(-n4c5ccccc5c5ccccc54)ccc2n3-c2c(-c3ccccc3)cc(-c3nc(-c4ccccc4)nc(-c4ccccc4)n3)cc2-c2ccccc2)c(C)c1]

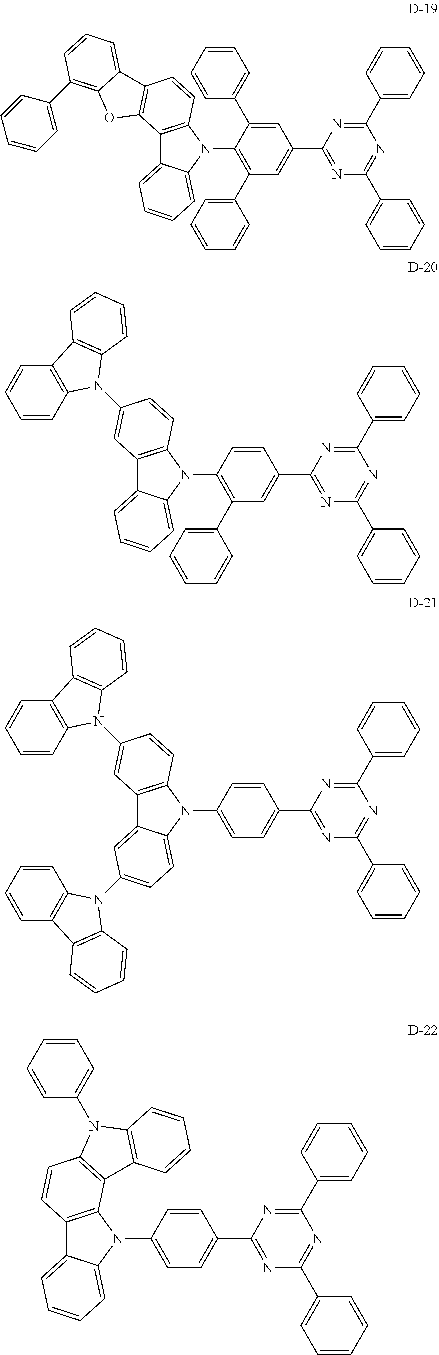 [SMILES: c1ccc(-c2nc(-c3ccccc3)nc(-c3cc(-c4ccccc4)c(-n4c5ccccc5c5c6oc7c(-c8ccccc8)cccc7c6ccc54)c(-c4ccccc4)c3)n2)cc1 ; c1ccc(-c2nc(-c3ccccc3)nc(-c3ccc(-n4c5ccccc5c5cc(-n6c7ccccc7c7ccccc76)ccc54)c(-c4ccccc4)c3)n2)cc1 ; c1ccc(-c2nc(-c3ccccc3)nc(-c3ccc(-n4c5ccc(-n6c7ccccc7c7ccccc76)cc5c5cc(-n6c7ccccc7c7ccccc76)ccc54)cc3)n2)cc1 ; c1ccc(-c2nc(-c3ccccc3)nc(-c3ccc(-n4c5ccccc5c5ccc6c(c7ccccc7n6-c6ccccc6)c54)cc3)n2)cc1]

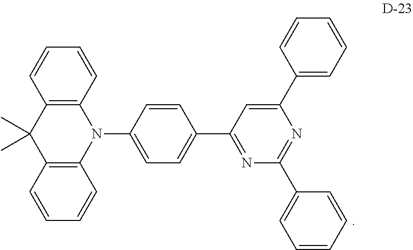 [SMILES: CC1(C)c2ccccc2N(c2ccc(-c3cc(-c4ccccc4)nc(-c4ccccc4)n3)cc2)c2ccccc21]

In an embodiment, the first compound and the second compound may be different from each other, but embodiments of the present disclosure are not limited thereto.

In an embodiment, the second compound may satisfy Condition 2, but embodiments of the present disclosure are not limited thereto:

E_{HOMO} (C2)>−5.45 eV. Condition 1

In Condition 2,

E_{HOMO} (C2) is a highest occupied molecular orbital (HOMO) energy level of the second compound.

E_{HOMO} (C2) is evaluated by using a DFT method of Gaussian program structurally optimized at a level of B3LYP/6-31G(d,p).

In an embodiment, the third compound may satisfy Condition 3:

E_{LUMO} (C3)<−1.70 eV. Condition 3

In Condition 3,

E_{LUMO} (C3) is a lowest unoccupied molecular orbital (LUMO) energy level of the third compound.

E_{LUMO} (C3) is evaluated by using a DFT method of Gaussian program structurally optimized at a level of B3LYP/6-31G(d,p).

Since the composition includes the first compound represented by Formula 1, the second compound represented by Formula 2, and the third compound satisfying Condition 1, the mobility properties of the electron and the hole may be improved. Therefore, an electronic device, for example, an organic light-emitting device, which includes the composition, may have a low roll-off and high luminescent efficiency.

The first compound represented by Formula 1 essentially includes at least one cyano group. Therefore, since the first compound represented by Formula 1 has excellent heat resistance, an electronic device, for example, an organic light-emitting device, which includes a thin film including the first compound, the second compound, and the third compound, may have a long lifespan.

Since the composition essentially includes the first compound represented by Formula 1, the composition may have excellent charge mobility and material stability and thus have a low roll-off and a long lifespan.

The composition may not include a transition metal-containing organometallic compound, and that is, the composition does not include a phosphorescent dopant. Therefore, the composition is clearly distinguished from other compositions in which at least one of the first compound to the third compound serves as a phosphorescent host.

In the composition, the first compound and the second compound may each serve as a host, and the third compound may serve as a dopant, for example, as a delayed fluorescent dopant. Since the composition essentially includes the second compound represented by Formula 2, the composition may have excellent hole mobility and material stability and thus have high efficiency and a long lifespan when mixed with the first compound.

For example, HOMO, LUMO, singlet (S₁), and triplet (T₁) energy levels of Compounds were evaluated by using a DFT method of Gaussian program structurally optimized at a level of B3LYP/6-31G(d,p), and results thereof are shown in Table 1.

TABLE 1

| | HOMO (eV) | LUMO (eV) | S₁ (eV) | T₁ (eV) |
|---|---|---|---|---|
| Compound H-1 | −4.98 | −1.46 | 3.09 | 2.92 |
| Compound H-2 | −5.13 | −1.09 | 3.61 | 3.15 |
| Compound H-3 | −5.42 | −1.07 | 3.38 | 3.17 |
| Compound E-1 | −5.64 | −2.06 | 3.14 | 3.03 |
| Compound D-1 | −5.56 | −2.21 | 2.73 | 2.53 |
| Compound D-4 | −5.37 | −1.93 | 2.81 | 2.63 |
| mCBP | −5.41 | −1.20 | 3.45 | 3.17 |
| DPEPO | −6.31 | −0.87 | 3.68 | 3.60 |
| PO-T2T | −6.92 | −2.32 | 3.76 | 3.03 |

The weight ratio of the first compound to the second compound in the composition may be in a range of about 0.1:99.9 to about 99.9:0.1, for example, about 1:9 to about 9:1. In an embodiment, the weight ratio of the first compound to the second compound may be in a range of about 3:7 to about 7:3. While not wishing to be bound by theory, it is understood that when the weight ratio of the first compound to the second compound in the composition is within this range, effective charge balance in the emission layer may be achieved. Therefore, an organic light-emitting device having a low roll-off, high efficiency, and a long lifespan may be implemented.

An amount of the third compound in the composition may be in a range of about 0.01 percent by weight (weight % to about 30 weight % based on the total amount of the first compound, the second compound, and the third compound, but embodiments of the present disclosure are not limited thereto. The amount of the third compound in the composition may be in a range of about 5 weight % to about 20 weight % based on the total amount of the first compound, the second compound, and the third compound, but embodiments of the present disclosure are not limited thereto. While not wishing to be bound by theory, it is understood that when the amount of the third compound is within this range, light emission may be implemented without quenching phenomenon.

According to another aspect of the present disclosure, there is provided a thin film including the composition. The thin film may be formed by using one or more suitable methods selected from vacuum deposition, spin coating, casting, and Langmuir-Blodgett (LB) deposition.

When thin film is formed by vacuum deposition, the deposition conditions may vary according to a material that is used to form the thin film, and the structure and thermal characteristics of the thin film. For example, the deposition conditions may include a deposition temperature of about 100° C. to about 500° C., a vacuum pressure of about 10⁻⁸ torr to about 10⁻³ torr, and a deposition rate of about 0.01 Angstroms per second (Å/sec) to about 100 Å/sec. However, the deposition conditions are not limited thereto.

When the thin film is formed using spin coating, coating conditions may vary depending on the material used to form the thin film, and the structure and thermal properties of the thin film. For example, a coating speed may be from about 2,000 revolutions per minute (rpm) to about 5,000 rpm, and a temperature at which a heat treatment is performed to remove a solvent after coating may be from about 80° C. to about 200° C. However, the coating conditions are not limited thereto.

The thin film includes the composition described above.

The thin film may be applied to an electronic device, for example, an organic layer of an organic light-emitting device. Therefore, an aspect provides an organic light-emitting device including a first electrode; a second electrode; and an organic layer between the first electrode and the second electrode, wherein the organic layer includes the composition or the thin film.

In an embodiment, the thin film included in the organic layer may be an emission layer. The first compound and the second compound included in the emission layer may act as a host. The third compound included in the emission layer may act as a dopant.

The third compound may emit delayed fluorescence. The third compound in the emission layer may emit delayed fluorescence when exciton moving from a ³n-π* excited state to a ¹π-π* excited state transitions to a ground state through reverse intersystem crossing. A ratio of delayed fluorescence in a light amount emitted from the emission layer may be about 90% or more, for example, about 92% or more, for example, about 95% or more, but embodiments of the present disclosure are not limited thereto.

When the thin film is the emission layer including the composition, the first compound and the second compound in the emission layer may increase the mobility of electron and hole in the organic light-emitting device and may adjust charge balance in the emission layer. Therefore, an organic light-emitting device having a low roll-off, high efficiency, and a long lifespan may be implemented.

When the thin film includes the composition, an organic light-emitting device that emits blue light may be implemented.

The FIGURE is a schematic view of an organic light-emitting device 10 according to an embodiment. Hereinafter, the structure of an organic light-emitting device according to an embodiment and a method of manufacturing an organic light-emitting device according to an embodiment will be described in connection with the FIGURE. The organic light-emitting device 10 includes a first electrode 11, an organic layer 15, and a second electrode 19, which are sequentially stacked.

A substrate may be additionally disposed under the first electrode 11 or above the second electrode 19. For use as the substrate, any substrate that is used in general organic light-emitting devices may be used, and the substrate may be a glass substrate or a transparent plastic substrate, each having excellent mechanical strength, thermal stability, transparency, surface smoothness, ease of handling, and water resistance.

In one or more embodiments, the first electrode 11 may be formed by depositing or sputtering a material for forming the first electrode 11 on the substrate. The first electrode 11 may be an anode. The material for forming the first electrode 11 may be selected from materials with a high work function to facilitate hole injection. The first electrode 11 may be a reflective electrode, a semi-transmissive electrode, or a transmissive electrode. The material for forming the first electrode 11 may be indium tin oxide (ITO), indium zinc oxide (IZO), tin oxide (SnO₂), or zinc oxide (ZnO). In one or more embodiments, the material for forming the first electrode 11 may be metal, such as magnesium (Mg), aluminum (Al), aluminum-lithium (Al—Li), calcium (Ca), magnesium-indium (Mg—In), or magnesium-silver (Mg—Ag).

The first electrode 11 may have a single-layered structure or a multi-layered structure including two or more layers. For example, the first electrode 11 may have a three-layered structure of ITO/Ag/ITO, but the structure of the first electrode 110 is not limited thereto.

The organic layer 15 is disposed on the first electrode 11.

The organic layer 15 may include a hole transport region, an emission layer, and an electron transport region.

The hole transport region may be disposed between the first electrode 11 and the emission layer.

The hole transport region may include a hole injection layer, a hole transport layer, an electron blocking layer, a buffer layer, or any combination thereof.

The hole transport region may include only either a hole injection layer or a hole transport layer. In one or more embodiments, the hole transport region may have a hole injection layer/hole transport layer structure or a hole injection layer/hole transport layer/electron blocking layer structure, which are sequentially stacked in this stated order from the first electrode 11.

When the hole transport region includes a hole injection layer (HIL), the hole injection layer may be formed on the first electrode 11 by using one or more suitable methods, for example, vacuum deposition, spin coating, casting, and/or Langmuir-Blodgett (LB) deposition.

When a hole injection layer is formed by vacuum deposition, the deposition conditions may vary according to a material that is used to form the hole injection layer, and the structure and thermal characteristics of the hole injection layer. For example, the deposition conditions may include a deposition temperature of about 100° C. to about 500° C., a vacuum pressure of about 10⁻⁸ torr to about 10⁻³ torr, and a deposition rate of about 0.01 Å/sec to about 100 Å/sec.

When the hole injection layer is formed using spin coating, coating conditions may vary according to the material used to form the hole injection layer, and the structure and thermal properties of the hole injection layer. For example, a coating speed may be from about 2,000 rpm to about 5,000 rpm, and a temperature at which a heat treatment is performed to remove a solvent after coating may be from about 80° C. to about 200° C. However, the coating conditions are not limited thereto.

Conditions for forming a hole transport layer and an electron blocking layer may be understood by referring to conditions for forming the hole injection layer.

The hole transport region may include at least one selected from m-MTDATA, TDATA, 2-TNATA, NPB, β-NPB, TPD, Spiro-TPD, Spiro-NPB, methylated-NPB, TAPC, HMTPD, 4,4′,4″-tris(N-carbazolyl)triphenylamine (TCTA), polyaniline/dodecylbenzene sulfonic acid (PANI/DBSA), poly(3,4-ethylenedioxythiophene)/poly(4-styrene sulfonate) (PEDOT/PSS), polyaniline/camphor sulfonic acid (PANI/CSA), polyaniline/poly(4-styrene sulfonate) (PANI/PSS), a compound represented by Formula 201, and a compound represented by Formula 202:

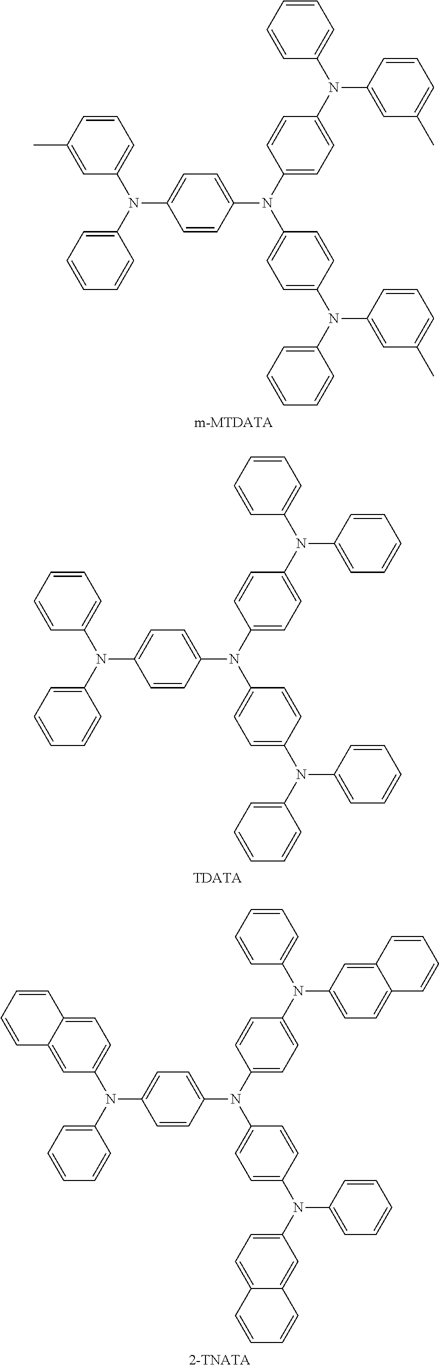

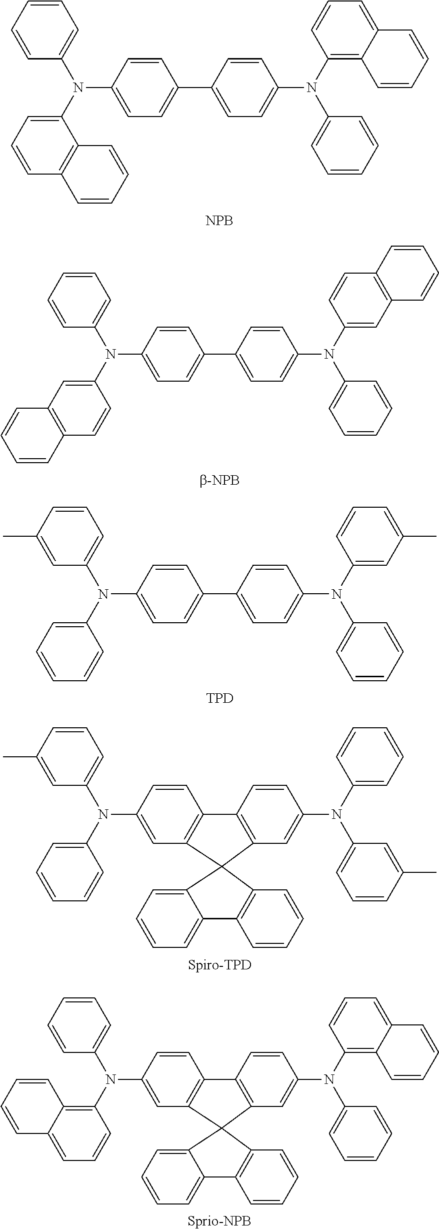

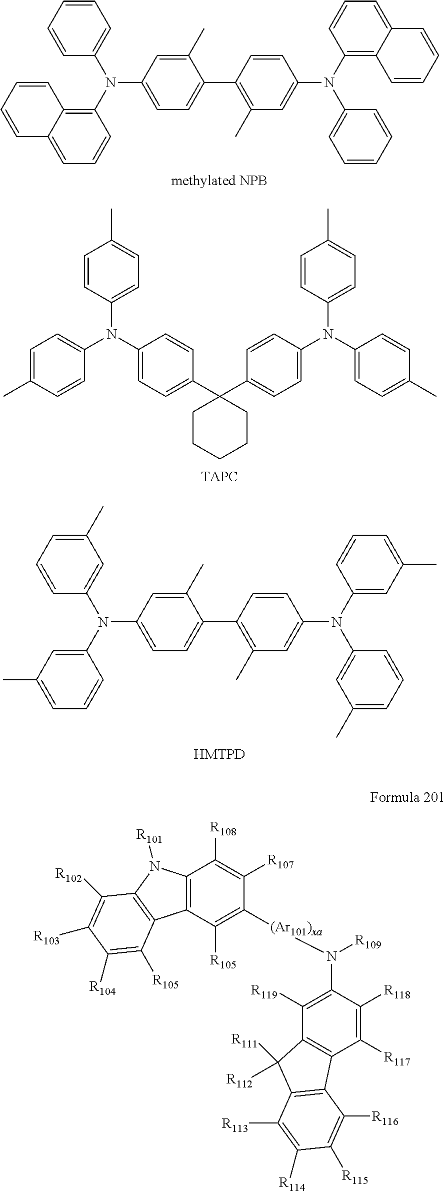

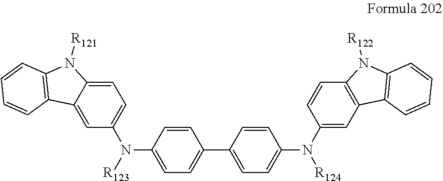

Ar₁₀₁ and A₁₀₂ in Formula 201 may each independently be selected from:

a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, and a pentacenylene group; and

a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, and a pentacenylene group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₆-C₆₀ aryloxy group, a C₆-C₆₀ arylthio group, a C₇-C₆₀ aryl alkyl group, a C₁-C₆₀ heteroaryl group, a C₁-C₆₀ heteroaryloxy group, a C₁-C₆₀ heteroarylthio group, a C₂-C₆₀ heteroaryl alkyl group, a monovalent non-aromatic condensed polycyclic group, and a monovalent non-aromatic condensed heteropolycyclic group.

In Formula 201, xa and xb may each independently be an integer from 0 to 5, or 0, 1 or 2. For example, xa may be 1 and xb may be 0, but xa and xb are not limited thereto.

In Formulae 201 and 202, R₁₀₁ to R₁₀₈, R₁₁₁ to R₁₁₉, and R₁₂₁ to R₁₂₄ may each independently be selected from:

hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group (for example, a methyl group, an ethyl group, a propyl group, a butyl group, a pentyl group, a hexyl group, and so on), or a C₁-C₁₀ alkoxy group (for example, a methoxy group, an ethoxy group, a propoxy group, a butoxy group, a pentoxy group, and so on);

a C₁-C₁₀ alkyl group and a C₁-C₁₀ alkoxy group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof;

a phenyl group, a naphthyl group, an anthracenyl group, a fluorenyl group, or a pyrenyl group; or

a phenyl group, a naphthyl group, an anthracenyl group, a fluorenyl group, and a pyrenyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, and a C₁-C₁₀ alkoxy group,

but embodiments of the present disclosure are not limited thereto.

R₁₀₉ in Formula 201 may be selected from:

a phenyl group, a naphthyl group, an anthracenyl group, and a pyridinyl group; and

a phenyl group, a naphthyl group, an anthracenyl group, and a pyridinyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a alkoxy group, a phenyl group, a naphthyl group, an anthracenyl group, and a pyridinyl group.

In an embodiment, the compound represented by Formula 201 may be represented by Formula 201A, but embodiments of the present disclosure are not limited thereto:

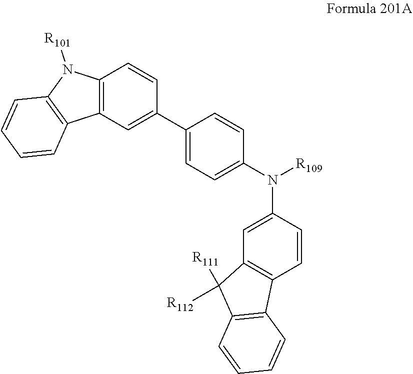

In Formula 201A, R₁₀₁, R₁₁₁, R₁₁₂, and R₁₀₉ may each independently be the same as described above.

For example, the compound represented by Formula 201, and the compound represented by Formula 202 may include compounds HT1 to HT20, but are not limited thereto.

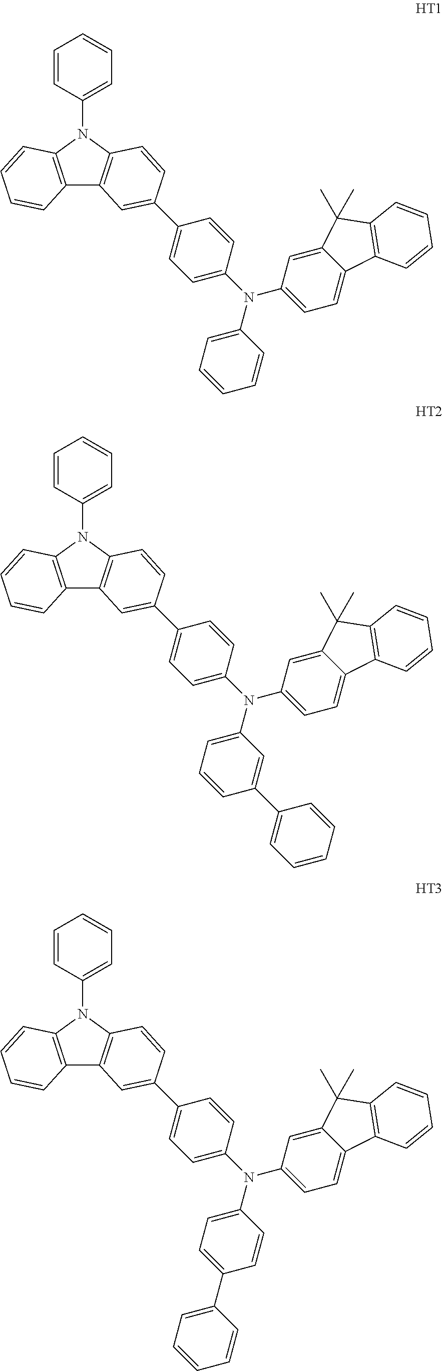 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

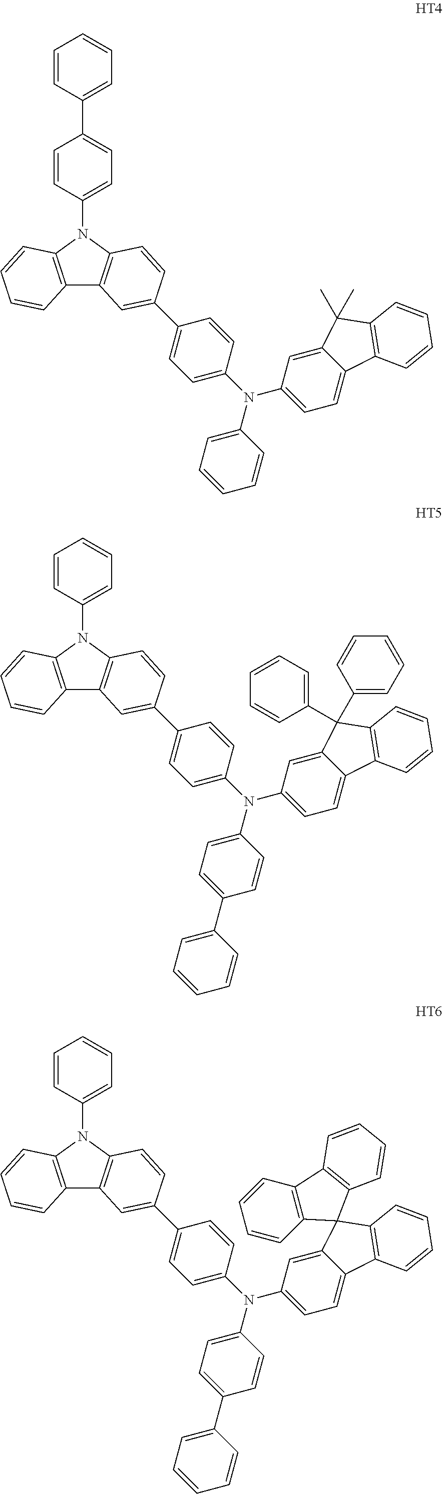 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

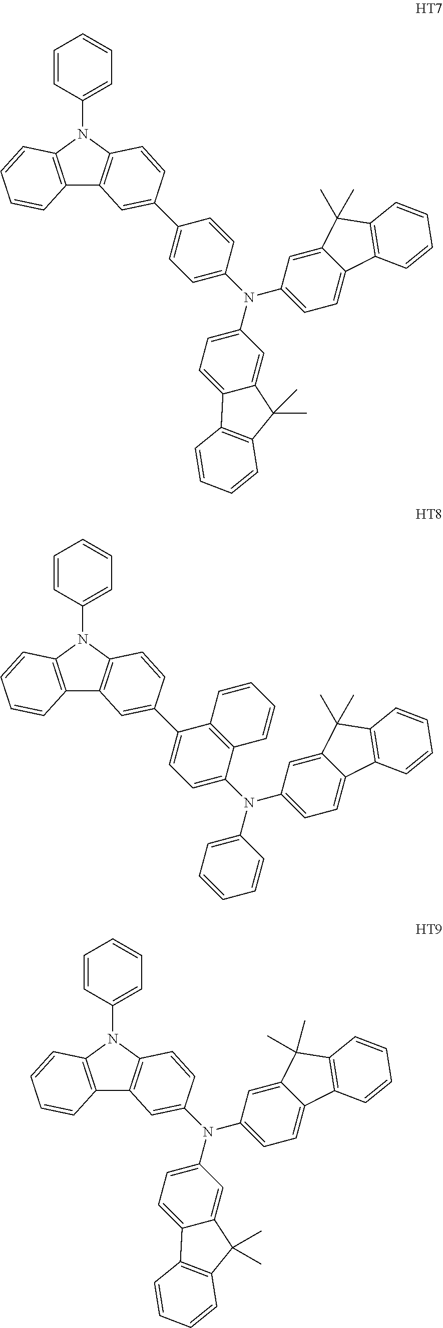 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

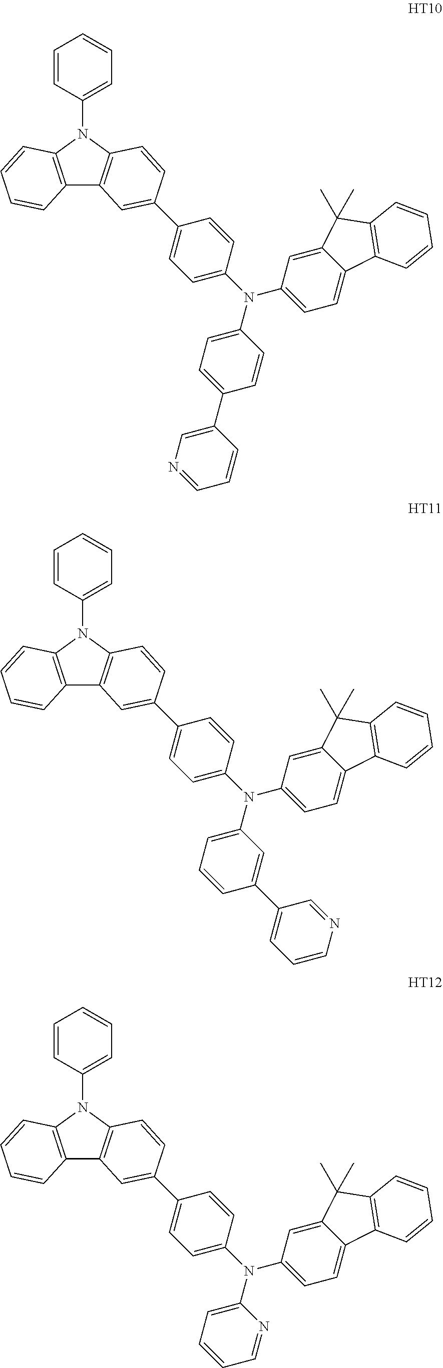 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

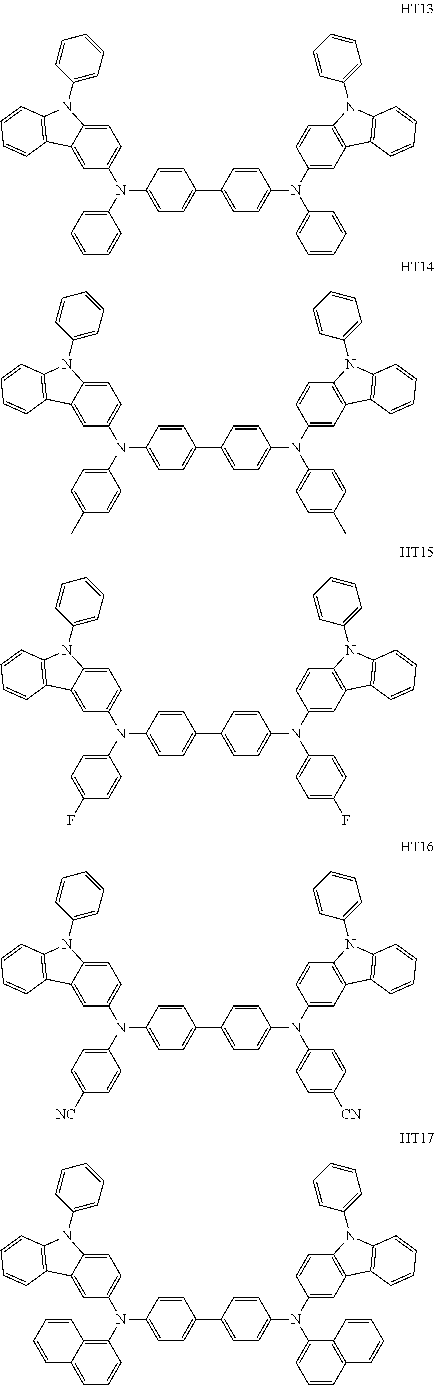

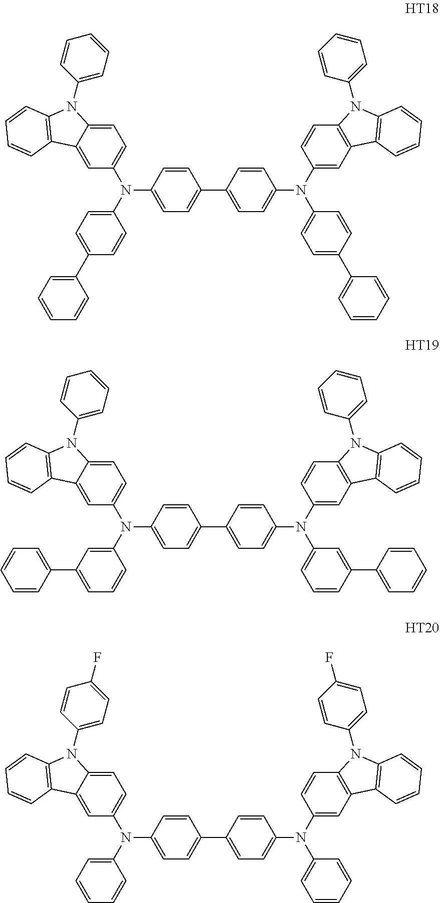 [SMILES: c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be in a range of about 100 Angstroms (Å) to about 10,000 Å, for example, about 100 Å to about 1,000 Å. When the hole transport region includes at least one of a hole injection layer and a hole transport layer, a thickness of the hole injection layer may be in a range of about 100 Å to about 10,000 Å, for example, about 100 Å to about 1,000 Å, and a thickness of the hole transport layer may be in a range of about 50 Å to about 2,000 Å, for example about 100 Å to about 1,500 Å. While not wishing to be bound by theory, it is understood that when the thicknesses of the hole transport region, the hole injection layer, and the hole transport layer are within these ranges, satisfactory hole transporting characteristics may be obtained without a substantial increase in driving voltage.

The hole transport region may further include, in addition to these materials, a charge-generation material for the improvement of conductive properties. The charge-generation material may be homogeneously or non-homogeneously dispersed in the hole transport region.

The charge-generation material may be, for example, a p-dopant. The p-dopant may be one selected from a quinone derivative, a metal oxide, and a cyano group-containing compound, but embodiments of the present disclosure are not limited thereto. Non-limiting examples of the p-dopant are a quinone derivative, such as tetracyanoquinonedimethane (TCNQ) or 2,3,5,6-tetrafluoro-tetracyano-1,4-benzoquinonedimethane (F4-TCNQ); a metal oxide, such as a tungsten oxide or a molybdenium oxide; and a cyano group-containing compound, such as Compound HT-D1 or HP-1, but are not limited thereto.

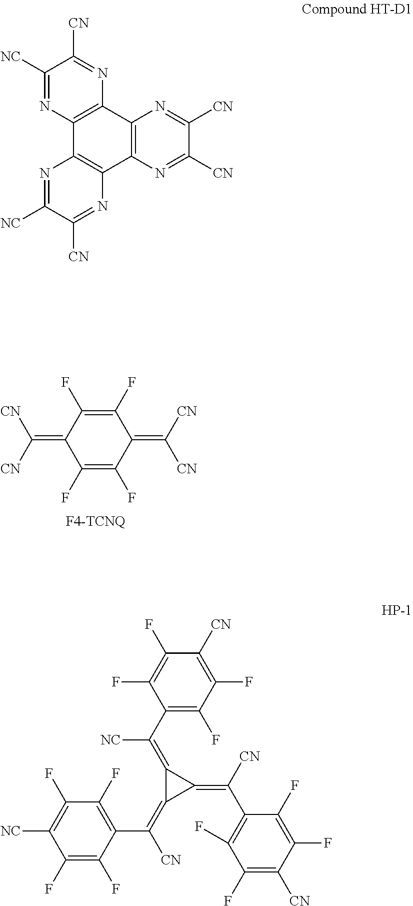

The hole transport region may include a buffer layer.

Also, the buffer layer may compensate for an optical resonance distance according to a wavelength of light emitted from the emission layer, and thus, efficiency of a formed organic light-emitting device may be improved.

The electron transport region may further include an electron blocking layer. The electron blocking layer may include, for example, mCP, but a material therefor is not limited thereto.

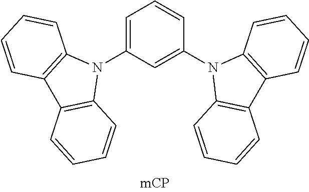 [SMILES: c1cc(-n2c3ccccc3c3ccccc32)cc(-n2c3ccccc3c3ccccc32)c1]

Then, an emission layer may be formed on the hole transport region by vacuum deposition, spin coating, casting, LB deposition, or the like. When the emission layer is formed by vacuum deposition or spin coating, the deposition or coating conditions may be similar to those applied in forming the hole injection layer although the deposition or coating conditions may vary according to a compound that is used to form the emission layer.

When the organic light-emitting device is a full-color organic light-emitting device, the emission layer may be patterned into a red emission layer, a green emission layer, and a blue emission layer. In one or more embodiments, due to a stacked structure including a red emission layer, a green emission layer, and/or a blue emission layer, the emission layer may emit white light.

The emission layer may include the thin film.

For example, the emission layer may have a single-layered structure including only the thin film, or a multi-layered structure further including other known emission layers.

A thickness of the emission layer may be in a range of about 100 Å to about 1,000 Å, for example, about 200 Å to about 600 Å. While not wishing to be bound by theory, it is understood that when the thickness of the emission layer is within this range, excellent light-emission characteristics may be obtained without a substantial increase in driving voltage.

Then, an electron transport region may be disposed on the emission layer.

The electron transport region may include a hole blocking layer, an electron transport layer, an electron injection layer, or any combination thereof.

For example, the electron transport region may have a hole blocking layer/electron transport layer/electron injection layer structure or an electron transport layer/electron injection layer structure, but the structure of the electron transport region is not limited thereto. The electron transport layer may have a single-layered structure or a multi-layered structure including two or more different materials.

Conditions for forming the hole blocking layer, the electron transport layer, and the electron injection layer which constitute the electron transport region may be understood by referring to the conditions for forming the hole injection layer.

When the electron transport region includes a hole blocking layer, the hole blocking layer may include, for example, at least one of BCP and Bphen, but may also include other materials.

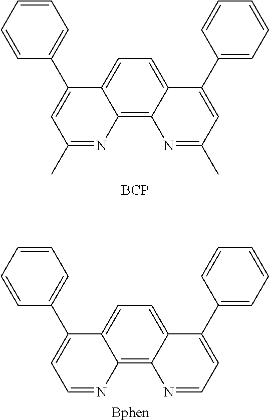

For example, as a material for the hole blocking layer, the first compound represented by Formula 1 may be used, but embodiments of the present disclosure are not limited thereto.

A thickness of the hole blocking layer may be in a range of about 20 Å to about 1,000 Å, for example, about 30 Å to about 300 Å. While not wishing to be bound by theory, it is understood that when the thickness of the hole blocking layer is within these ranges, the hole blocking layer may have excellent hole blocking characteristics without a substantial increase in driving voltage.

The electron transport layer may include at least one selected from BCP, Bphen, Alq₃, BAlq, TAZ, and NTAZ.

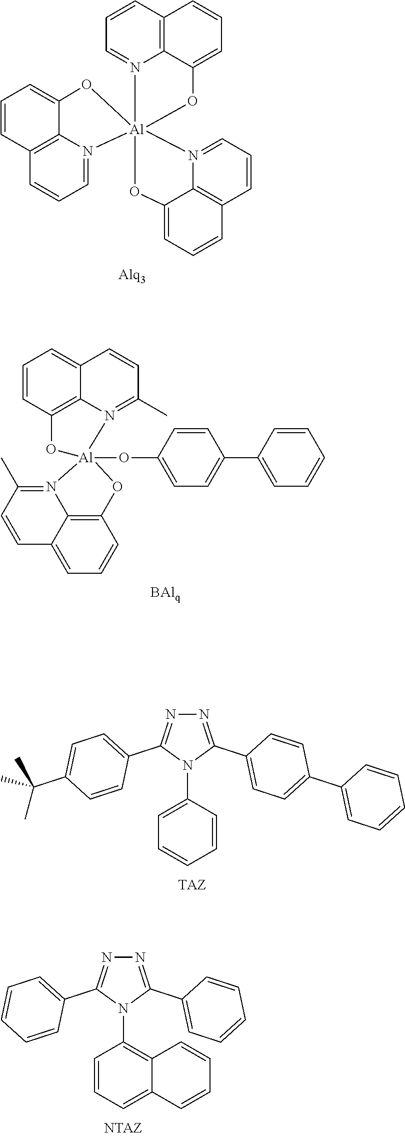

In one or more embodiments, the electron transport layer may include at least one of ET1 to ET25, but are not limited thereto:

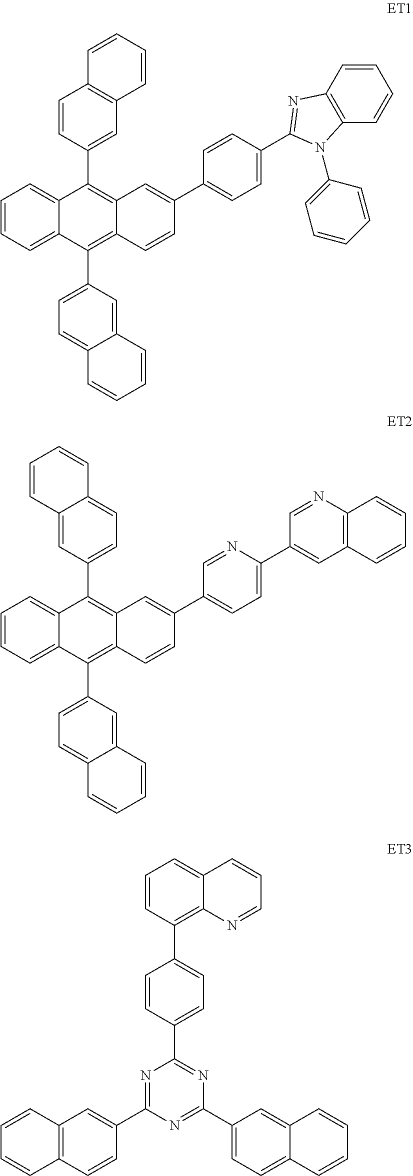 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6cccnc56)cc4)nc(-c4ccc5ccccc5c4)n3)ccc2c1]

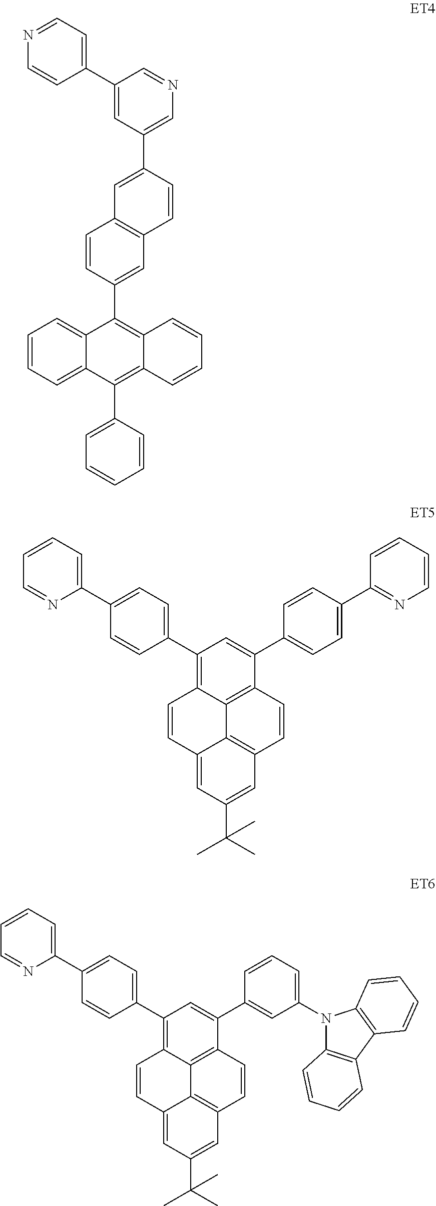 [SMILES: c1ccc(-c2c3ccccc3c(-c3ccc4cc(-c5cncc(-c6ccncc6)c5)ccc4c3)c3ccccc23)cc1 ; CC(C)(C)c1cc2ccc3c(-c4ccc(-c5ccccn5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4cccc(-n5c6ccccc6c6ccccc65)c4)c4ccc(c1)c2c34]

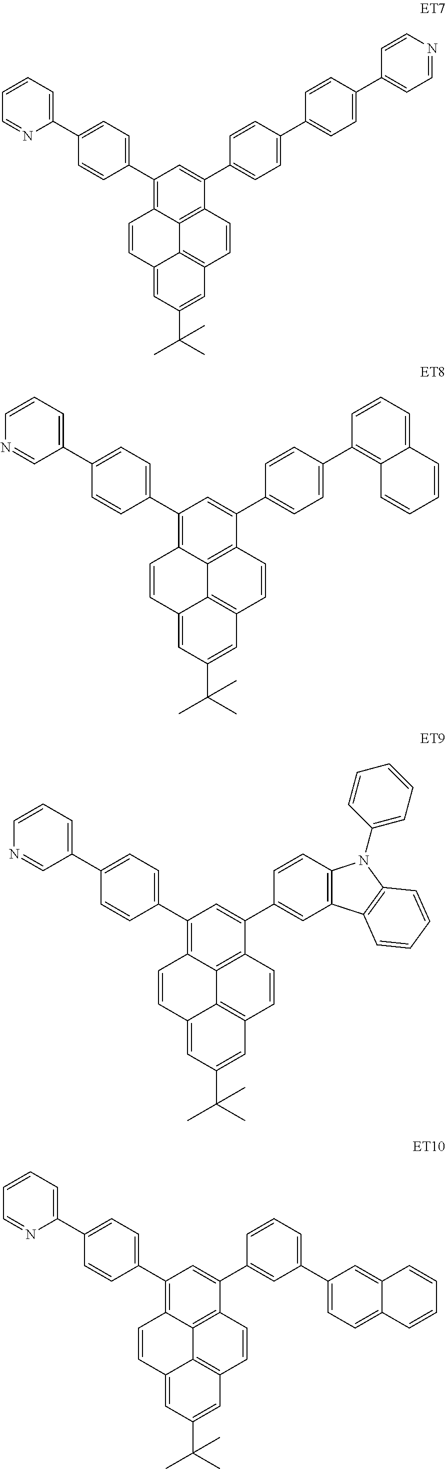 [SMILES: CC(C)(C)c1cc2ccc3c(-c4ccc(-c5ccc(-c6ccncc6)cc5)cc4)cc(-c4ccc(-c5ccccn5)cc4)c4ccc(c1)c2c34 ; CC(C)(C)c1cc2ccc3c(-c4ccc(-c5cccnc5)cc4)cc(-c4ccc(-c5cccc6ccccc56)cc4)c4ccc(c1)c2c34 ; CC(C)(C)c1cc2ccc3c(-c4ccc(-c5cccnc5)cc4)cc(-c4ccc5c(c4)c4ccccc4n5-c4ccccc4)c4ccc(c1)c2c34 ; CC(C)(C)c1cc2ccc3c(-c4ccc(-c5ccccn5)cc4)cc(-c4cccc(-c5ccc6ccccc6c5)c4)c4ccc(c1)c2c34]

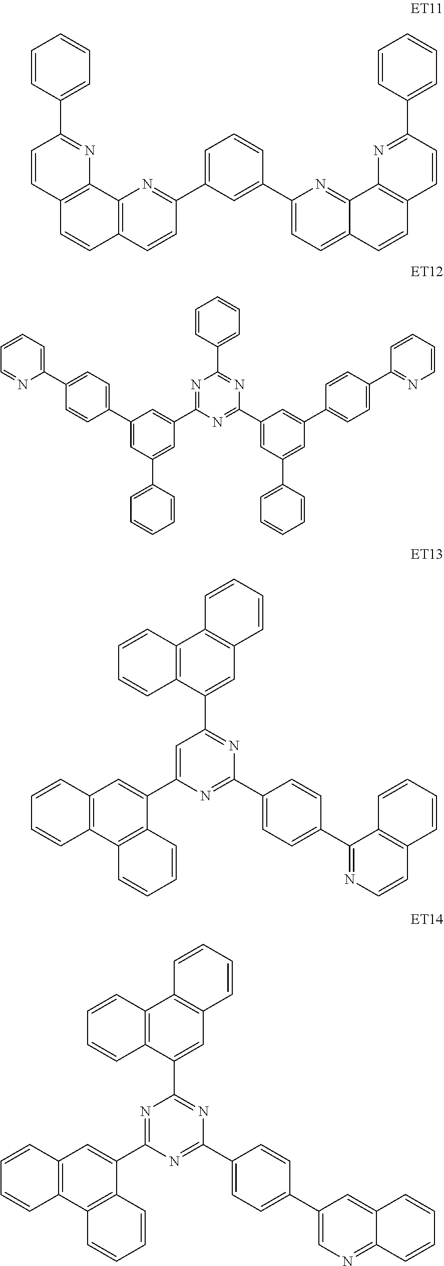 [SMILES: c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc(-c4ccccn4)cc3)cc(-c3nc(-c4ccccc4)nc(-c4cc(-c5ccccc5)cc(-c5ccc(-c6ccccn6)cc5)c4)n3)c2)cc1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

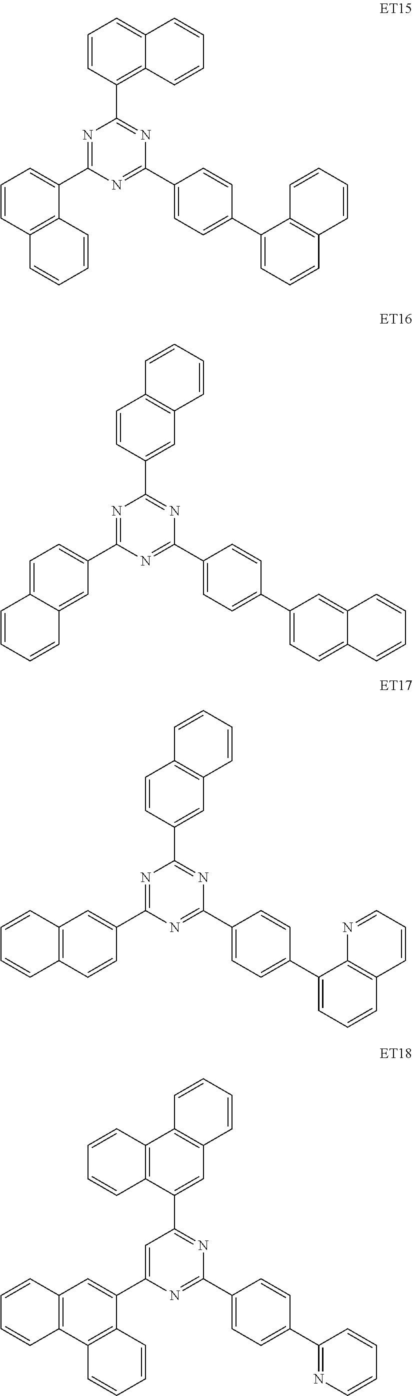 [SMILES: c1ccc2c(-c3ccc(-c4nc(-c5cccc6ccccc56)nc(-c5cccc6ccccc56)n4)cc3)cccc2c1 ; c1ccc2cc(-c3ccc(-c4nc(-c5ccc6ccccc6c5)nc(-c5ccc6ccccc6c5)n4)cc3)ccc2c1 ; c1ccc2cc(-c3nc(-c4ccc(-c5cccc6cccnc56)cc4)nc(-c4ccc5ccccc5c4)n3)ccc2c1 ; c1ccc(-c2ccc(-c3nc(-c4cc5ccccc5c5ccccc45)cc(-c4cc5ccccc5c5ccccc45)n3)cc2)nc1]

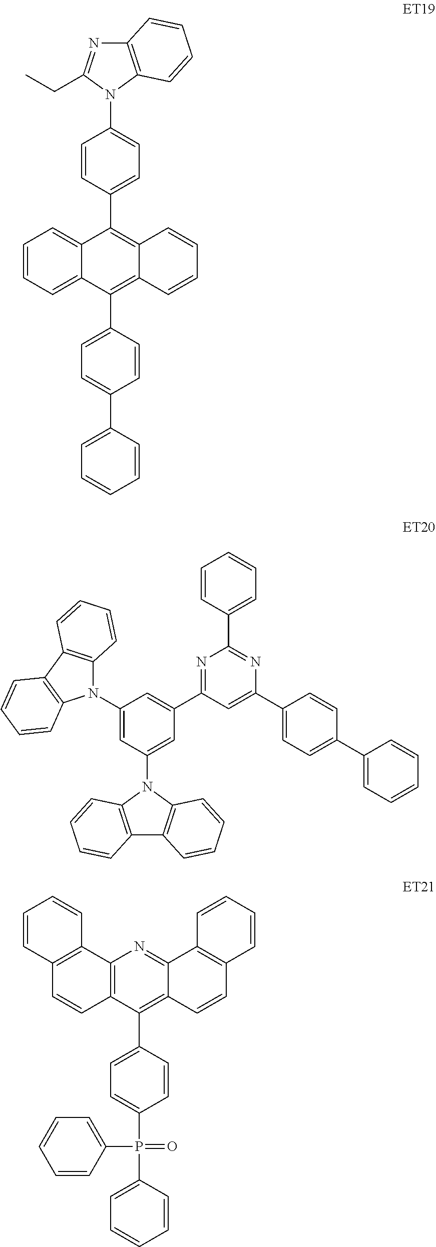

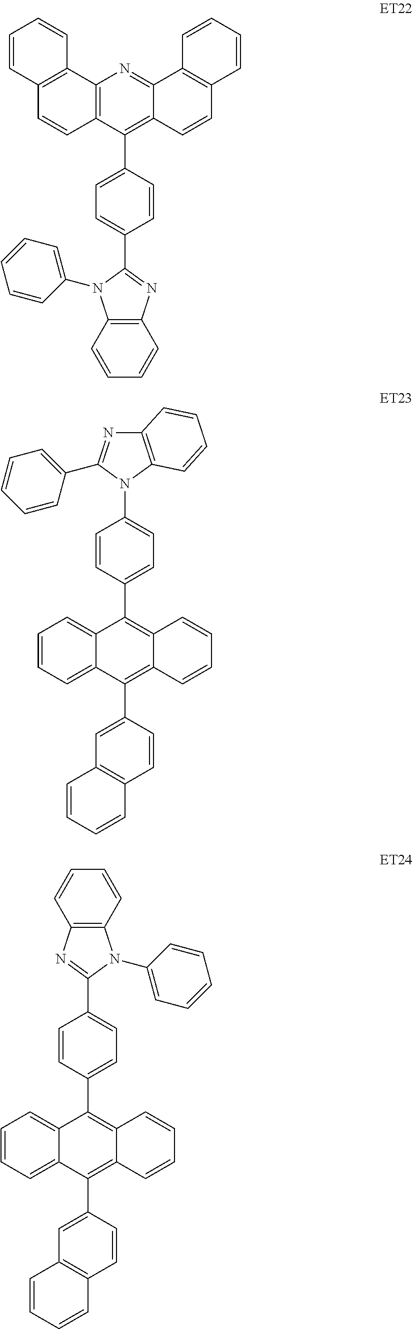

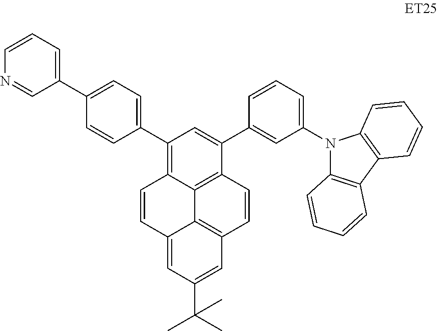 [SMILES: CC(C)(C)c1cc2ccc3c(-c4ccc(-c5cccnc5)cc4)cc(-c4cccc(-n5c6ccccc6c6ccccc65)c4)c4ccc(c1)c2c34]

A thickness of the electron transport layer may be in a range of about 100 Å to about 1,000 Å, for example, about 150 Å to about 500 Å. While not wishing to be bound by theory, it is understood that when the thickness of the electron transport layer is within the range described above, the electron transport layer may have satisfactory electron transport characteristics without a substantial increase in driving voltage.

Also, the electron transport layer may further include, in addition to the materials described above, a metal-containing material.

The metal-containing material may include a Li complex. The Li complex may include, for example, Compound ET-D1 (lithium 8-hydroxyquinolate, LiQ) or ET-D2.

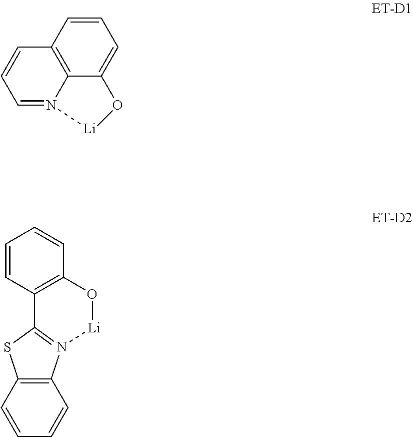

The electron transport region may include an electron injection layer (EIL) that promotes flow of electrons from the second electrode 19 thereinto.

The electron injection layer may include at least one selected from LiF, NaCl, CsF, Li₂O, and BaO.

A thickness of the electron injection layer may be in a range of about 1 Å to about 100 Å, and, for example, about 3 Å to about 90 Å. While not wishing to be bound by theory, it is understood that when the thickness of the electron injection layer is within the range described above, the electron injection layer may have satisfactory electron injection characteristics without a substantial increase in driving voltage.

The second electrode 19 is disposed on the organic layer 15. The second electrode 19 may be a cathode. A material for forming the second electrode 19 may be metal, an alloy, an electrically conductive compound, or a combination thereof, which have a relatively low work function. For example, lithium (Li), magnesium (Mg), aluminum (Al), aluminum-lithium (Al—Li), calcium (Ca), magnesium-indium (Mg—In), or magnesium-silver (Mg—Ag) may be formed as the material for forming the second electrode 19. To manufacture a top-emission type light-emitting device, a transmissive electrode formed using ITO or IZO may be used as the second electrode 19.

Hereinbefore, the organic light-emitting device has been described with reference to the FIGURE, but embodiments of the present disclosure are not limited thereto.

The term “C₁-C₆₀ alkyl group” as used herein refers to a linear or branched saturated aliphatic hydrocarbon monovalent group having 1 to 60 carbon atoms, and examples thereof include a methyl group, an ethyl group, a propyl group, an iso-butyl group, a sec-butyl group, a tert-butyl group, a pentyl group, an iso-amyl group, and a hexyl group. The term “C₁-C₆₀ alkylene group” as used herein refers to a divalent group having the same structure as the C₁-C₆₀ alkyl group.

The term “C₁-C₆₀ alkoxy group” as used herein refers to a monovalent group represented by -OA₁₀₁ (wherein A₁₀₁ is the C₁-C₆₀ alkyl group), and examples thereof include a methoxy group, an ethoxy group, and an iso-propyloxy group.

The term “C₂-C₆₀ alkenyl group” as used herein refers to a hydrocarbon group having at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group having at least one carbon-carbon triple bond in the middle or at the terminus of the C₂-C₆₀ alkyl group, and examples thereof include an ethynyl group, and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon monocyclic group having 3 to 10 carbon atoms, and examples thereof include a cyclopropyl group, a cyclobutyl group, a cyclopentyl group, a cyclohexyl group, and a cycloheptyl group. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent saturated monocyclic group having at least one heteroatom selected from N, O, P, Si and S as a ring-forming atom and 1 to 10 carbon atoms, and non-limiting examples thereof include a tetrahydrofuranyl group, and a tetrahydrothiophenyl group. The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein refers to a monovalent monocyclic group that has 3 to 10 carbon atoms and at least one carbon-carbon double bond in the ring thereof and no aromaticity, and non-limiting examples thereof include a cyclopentenyl group, a cyclohexenyl group, and a cycloheptenyl group. The term “C₃-C₁₀ cycloalkenylene group,” used herein, refers to a divalent group having the same structure as the C₃-C₁₀ cycloalkenyl group.

The term “C₁-C₁₀ heterocycloalkenyl group” as used herein refers to a monovalent monocyclic group that has at least one heteroatom selected from N, O, P, Si, and S as a ring-forming atom, 1 to 10 carbon atoms, and at least one double bond in its ring. Examples of the C₁-C₁₀ heterocycloalkenyl group are a 2,3-dihydrofuranyl group, and a 2,3-dihydrothiophenyl group. The term “C₁-C₁₀ heterocycloalkenylene group,” used herein, refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Examples of the C₆-C₆₀ aryl group are a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

The term “C₁-C₆₀ heteroaryl group” as used herein refers to a monovalent group having a heterocyclic aromatic system that has at least one heteroatom selected from N, O, P, Si, and S as a ring-forming atom, in addition to 1 to 60 carbon atoms. The term “C₁-C₆₀ heteroarylene group” as used herein refers to a divalent group having a heterocyclic aromatic system that has at least one heteroatom selected from N, O, P, Si, and S as a ring-forming atom, in addition to 1 to 60 carbon atoms. Examples of the C₁-C₆₀ heteroaryl group are a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include two or more rings, the rings may be fused to each other.

The term “C₆-C₆₀ aryloxy group” as used herein indicates -OA₁₀₂ (wherein A₁₀₂ is the C₆-C₆₀ aryl group), a C₆-C₆₀ arylthio group indicates -SA₁₀₃ (wherein A₁₀₃ is the C₆-C₆₀ aryl group), and the term “C₇-C₆₀ arylalkyl group” as used herein indicates -A₁₀₄A₁₀₅ (wherein A₁₀₅ is the C₆-C₅₉ aryl group and A₁₀₄ is the C₁-C₅₃ alkylene group).

The term “C₁-C₆₀ heteroaryloxy group” as used herein refers to -OA₁₀₆ (wherein A₁₀₆ is the C₂-C₆₀ heteroaryl group), the term “C₁-C₆₀ heteroarylthio group” as used herein indicates -SA₁₀₇ (wherein A₁₀₇ is the C₁-C₆₀ heteroaryl group), and the term “C₂-C₆₀ heteroarylalkyl group” as used herein refers to -A₁₀₈A₁₀₉ (A₁₀₉ is a C₁-C₅₉ heteroaryl group, and A₁₀₈ is a C₁-C₅₉ alkylene group).

The term “monovalent non-aromatic condensed polycyclic group” as used herein refers to a monovalent group having two or more rings condensed to each other, only carbon atoms (for example, the number of carbon atoms may be in a range of 8 to 60) as a ring-forming atom, and no aromaticity in its entire molecular structure. Non-limiting examples of the monovalent non-aromatic condensed polycyclic group include a fluorenyl group. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group having two or more rings condensed to each other, a heteroatom selected from N, O, P, Si, and S, other than carbon atoms (for example, the number of carbon atoms may be in a range of 2 to 60), as a ring-forming atom, and no aromaticity in its entire molecular structure. Non-limiting examples of the monovalent non-aromatic condensed heteropolycyclic group include a carbazolyl group. The term “divalent non-aromatic condensed heteropolycyclic group” as used herein refers to a divalent group having the same structure as the monovalent non-aromatic condensed heteropolycyclic group.

The term “C₅-C₃₀ carbocyclic group” as used herein refers to a saturated or unsaturated cyclic group having, as a ring-forming atom, 5 to 30 carbon atoms only. The term “C₅-C₃₀ carbocyclic group” as used herein refers to a monocyclic group or a polycyclic group, and, according to its chemical structure, a monovalent, divalent, trivalent, tetravalent, pentavalent, or hexavalent group.

The term “C₁-C₃₀ heterocyclic group” as used herein refers to a saturated or unsaturated cyclic group having, as a ring-forming atom, at least one heteroatom selected from N, O, Si, P, and S other than 1 to 30 carbon atoms. The term “C₁-C₃₀ heterocyclic group” as used herein refers to a monocyclic group or a polycyclic group, and, according to its chemical structure, a monovalent, divalent, trivalent, tetravalent, pentavalent, or hexavalent group.

At least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₇-C₆₀ aryl alkyl group, the substituted C₁-C₆₀ heteroaryl group, the substituted C₁-C₆₀ heteroaryloxy group, the substituted C₁-C₆₀ heteroarylthio group, the substituted C₂-C₆₀ heteroaryl alkyl group, the substituted monovalent non-aromatic condensed polycyclic group, and the substituted monovalent non-aromatic condensed heteropolycyclic group may be selected from:

deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ aryl alkyl group, a C₁-C₆₀ heteroaryl group, a C₁-C₆₀ heteroaryloxy group, a C₁-C₆₀ heteroarylthio group, a C₂-C₆₀ heteroaryl alkyl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —B(Q₁₆)(Q₁₇), and —P(═O)(Q₁₈)(Q₁₉);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ aryl alkyl group, a C₁-C₆₀ heteroaryl group, a C₁-C₆₀ heteroaryloxy group, a C₁-C₆₀ heteroarylthio group, a C₂-C₆₀ heteroaryl alkyl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ aryl alkyl group, a C₁-C₆₀ heteroaryl group, a C₁-C₆₀ heteroaryloxy group, a C₁-C₆₀ heteroarylthio group, a C₂-C₆₀ heteroaryl alkyl group, a monovalent non-aromatic condensed polycyclic group, and a monovalent non-aromatic condensed heteropolycyclic group, each substituted with at least one selected from deuterium, —F, —Cl, —Br, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C60 alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ aryl alkyl group, a C₁-C₆₀ heteroaryl group, a C₁-C₆₀ heteroaryloxy group, a C₁-C₆₀ heteroarylthio group, a C₂-C₆₀ heteroaryl alkyl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —B(Q₂₆)(Q₂₇), and —P(═O)(Q₂₈)(Q₂₉); and

—N(Q₃₁)(Q₃₂), —Si(Q₃₃)(Q₃₄)(Q₃₅), —B(Q₃₆)(Q₃₇), and —P(═O)(Q₃₈)(Q₃₉), and

Q₁ to Q₉, Q₁₁ to Q₁₉, Q₂₁ to Q₂₉, and Q₃₁ to Q₃₉ may each independently be selected from hydrogen, deuterium, —F, —Cl, —Br, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with at least one selected from a C₁-C₆₀ alkyl group, and a C₆-C₆₀ aryl group, a C₆-C₆₀ aryloxy group, a C₆-C₆₀ arylthio group, a C₇-C₆₀ aryl alkyl group, a C₁-C₆₀ heteroaryl group, a C₁-C₆₀ heteroaryloxy group, a C₁-C₆₀ heteroarylthio group, a C₂-C₆₀ heteroaryl alkyl group, a monovalent non-aromatic condensed polycyclic group, and a monovalent non-aromatic condensed heteropolycyclic group.

The term “room temperature” as used herein refers to about 25° C.

The term “biphenyl group” refers to a monovalent group in which two benzene groups are linked via a single bond.

The term “terphenyl group” refers to a monovalent group in which three benzene groups are linked via a single bond.

Hereinafter, a compound and an organic light-emitting device according to embodiments are described in detail with reference to Synthesis Example and Examples. However, the organic light-emitting device is not limited thereto. The wording “‘B’ was used instead of ‘A’” used in describing Synthesis Examples means that a molar equivalent of ‘A’ was identical to a molar equivalent of ‘B’.

### EXAMPLES

### Example 1

As an anode, a glass substrate, on which an ITO electrode was formed, was cut to a size of 50 mm×50 mm×0.5 mm (mm=millimeters), sonicated with acetone, iso-propyl alcohol, and pure water each for 15 minutes, and then cleaned by exposure to ultraviolet rays and ozone for 30 minutes.

Compound HT3 and HP-1 (concentration of HP-1:3 percent by weight, weight %) were co-deposited on the anode to form a hole injection layer having a thickness of 100 Å, Compound HT3 was deposited on the hole injection layer to form a hole transport layer having a thickness of 1,350 Å, and Compound H-1 was deposited on the hole transport layer to form an electron blocking layer having a thickness of 100 Å, thereby forming a hole transport region.

Compound E-1 and H-1 (weight ratio of 9:1) as a host and Compound D-1 (15 weight % based on the total weight of the host and the dopant) as a dopant were co-deposited on the hole transport region to form an emission layer having a thickness of 400 Å.

Compound E-1 was vacuum-deposited on the emission layer to form a hole blocking layer having a thickness of 100 Å, Compound ET17 and LiQ were co-deposited on the hole blocking layer at a weight ratio of 5:5 to form an electron transport layer having a thickness of 300 Å, LiQ was deposited on the electron transport layer to form an electron injection layer having a thickness of 10 Å, and AI was formed on the electron injection layer to a thickness of 1,000 Å, thereby completing the manufacture of an organic light-emitting device.

### Examples 2 to 4 and Comparative Examples 1 to 8

Organic light-emitting devices were manufactured in the same manner as in Example 1, except that a host and a dopant were changed as shown in Table 2 in forming an emission layer.

TABLE 2

| | |
|---|---|
| Host | Dopant |

| | First | Second | Third | Weight ratio of first compound | Weight ratio |
|---|---|---|---|---|---|
| | compound | compound | compound | to second compound | of dopant |
| Example 1 | E-1 | H-1 | D-1 | 9:1 | 15 |
| Example 2 | E-1 | H-3 | D-1 | 9:1 | 15 |
| Example 3 | E-1 | H-2 | D-4 | 7:3 | 15 |
| Example 4 | E-1 | H-3 | D-4 | 9:1 | 15 |
| Comparative | DPEPO | | D-1 | — | 15 |
| Example 1 | | | | | |
| Comparative | mCBP | | D-1 | — | 40 |
| Example 2 | | | | | |
| Comparative | E-1 | | D-1 | — | 15 |
| Example 3 | | | | | |
| Comparative | H-3 | PO-T2T | D-1 | 9:1 | 15 |
| Example 4 | | | | | |
| Comparative | DPEPO | | D-4 | — | 15 |
| Example 5 | | | | | |
| Comparative | mCBP | | D-4 | — | 40 |
| Example 6 | | | | | |
| Comparative | E-1 | | D-4 | — | 15 |
| Example 7 | | | | | |
| Comparative | H-3 | PO-T2T | D-4 | 9:1 | 15 |
| Example 8 | | | | | |

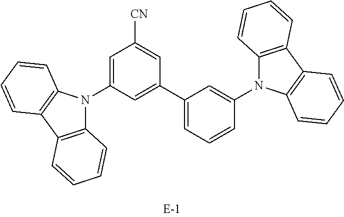 [SMILES: N#Cc1cc(-c2cccc(-n3c4ccccc4c4ccccc43)c2)cc(-n2c3ccccc3c3ccccc32)c1]

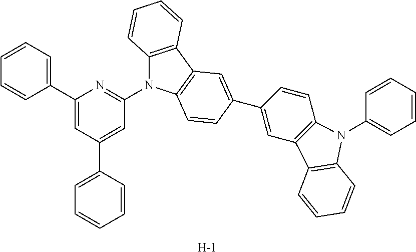

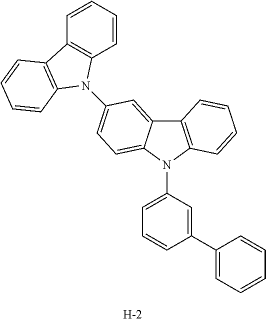

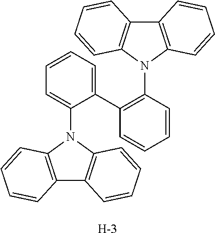

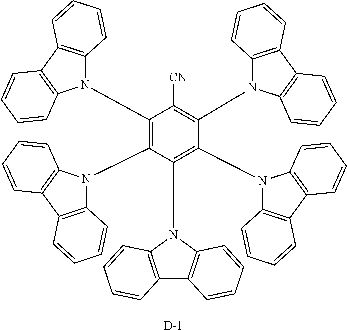

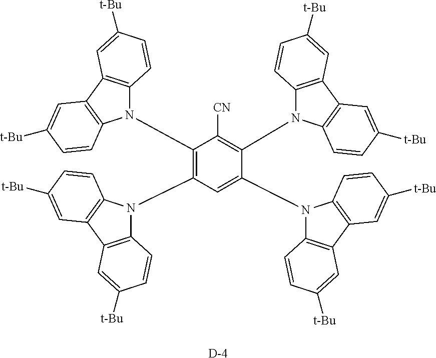

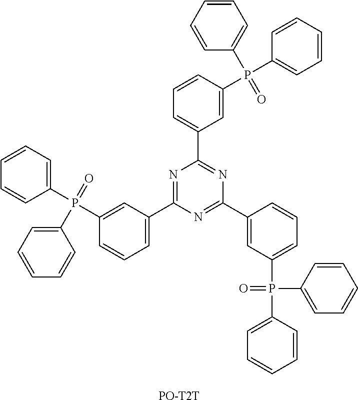 [SMILES: O=P(c1ccccc1)(c1ccccc1)c1cccc(-c2nc(-c3cccc(P(=O)(c4ccccc4)c4ccccc4)c3)nc(-c3cccc(P(=O)(c4ccccc4)c4ccccc4)c3)n2)c1 ; "PO-T2T"]

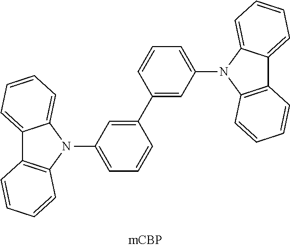 [SMILES: c1cc(-c2cccc(-n3c4ccccc4c4ccccc43)c2)cc(-n2c3ccccc3c3ccccc32)c1]

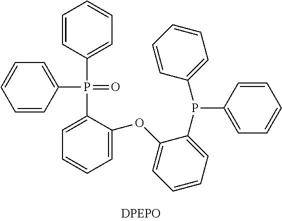 [SMILES: O=P(c1ccccc1)(c1ccccc1)c1ccccc1Oc1ccccc1P(c1ccccc1)c1ccccc1]

### Evaluation Example 1

### Evaluation of Device Characteristics

The driving voltage (at 10 candelas per square meter, cd/m²), maximum external quantum efficiency (EQEₘₐₓ), maximum power efficiency (PEₘₐₓ), luminance, external quantum efficiency (EQE, at 500 cd/m²), roll-off (roll-off, 1-(EQE/EQEₘₐₓ)), CIE color coordinates, and lifespan (T₅₀) characteristics of the organic light-emitting devices manufactured according to Examples 1 to 4 and Comparative Examples 1 to 8 were measured by using a current-voltage meter (Keithley 2400) and a luminance meter (Minolta Cs-1000A), and results thereof are shown in Table 3. T₅₀ (at 500 cd/m²) in Table 3 indicates lifespan data evaluating the amount of time that lapsed when luminance was 50% of initial luminance (100%).

TABLE 3

| | Host | | Dopant | Driving | | | | | Roll- | | | |
|---|---|---|---|---|---|---|---|---|---|---|---|---|
| | first | second | third | voltage | EQEₘₐₓ | PEₘₐₓ | Luminance | EQE | off | | | Lifespan |
| | compound | compound | compound | (V) | (%) | (lm/W) | (cd/m²) | (%) | (%) | CIEx | CIEy | (time) |
| Example 1 | E-1 | H-1 | D-1 | 3.12 | 19.6 | 51.4 | 500 | 15.8 | 19.4 | 0.20 | 0.36 | 770 |
| Example 2 | E-1 | H-3 | D-1 | 3.02 | 20.9 | 54.3 | 500 | 17.3 | 17.2 | 0.19 | 0.35 | 500 |
| Example 3 | E-1 | H-2 | D-4 | 3.16 | 20.7 | 32.6 | 500 | 20.1 | 2.9 | 0.16 | 0.22 | 225 |
| Example 4 | E-1 | H-3 | D-4 | 3.09 | 23.2 | 42.7 | 500 | 20.5 | 11.6 | 0.16 | 0.22 | 280 |
| Comparative | DPEPO | | D-1 | 4.23 | 17.7 | 33.1 | 500 | 11.5 | 35.0 | 0.19 | 0.34 | <1 |
| Example 1 | | | | | | | | | | | | |
| Comparative | mCBP | | D-1 | 3.69 | 19.8 | 50.0 | 500 | 14.6 | 26.3 | 0.22 | 0.42 | 34 |
| Example 2 | | | | | | | | | | | | |
| Comparative | E-1 | | D-1 | 2.99 | 19.7 | 46.2 | 500 | 15.0 | 23.9 | 0.19 | 0.33 | 180 |
| Example 3 | | | | | | | | | | | | |
| Comparative | H-3 | PO-T2T | D-1 | 3.21 | 16.1 | 44.8 | 500 | 14.3 | 11.2 | 0.26 | 0.47 | 4 |
| Example 4 | | | | | | | | | | | | |
| Comparative | DPEPO | | D-4 | 5.36 | 22.7 | 29.0 | 500 | 7.0 | 69.2 | 0.16 | 0.25 | <1 |
| Example 5 | | | | | | | | | | | | |
| Comparative | mCBP | | D-4 | 4.05 | 20.5 | 28.4 | 500 | 15.2 | 25.9 | 0.16 | 0.22 | 2 |
| Example 6 | | | | | | | | | | | | |
| Comparative | E-1 | | D-4 | 3.10 | 22.0 | 39.2 | 500 | 19.6 | 10.9 | 0.16 | 0.22 | 170 |
| Example 7 | | | | | | | | | | | | |
| Comparative | H-3 | PO-T2T | D-4 | 3.29 | 16.2 | 44.6 | 500 | 14.0 | 13.6 | 0.23 | 0.39 | 3 |
| Example 8 | | | | | | | | | | | | |

Referring to Table 3, it is confirmed that the organic light-emitting devices manufactured according to Examples 1 to 4 have high power efficiency, high quantum efficiency, and a long lifespan, as compared with the organic light-emitting devices manufactured according to Comparative Examples 1 to 8.

The organic light-emitting device including the thin film including the first compound, the second compound, and the third compound may have a low roll-off, high efficiency, and a long lifespan simultaneously.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the present description as defined by the following claims.

What is claimed is:

1. A composition comprising:
a first compound represented by Formula 1;
a second compound represented by Formula 2; a third compound satisfying Condition 1, and
the second compound is different from the first compound: 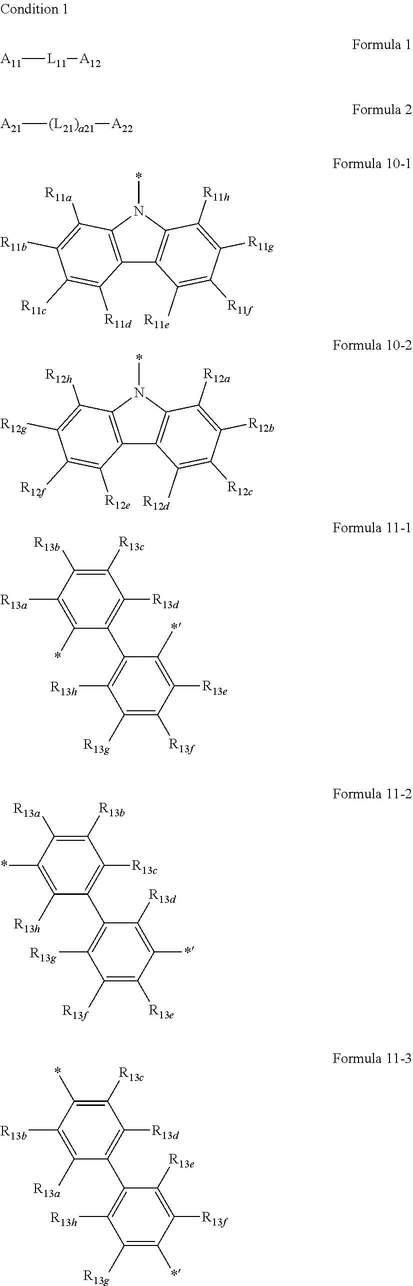 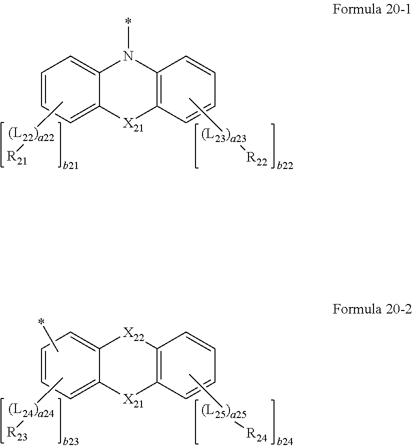
0 electron volts≤E_{S1}(C3)-E_{T1}(C3)≤0.3 electron volts,
wherein, in Condition 1,
E_{S1}(C3) is a lowest excitation singlet energy level of the third compound,
E_{T1}(C3) is a lowest excitation triplet energy level of the third compound, and
E_{S1}(C3) and E_{T1}(C3) are evaluated by using a DFT method structurally optimized at a level of B3LYP/6-31G(d,p),
in Formulae 1 and 2,
A₁₁ is a group represented by Formula 10-1,
A₁₂ is a group represented by Formula 10-2,
L₁₁ is a group represented by one selected from Formulae 11-1 to 11-3,
A₂₁ is a group represented by one selected from Formulae 20-1 and 20-2;
A22 is selected from groups represented by Formulae 20-1 and 20-2, a phenyl group, a naphthyl group, and a benzimidazolyl group; and
a phenyl group, a naphthyl group, and a benzimidazolyl group, each substituted with at least one selected from deuterium, a hydroxyl group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a carbazolyl group, a dibenzofuranyl group, and a dibenzothiophenyl group,
X₂₁ is selected from a single bond, C[(L₂₇)ₐ₂₇—R₂₆][(L₂₈)ₐ₂₈—R₂₇], O, and S,
X₂₂ is selected from N[(L₂₆)ₐ₂₆—R₂₅], C[(L₂₉)ₐ₂₉—R₂₈][(L₃₀)ₐ₃₀—R₂₉], O, and S,
L₂₁ to L₃₀ are each independently selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,
a₂₁ to a₃₀ are each independently selected from 0, 1, 2, 3, 4, and 5,
R₁₁ₐ to R₁₁ₕ, R₁₂ₐ to R₁₂ₕ, R₁₃ₐ to R₁₃ₕ, and R₂₁ to R₂₉ are each independently selected from hydrogen, deuterium, —F, —Cl, —Br, —I, a hydroxyl group, a cyano group (CN), a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ aryl alkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroaryl alkyl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₁)(Q₂), and —B(Q₁)(Q₂), two or more selected from R₂₁ to R₂₉ are optionally linked to form a ring,
at least one selected from R₁₁ₐ to R₁₁ₕ, R₁₂ₐ to R₁₂ₕ, and R₁₃ₐ to R₁₃ₕ is a cyano group,
b21, b22, and b24 are each independently selected from 1, 2, 3, and 4,
b23 is selected from 1, 2, and 3,
Q₁ to Q₃ are each independently selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, and a terphenyl group, and
* and *′ each indicate a binding site to a neighboring atom.

2. The composition of claim 1, wherein
one, two, or three selected from R₁₁ₐ to R₁₁ₕ, R₁₂ₐ to R₁₂ₕ, and R₁₃ₐ to R₁₃ₕ are a cyano group.

3. The composition of claim 1, wherein
R₁₁ₐ to R₁₁ₕ, R₁₂ₐ to R₁₂ₕ, and R₁₃ₐ to R₁₃ₕ are each independently selected from:
hydrogen, deuterium, a cyano group, a C₁-C₁₀ alkyl group, and a C₁-C₁₀ alkoxy group;
a C₁-C₁₀ alkyl group and a C₁-C₁₀ alkoxy group, each substituted with at least one selected from deuterium and a cyano group;
a phenyl group, a biphenyl group, a terphenyl group, a naphthyl group, a fluorenyl group, a pyridinyl group, a pyrazinyl group, a pyrimidinyl group, a carbazolyl group, a dibenzofuranyl group, and a dibenzothiophenyl group; and
a phenyl group, a biphenyl group, a terphenyl group, a naphthyl group, a fluorenyl group, a pyridinyl group, a carbazolyl group, a dibenzofuranyl group, and a dibenzothiophenyl group, each substituted with at least one selected from deuterium, a cyano group, a C₁-C₁₀ alkyl group, a C₁-C₁₀ alkoxy group, a phenyl group, a biphenyl group, a terphenyl group, a naphthyl group, a fluorenyl group, a pyridinyl group, a pyrazinyl group, a pyrimidinyl group, a carbazolyl group, a dibenzofuranyl group, and a dibenzothiophenyl group.

4. The composition of claim 1, wherein
A₁₁ is represented by Formula 10-11, A₁₂ is represented by Formula 10-21, and is represented by one selected from Formulae 11-15 to 11-22, 11-27 to 11-34, and 11-37 to 11-40;
A₁₁ is represented by one selected from Formulae 10-12 and 10-13, A₁₂ is represented by one selected from Formulae 10-21 to 10-23, and L₁₁ is represented by one selected from Formulae 11-11 to 11-40; or
A₁₁ is represented by Formula 10-11, A₁₂ is represented by one selected from Formulae 10-22 and 10-23, and L₁₁ is represented by one selected from Formulae 11-11 to 11-40: 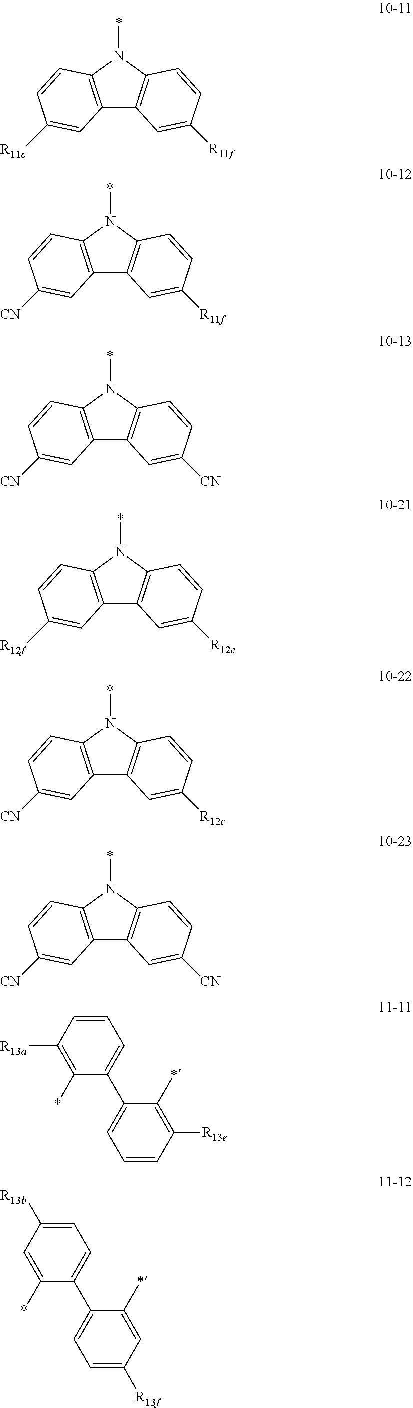 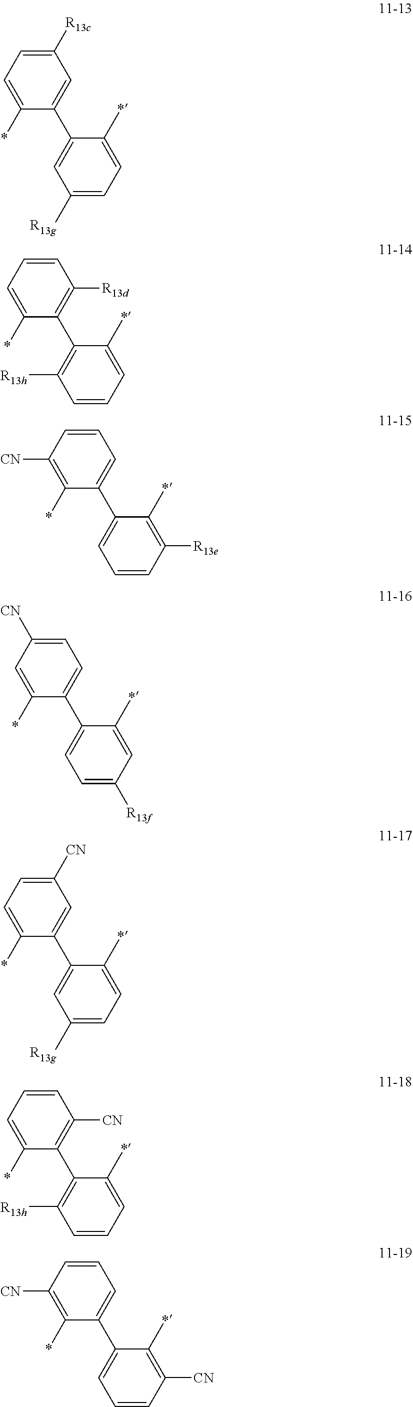 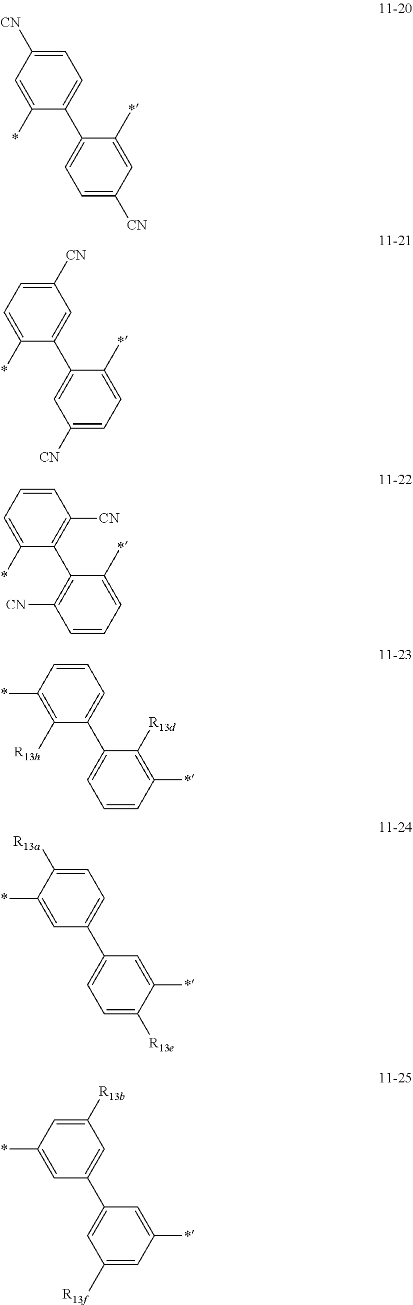 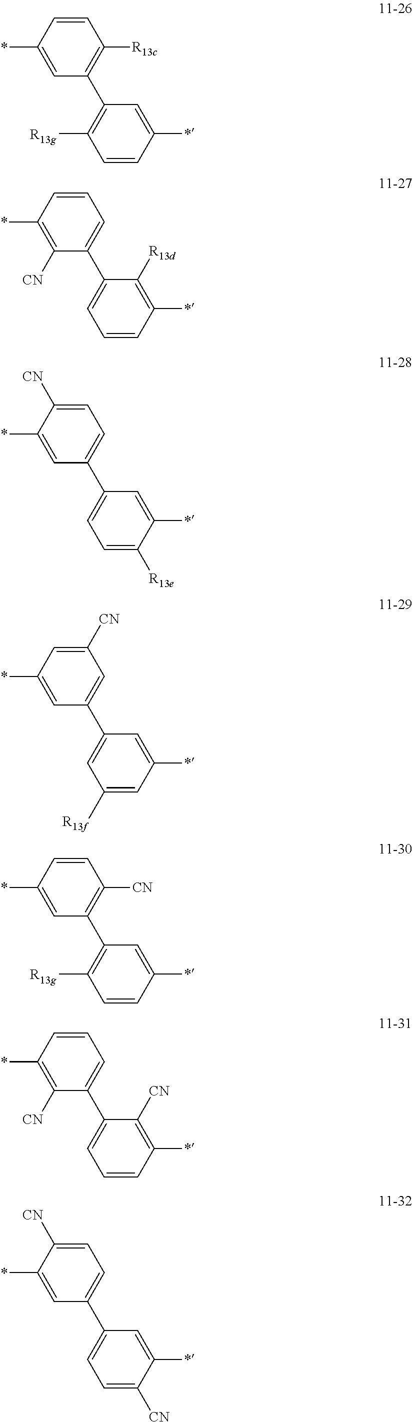 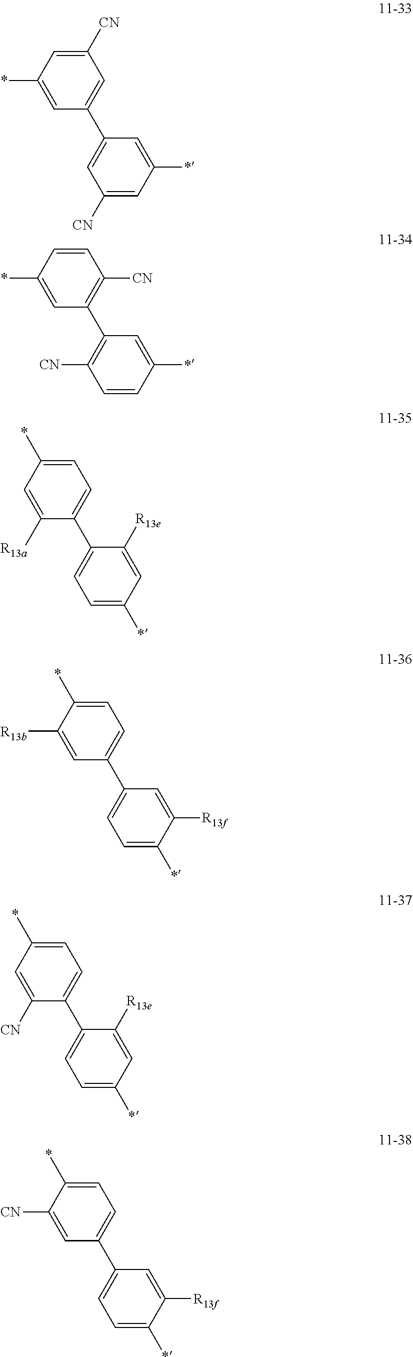 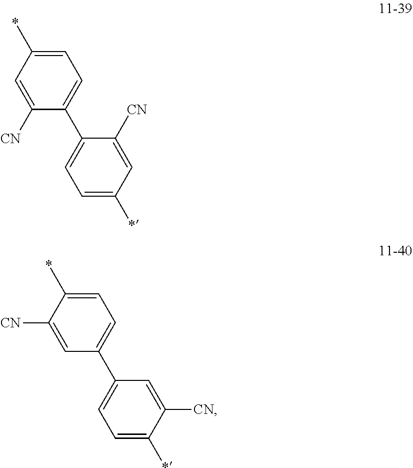
wherein, in Formulae 10-11 to 10-13, 10-21 to 10-23, and 11-11 to 11-40,
R_{12c}, R_{12f}, and R₁₃ₐ to R_{13f} are each independently selected from:
hydrogen, deuterium, a C₁-C₁₀ alkyl group, a C₁-C₁₀ alkoxy group, a phenyl group, a biphenyl group, a terphenyl group, a naphthyl group, a fluorenyl group, a pyridinyl group, a pyrazinyl group, a pyrimidinyl group, a carbazolyl group, a dibenzofuranyl group, and a dibenzothiophenyl group;
a C₁-C₁₀ alkyl group and a C₁-C₁₀ alkoxy group, each substituted with deuterium; and
a phenyl group, a biphenyl group, a terphenyl group, a naphthyl group, a fluorenyl group, a pyridinyl group, a pyrazinyl group, a pyrimidinyl group, a carbazolyl group, a dibenzofuranyl group, and a dibenzothiophenyl group, each substituted with at least one selected from deuterium, a C₁-C₁₀ alkyl group, a C₁-C₁₀ alkoxy group, a phenyl group, a biphenyl group, a terphenyl group, a naphthyl group, a fluorenyl group, a pyridinyl group, a pyrazinyl group, a pyrimidinyl group, a carbazolyl group, a dibenzofuranyl group, and a dibenzothiophenyl group, and
* and *′ each indicate a binding site to a neighboring atom.

5. The composition of claim 1, wherein
the first compound is selected from Compounds E-1 to E-20:

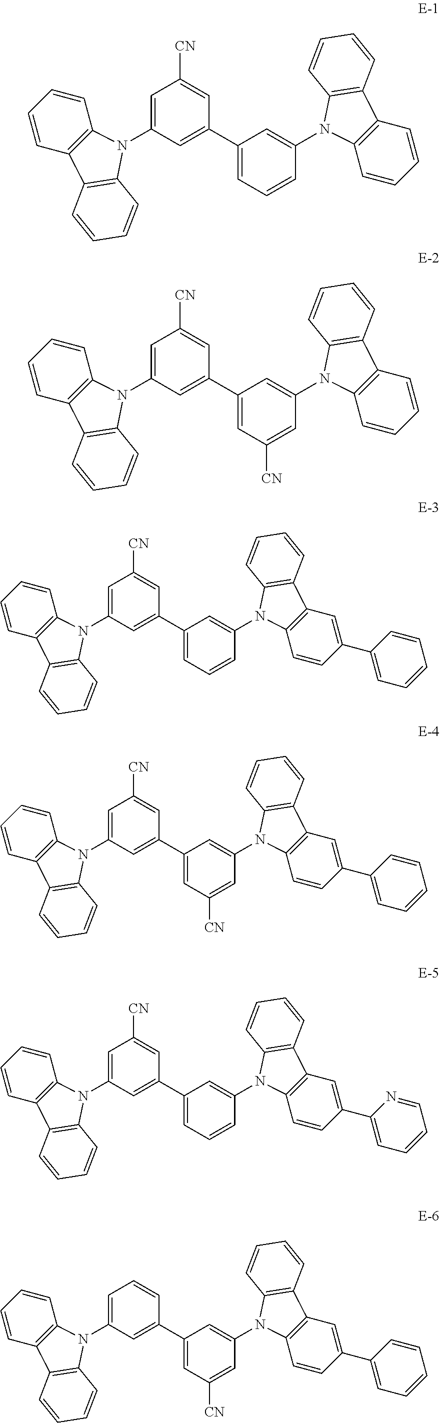 [SMILES: N#Cc1cc(-c2cccc(-n3c4ccccc4c4ccccc43)c2)cc(-n2c3ccccc3c3ccccc32)c1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4cc(-c5ccccc5)ccc43)c2)cc(-n2c3ccccc3c3ccccc32)c1 ; N#Cc1cc(-c2cc(C#N)cc(-n3c4ccccc4c4cc(-c5ccccc5)ccc43)c2)cc(-n2c3ccccc3c3ccccc32)c1 ; N#Cc1cc(-c2cccc(-n3c4ccccc4c4cc(-c5ccccn5)ccc43)c2)cc(-n2c3ccccc3c3ccccc32)c1 ; N#Cc1cc(-c2cccc(-n3c4ccccc4c4ccccc43)c2)cc(-n2c3ccccc3c3cc(-c4ccccc4)ccc32)c1]

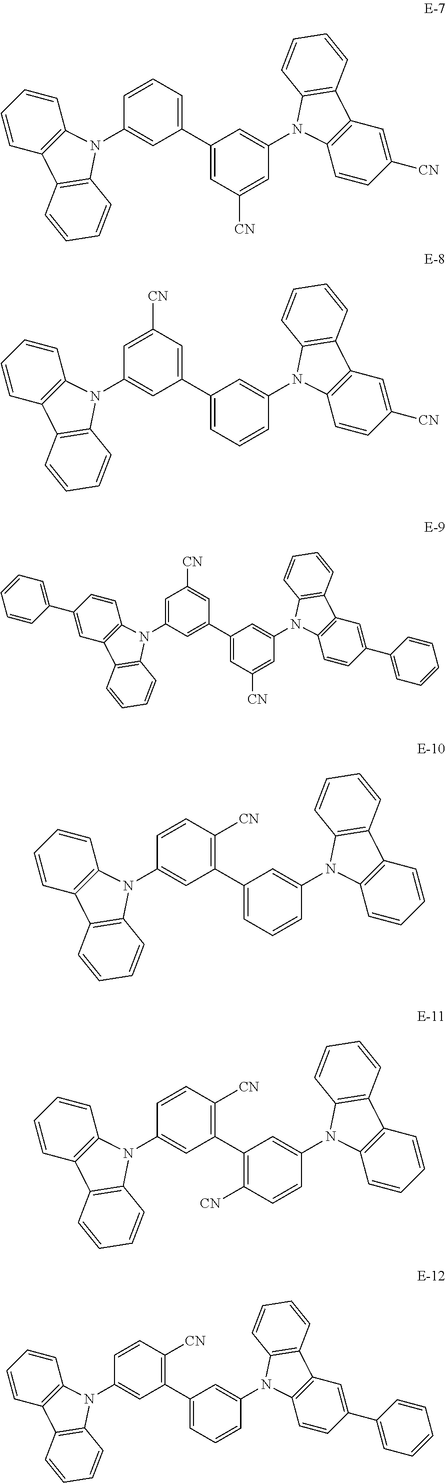

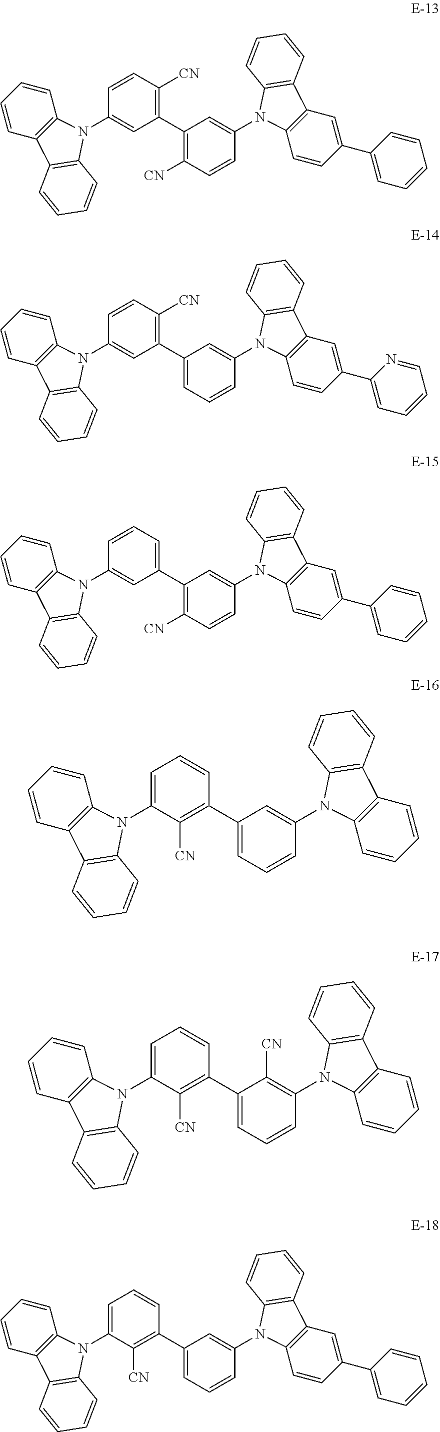

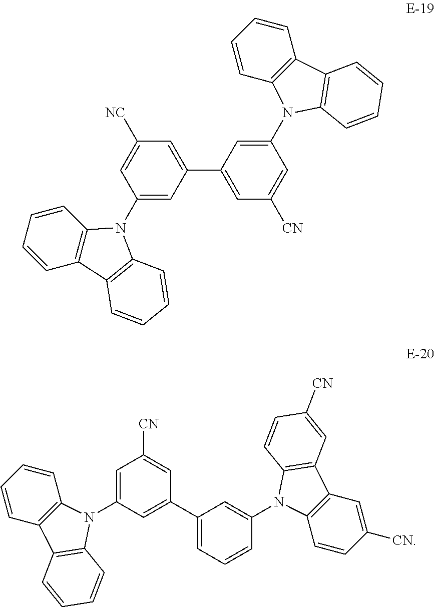 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccc(C#N)cc4c4cc(C#N)ccc43)c2)cc(-n2c3ccccc3c3ccccc32)c1]

6. The composition of claim 1, wherein
A₂₁ and A₂₂ are each independently represented by Formula 20-1;
A₂₁ is represented by Formula 20-1, and A₂₂ is represented by Formula 20-2; or
A₂₁ and A₂₂ are each independently represented by Formula 20-2.

7. The composition of claim 1, wherein
X₂₁ is a single bond, and
X₂₂ is selected from N(R₂₅), C(R₂₈)(R₂₉), O, and S.

8. The composition of claim 1, wherein
R₂₁ to R₂₉ are each independently selected from:
hydrogen, deuterium, —F, —Cl, —Br, —I, a cyano group, a C₁-C₁₀ alkyl group, a C₁-C₁₀ alkoxy group, a C₃-C₁₀ cycloalkyl group, and a C₁-C₁₀ heterocycloalkyl group;
a C₁-C₁₀ alkyl group, a C₁-C₁₀ alkoxy group, a C₃-C₁₀ cycloalkyl group, and a C₁-C₁₀ heterocycloalkyl group, each substituted with at least one selected from deuterium, —F, —Cl, —Br, —I, and a cyano group;
a C₆-C₃₀ aryl group, a biphenyl group, a terphenyl group, a C₆-C₃₀ aryloxy group, a C₆-C₃₀ arylthio group, a C₇-C₆₀ aryl alkyl group, a C₁-C₃₀ heteroaryl group, a C₁-C₆₀ heteroaryloxy group, a C₁-C₆₀ heteroarylthio group, a C₂-C₆₀ heteroaryl alkyl group, a monovalent non-aromatic condensed polycyclic group, and a monovalent non-aromatic condensed heteropolycyclic group;
a C₆-C₃₀ aryl group, a biphenyl group, a terphenyl group, a C₆-C₃₀ aryloxy group, a C₆-C₃₀ arylthio group, a C₇-C₆₀ aryl alkyl group, a C₁-C₃₀ heteroaryl group, a C₁-C₆₀ heteroaryloxy group, a C₁-C₆₀ heteroarylthio group, a C₂-C₆₀ heteroaryl alkyl group, a monovalent non-aromatic condensed polycyclic group, and a monovalent non-aromatic condensed heteropolycyclic group, each substituted with at least one selected from deuterium, —F, —Cl, —Br, —I, a cyano group, a C₁-C₁₀ alkyl group, a C₁-C₁₀ alkoxy group, a C₃-C₁₀ cycloalkyl group, a C₁-C₁₀ heterocycloalkyl group, a C₆-C₃₀ aryl group, a biphenyl group, a terphenyl group, a C₆-C₃₀ aryloxy group, a C₆-C₃₀ arylthio group, a C₇-C₆₀ aryl alkyl group, a C₁-C₃₀ heteroaryl group, a C₁-C₆₀ heteroaryloxy group, a C₁-C₆₀ heteroarylthio group, a C₂-C₆₀ heteroaryl alkyl group, a monovalent non-aromatic condensed polycyclic group, and a monovalent non-aromatic condensed heteropolycyclic group; and
—Si(Q₁)(Q₂)(Q₃), —N(Q₁)(Q₂), and —B(Q₁)(Q₂),
two or more selected from R₂₁ to R₂₉ are optionally linked to form a ring, and
Q₁ to Q₃ are each independently selected from hydrogen, a C₁-C₁₀ alkyl group, a C₆-C₃₀ aryl group, a biphenyl group, a terphenyl group, a C₁-C₃₀ heteroaryl group, a monovalent non-aromatic condensed polycyclic group, and a monovalent non-aromatic condensed heteropolycyclic group.

9. The composition of claim 1, wherein
the group represented by Formula 20-2 is a group represented by one selected from Formulae 20-21 to 20-24: 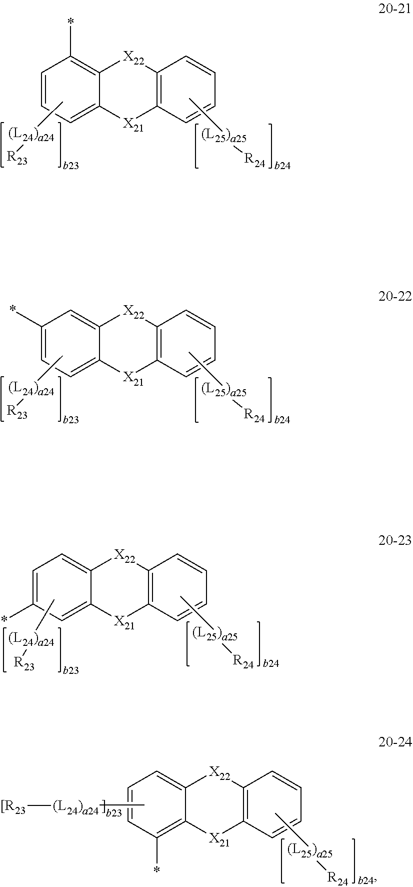
wherein, in Formulae 20-21 to 20-24,
X₂₁, X₂₂, L₂₄, L₂₅, a24, a25, R₂₃, R₂₄, b23 and b24 are each independently the same as defined in Formula 20-2, and
* indicates a binding site to a neighboring atom.

10. The composition of claim 1, wherein
the second compound is represented by one selected from Formulae 2-1 to 2-3: 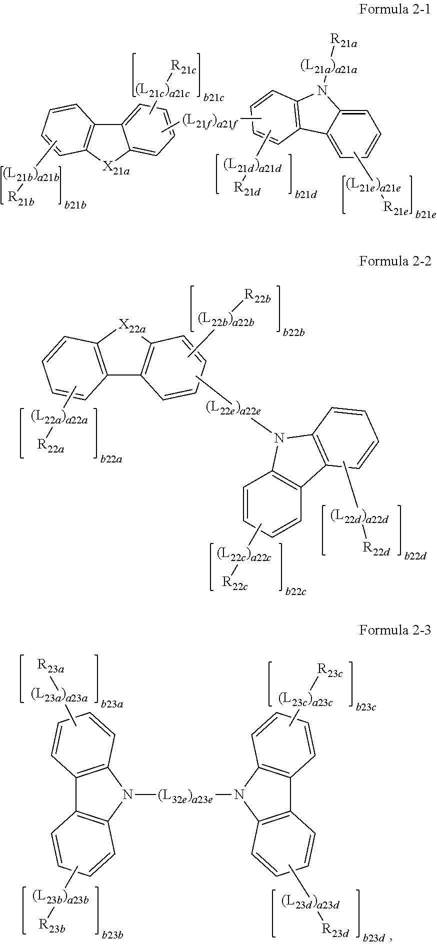
wherein, in Formulae 2-1 to 2-3,
X₂₁ₐ is selected from N[(L_{21g})_{a21g}—R_{21f}], O, and S, and X₂₂ₐ is selected from N[(L_{22f})_{a22f}—R₂₂ₑ], O, and S,
L₂₁ₐ to L_{21g}, L₂₂ₐ to L_{22f}, and L₂₃ₐ to L₂₃ₑ are each independently the same as described in connection with L₂₁ in Formula 2,
a21a to a21g, a22a to a22f, and a23a to a23e are each independently the same as described in connection with a21 in Formula 2,
R₂₁ₐ to R_{21f}, R₂₂ₐ to R₂₂ₑ, and R₂₃ₐ to R_{23d} are each independently the same as described in connection with R₂₁ in Formula 2,
b21b, b21e, b22a, b22c, b22d, and b23a to b23d are each independently the same as described in connection with b21 in Formula 2, and
b21c, b21d, and b22b are each independently the same as described in connection with b23 in Formula 2.

11. The composition of claim 10, wherein
(L₂₃ₑ)ₐ₂₃ₑ is selected from Formulae 9-1 to 9-6: 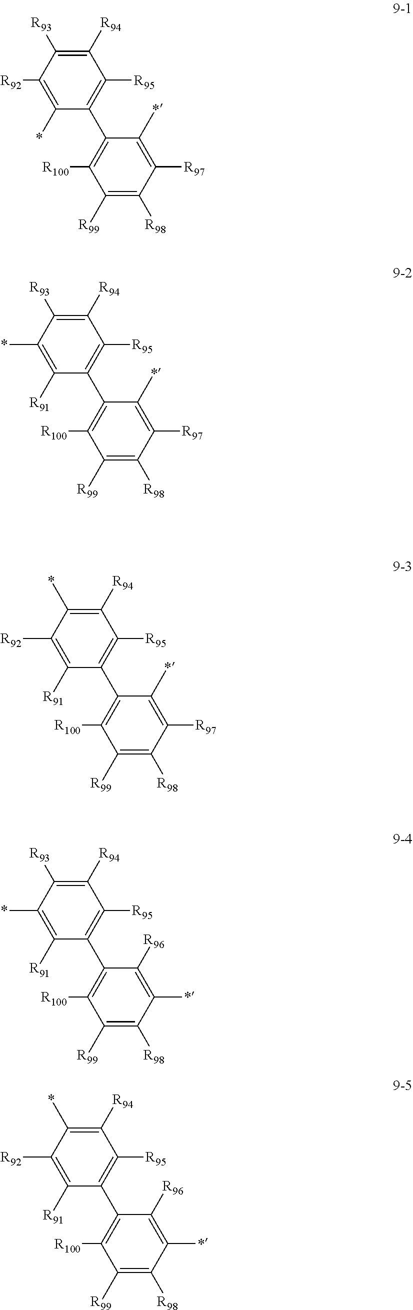 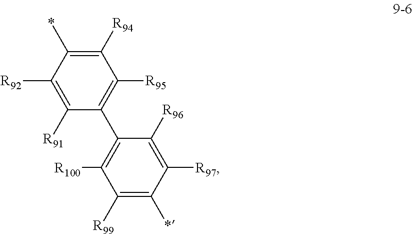
wherein, in Formulae 9-1 to 9-6,
R₉₁ to R₁₀₀ are each independently selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a biphenyl group, a terphenyl group, a C₁-C₆₀ heteroaryl group, a monovalent non-aromatic condensed polycyclic group, a monovalent non-aromatic condensed heteropolycyclic group, and —Si(Q₃₁)(Q₃₂)(Q₃₃), and
Q₃₁ to Q₃₃ are each independently selected from hydrogen, a C₁-C₁₀ alkyl group, a C₆-C₃₀ aryl group, a biphenyl group, a terphenyl group, a C₁-C₃₀ heteroaryl group, a monovalent non-aromatic condensed polycyclic group, and a monovalent non-aromatic condensed heteropolycyclic group.

12. The composition of claim 1, wherein
the second compound is represented by one selected from Formulae 2-11, 2-21, and 2-31 to 2-33: 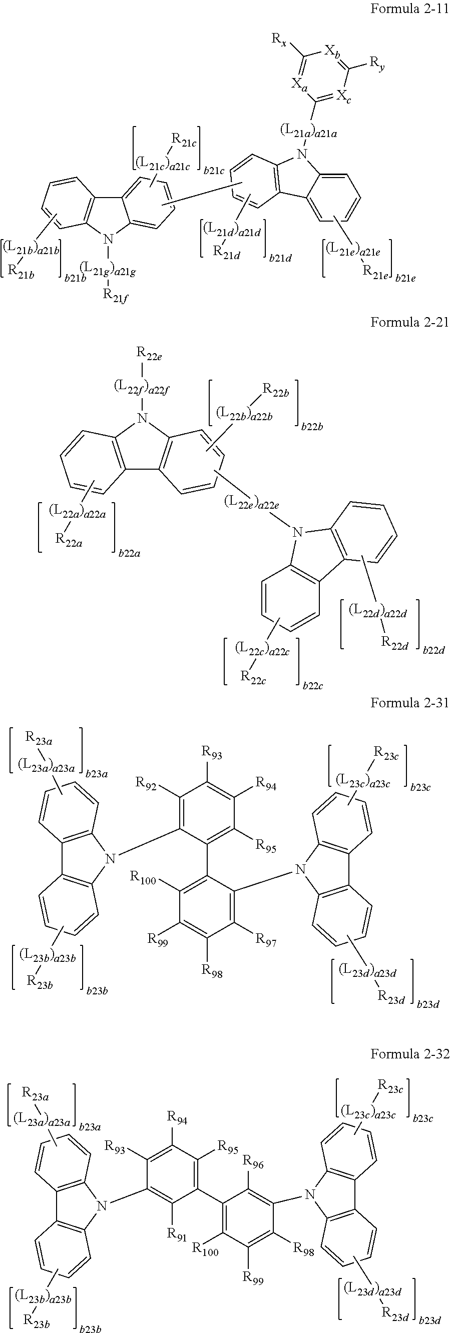 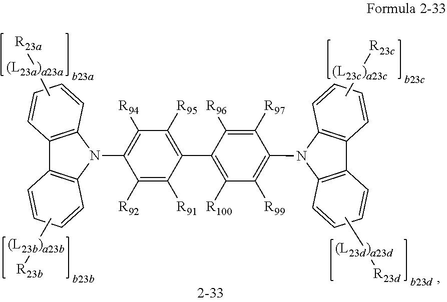
wherein, in Formulae 2-11, 2-21, and 2-31 to 2-33,
Xₐ, X_{b}, and X_{c} are each independently selected from C and N(R_{z}),
Xₐ, X_{b}, and X_{c} are not N(R_{z}) simultaneously,
L₂₁ₐ to L₂₁ₑ, L_{21g}, L₂₂ₐ to L_{22f}, and L₂₃ₐ to L_{23d} are each independently the same as described in connection with L₂₁ in Formula 2,
a21a to a21e, a21g, a22a to a22f, and a23a to a23d are each independently the same as described in connection with a21 in Formula 2,
R_{21b} to R_{21f}, R₂₂ₐ to R₂₂ₑ, and R₂₃ₐ to R_{23d} are each independently the same as described in connection with R₂₁ in Formula 2,
b21b, b21e, b22a, b22c, b22d, and b23a to b23d are each independently the same as described in connection with b21 in Formula 2,
b21c, b21d, and b22b are each independently the same as described in connection with b23 in Formula 2, and
R₉₁ to R₁₀₀, Rₓ, R_{y}, and R_{z} are each independently selected from hydrogen, deuterium, —F, —Cl, —Br, —I, a cyano group, a methyl group, an ethyl group, an n-propyl group, an iso-propyl group, an n-butyl group, an iso-butyl group, a sec-butyl group, a tert-butyl group, a phenyl group, a biphenyl group, a terphenyl group, a naphthyl group, a fluorenyl group, a pyridinyl group, a pyrazinyl group, a pyrimidinyl group, a quinolinyl group, an isoquinolinyl group, a carbazolyl group, a dibenzofuranyl group, and a dibenzothiophenyl group.

13. The composition of claim 1, wherein
the second compound is selected from Compounds H-1 to H-19:

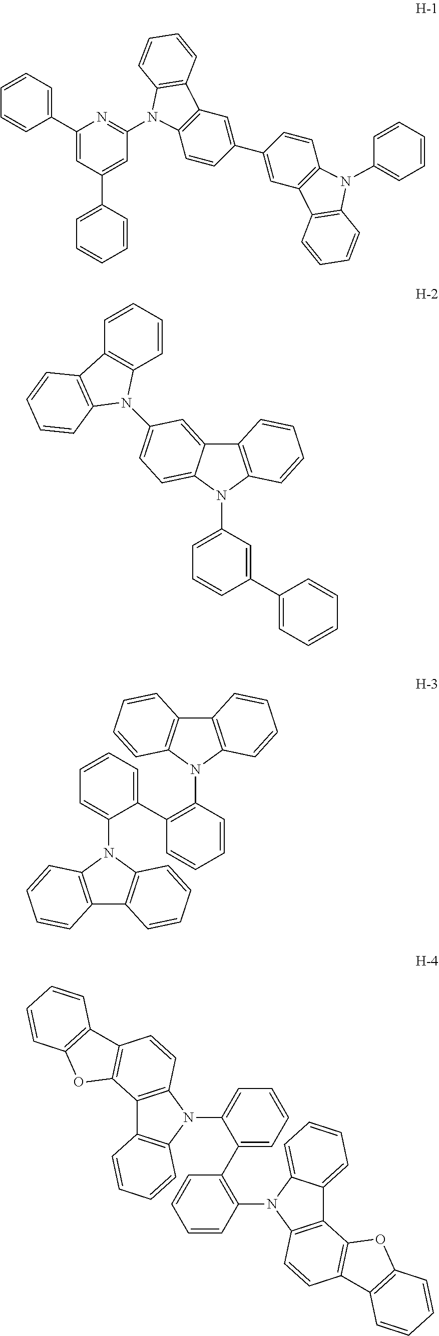 [SMILES: c1ccc(-c2cc(-c3ccccc3)nc(-n3c4ccccc4c4cc(-c5ccc6c(c5)c5ccccc5n6-c5ccccc5)ccc43)c2)cc1 ; c1ccc(-c2cccc(-n3c4ccccc4c4cc(-n5c6ccccc6c6ccccc65)ccc43)c2)cc1 ; c1ccc(-n2c3ccccc3c3ccccc32)c(-c2ccccc2-n2c3ccccc3c3ccccc32)c1 ; c1ccc(-n2c3ccccc3c3c4oc5ccccc5c4ccc32)c(-c2ccccc2-n2c3ccccc3c3c4oc5ccccc5c4ccc32)c1]

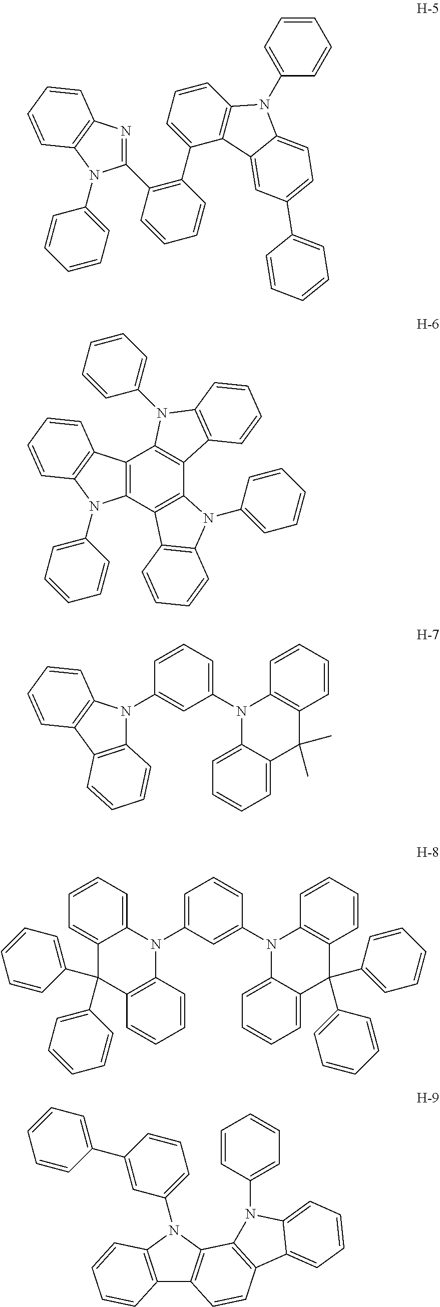

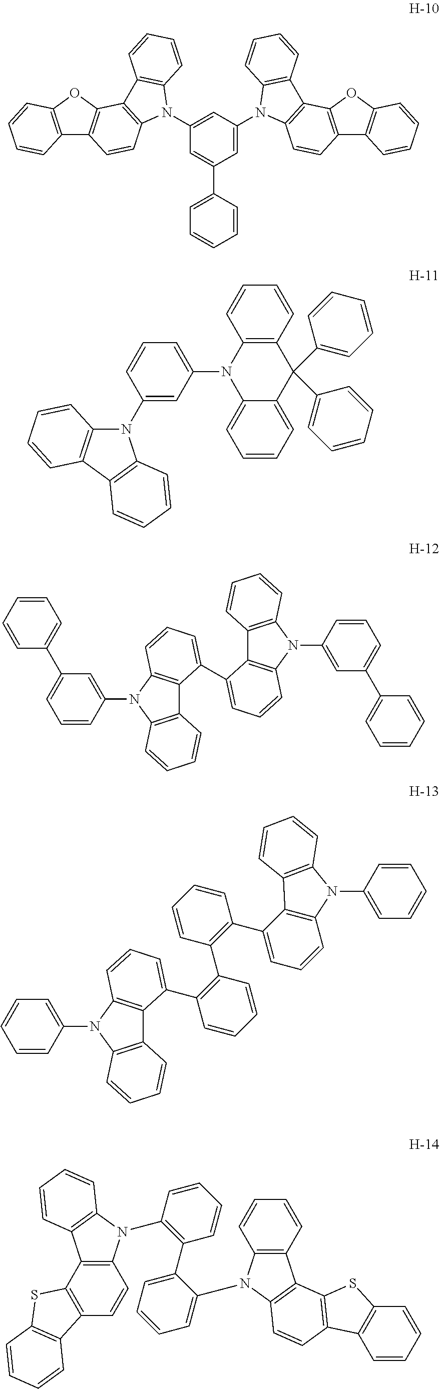 [SMILES: c1ccc(-c2cc(-n3c4ccccc4c4c5oc6ccccc6c5ccc43)cc(-n3c4ccccc4c4c5oc6ccccc6c5ccc43)c2)cc1 ; c1ccc(C2(c3ccccc3)c3ccccc3N(c3cccc(-n4c5ccccc5c5ccccc54)c3)c3ccccc32)cc1 ; c1ccc(-c2cccc(-n3c4ccccc4c4c(-c5cccc6c5c5ccccc5n6-c5cccc(-c6ccccc6)c5)cccc43)c2)cc1 ; c1ccc(-n2c3ccccc3c3c(-c4ccccc4-c4ccccc4-c4cccc5c4c4ccccc4n5-c4ccccc4)cccc32)cc1 ; c1ccc(-n2c3ccccc3c3c4sc5ccccc5c4ccc32)c(-c2ccccc2-n2c3ccccc3c3c4sc5ccccc5c4ccc32)c1]

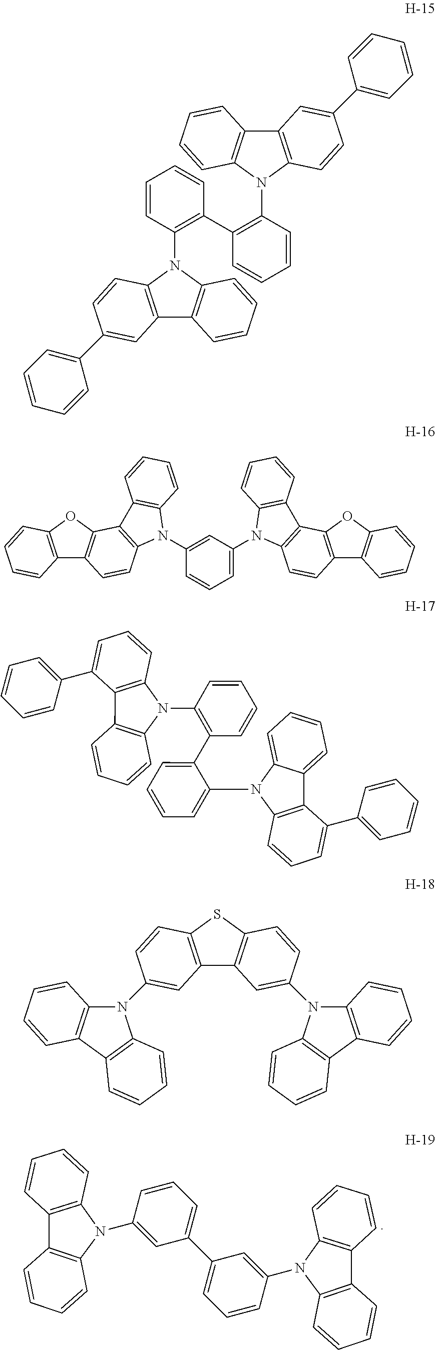 [SMILES: c1ccc(-c2ccc3c(c2)c2ccccc2n3-c2ccccc2-c2ccccc2-n2c3ccccc3c3cc(-c4ccccc4)ccc32)cc1 ; c1cc(-n2c3ccccc3c3c4oc5ccccc5c4ccc32)cc(-n2c3ccccc3c3c4oc5ccccc5c4ccc32)c1 ; c1ccc(-c2cccc3c2c2ccccc2n3-c2ccccc2-c2ccccc2-n2c3ccccc3c3c(-c4ccccc4)cccc32)cc1 ; c1ccc2c(c1)c1ccccc1n2-c1ccc2sc3ccc(-n4c5ccccc5c5ccccc54)cc3c2c1 ; c1cc(-c2cccc(-n3c4ccccc4c4ccccc43)c2)cc(-n2c3ccccc3c3ccccc32)c1]

14. The composition of claim 1, wherein
the third compound emits delayed fluorescence.

15. The composition of claim 1, wherein
the third compound is represented by one selected from Formulae 3 and 4: 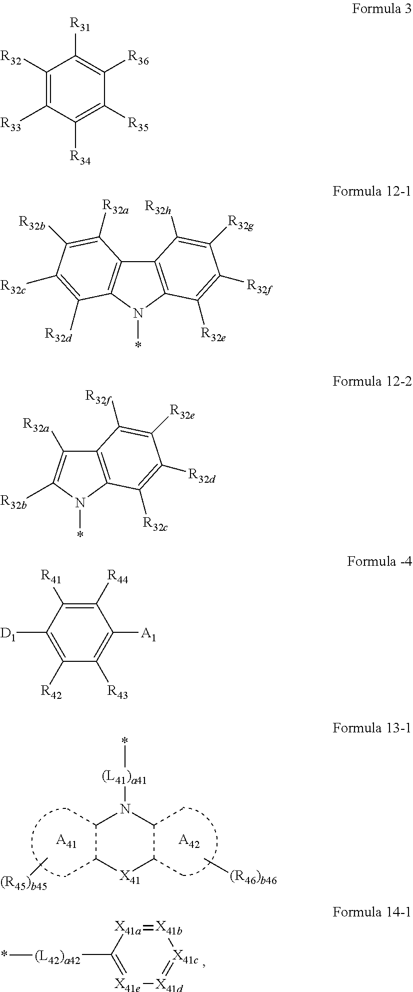
wherein, in Formulae 3, 4, 12-1, 12-2, 13-1, and 14-1,
R₃₁ to R₃₆ are each independently selected from a group represented by Formula 12-1, a group represented by Formula 12-2, hydrogen, deuterium, —F, —Cl, —Br, —I, a hydroxyl group, a cyano group, a substituted or unsubstituted C₁-C₆₀ alkyl group, a substituted or unsubstituted C₁-C₆₀ alkoxy group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ aryl alkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroaryl alkyl group,
at least one selected from R₃₁ to R₃₆ is a cyano group,
at least one selected from R₃₁ to R₃₆ is selected from a group represented by Formula 12-1 and a group represented by Formula 12-2,
D₁ is a group represented by Formula 13-1,
A₁ is a group represented by Formula 14-1,
X₄₁ is selected from a single bond, O, S, N(R₄₇), and C(R₄₇)(R₄₈),
A₄₁ and A₄₂ are each independently selected from a benzene group, a fluorene group, a carbazole group, a dibenzofuran group, a dibenzothiophene group, an indolofluorene group, an indolocarbazole group, an indolodibenzofuran group, an indolodibenzothiophene group, an indenofluorene group, an indenocarbazole group, an indenodibenzofuran group, an indenodibenzothiophene group, a benzofuranofluorene group, a benzofuranocarbazole group, a benzofuranodibenzofuran group, a benzofuranodibenzothiophene group, a benzothienofluorene group, a benzothienocarbazole group, a benzothienodibenzofuran group, and a benzothienodibenzothiophene group,
L₄₁ and L₄₂ are each independently selected from a substituted or unsubstituted C₅-C₃₀ carbocyclic group and a substituted or unsubstituted C₁-C₃₀ heterocyclic group,
a41 and a42 are each independently selected from 0, 1, 2, and 3,
X₄₁ₐ is N or C(R₄₁ₐ); X_{41b} is N or C(R_{41b}); X_{41c} is N or C(R_{41c}); X_{41d} is N or C(R_{41d}); and X₄₁ₑ is N or C(R₄₁ₑ), wherein at least one selected from X₄₁ₐ to X₄₁ₑ is N,
R₃₂ₐ to R₃₂ₕ, R₄₁ to R₄₈, and R₄₁ₐ to R₄₁ₑ are each independently selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted alkoxy group, a substituted or unsubstituted C₃-C₁₀ cycloalkyl group, a substituted or unsubstituted heterocycloalkyl group, a substituted or unsubstituted C₃-C₁₀ cycloalkenyl group, a substituted or unsubstituted heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ aryl alkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroaryl alkyl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₄)(Q₅), and —B(Q₆)(Q₇),
b45 and b46 are independently selected from 1, 2, 3, 4, 5, 6, 7, and 8,
Q₁ to Q₇ are each independently selected from hydrogen, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and
* indicates a binding site to a neighboring atom.

16. The composition of claim 15, wherein
one, two, or three selected from R₃₁ to R₃₆ are a cyano group, and
one, two, three, four, or five selected from R₃₁ to R₃₆ are selected from a group represented by Formula 12-1 and a group represented by Formula 12-2.

17. The composition of claim 1, wherein
the third compound is represented by one selected from Formulae 3-1 to 3-5: 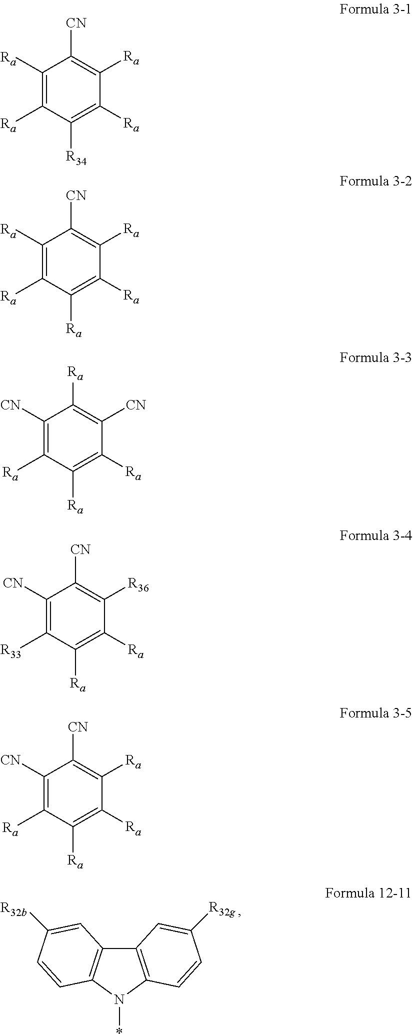
wherein, in Formulae 3-1 to 3-5 and 12-1 and 12-2,
Rₐ is a group represented by Formula 12-11,
R₃₃, R₃₄, and R₃₆ are each independently selected from hydrogen, deuterium, —F, —Cl, —Br, —I, a hydroxyl group, a C₁-C₁₀ alkyl group, and a C₁-C₁₀ alkoxy group,
R_{32b} and R_{32g} are each independently selected from hydrogen, deuterium, —F, —Cl, —Br, —I, a hydroxyl group, a C₁-C₁₀ alkyl group, a C₁-C₁₀ alkoxy group, a C₆-C₃₀ aryl group, and a C₁-C₃₀ heteroaryl group, and
* indicates a binding site to a neighboring atom.

18. The composition of claim 1, wherein
the third compound is selected from Compounds D-1 to D-23:

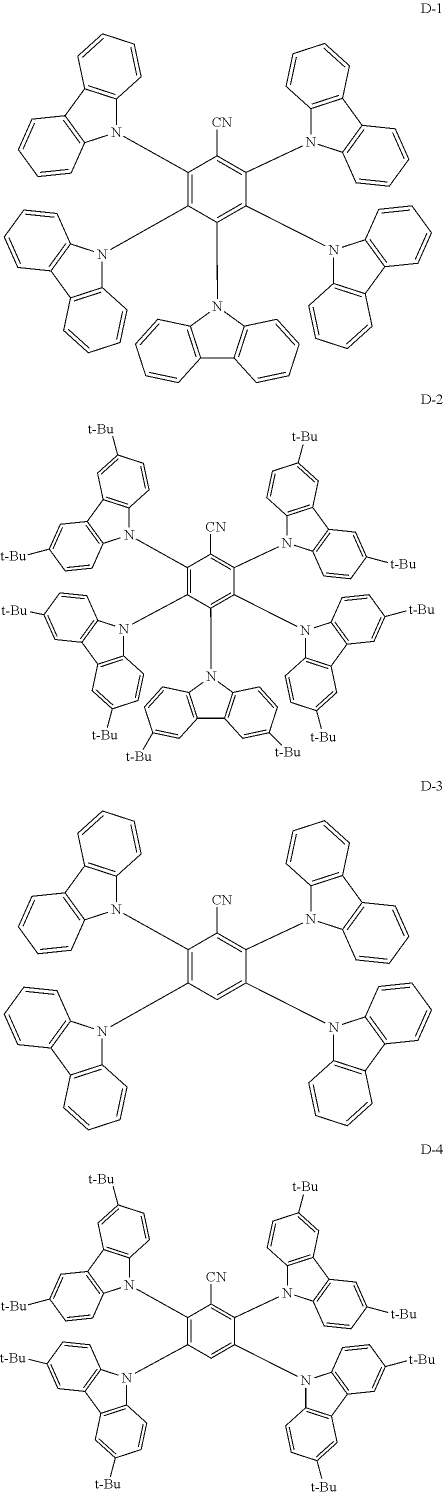

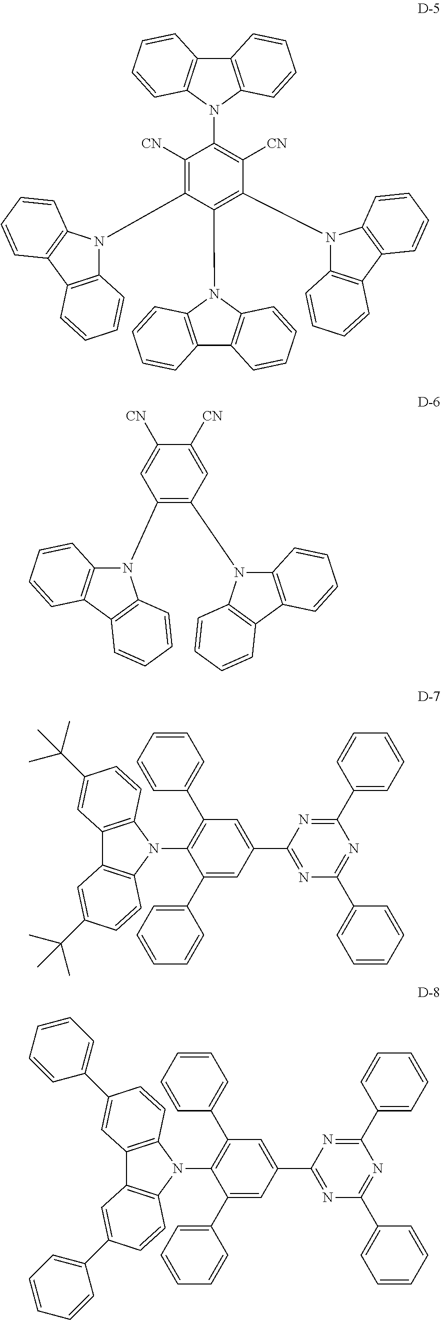

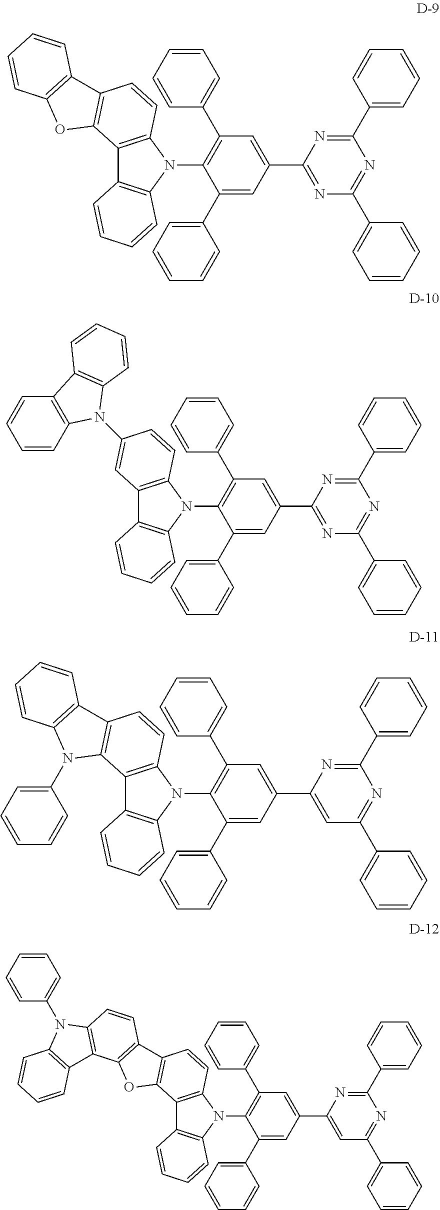 [SMILES: c1ccc(-c2nc(-c3ccccc3)nc(-c3cc(-c4ccccc4)c(-n4c5ccccc5c5c6oc7ccccc7c6ccc54)c(-c4ccccc4)c3)n2)cc1 ; c1ccc(-c2nc(-c3ccccc3)nc(-c3cc(-c4ccccc4)c(-n4c5ccccc5c5cc(-n6c7ccccc7c7ccccc76)ccc54)c(-c4ccccc4)c3)n2)cc1 ; c1ccc(-c2cc(-c3cc(-c4ccccc4)c(-n4c5ccccc5c5c4ccc4c6ccccc6n(-c6ccccc6)c45)c(-c4ccccc4)c3)nc(-c3ccccc3)n2)cc1 ; c1ccc(-c2cc(-c3cc(-c4ccccc4)c(-n4c5ccccc5c5c6oc7c(ccc8c7c7ccccc7n8-c7ccccc7)c6ccc54)c(-c4ccccc4)c3)nc(-c3ccccc3)n2)cc1]

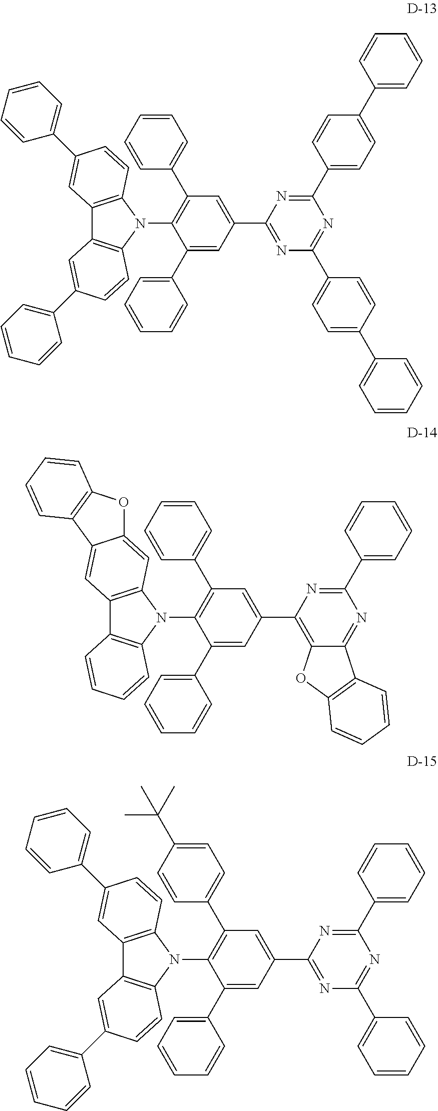 [SMILES: c1ccc(-c2ccc(-c3nc(-c4ccc(-c5ccccc5)cc4)nc(-c4cc(-c5ccccc5)c(-n5c6ccc(-c7ccccc7)cc6c6cc(-c7ccccc7)ccc65)c(-c5ccccc5)c4)n3)cc2)cc1 ; c1ccc(-c2nc(-c3cc(-c4ccccc4)c(-n4c5ccccc5c5cc6c(cc54)oc4ccccc46)c(-c4ccccc4)c3)c3oc4ccccc4c3n2)cc1 ; CC(C)(C)c1ccc(-c2cc(-c3nc(-c4ccccc4)nc(-c4ccccc4)n3)cc(-c3ccccc3)c2-n2c3ccc(-c4ccccc4)cc3c3cc(-c4ccccc4)ccc32)cc1]

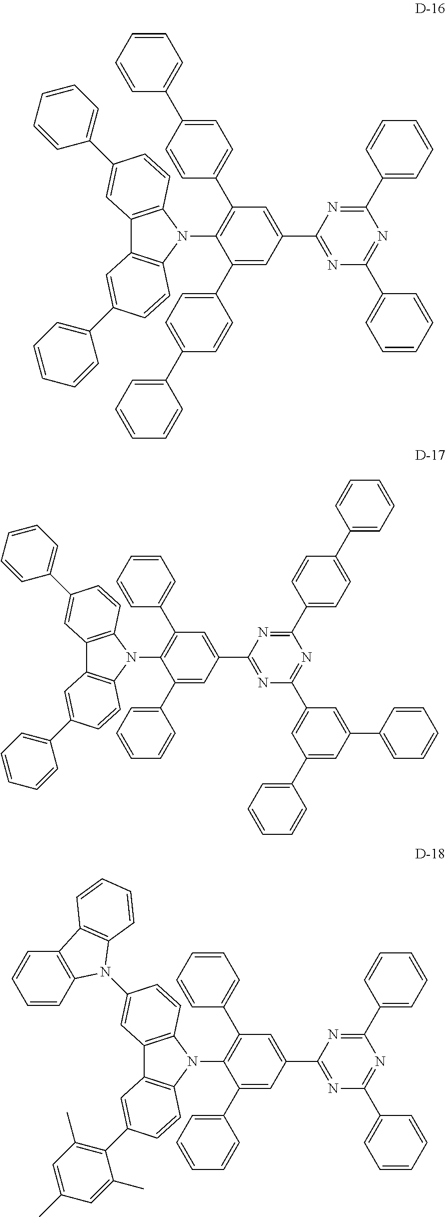 [SMILES: c1ccc(-c2ccc(-c3cc(-c4nc(-c5ccccc5)nc(-c5ccccc5)n4)cc(-c4ccc(-c5ccccc5)cc4)c3-n3c4ccc(-c5ccccc5)cc4c4cc(-c5ccccc5)ccc43)cc2)cc1 ; c1ccc(-c2ccc(-c3nc(-c4cc(-c5ccccc5)cc(-c5ccccc5)c4)nc(-c4cc(-c5ccccc5)c(-n5c6ccc(-c7ccccc7)cc6c6cc(-c7ccccc7)ccc65)c(-c5ccccc5)c4)n3)cc2)cc1 ; Cc1cc(C)c(-c2ccc3c(c2)c2cc(-n4c5ccccc5c5ccccc54)ccc2n3-c2c(-c3ccccc3)cc(-c3nc(-c4ccccc4)nc(-c4ccccc4)n3)cc2-c2ccccc2)c(C)c1]

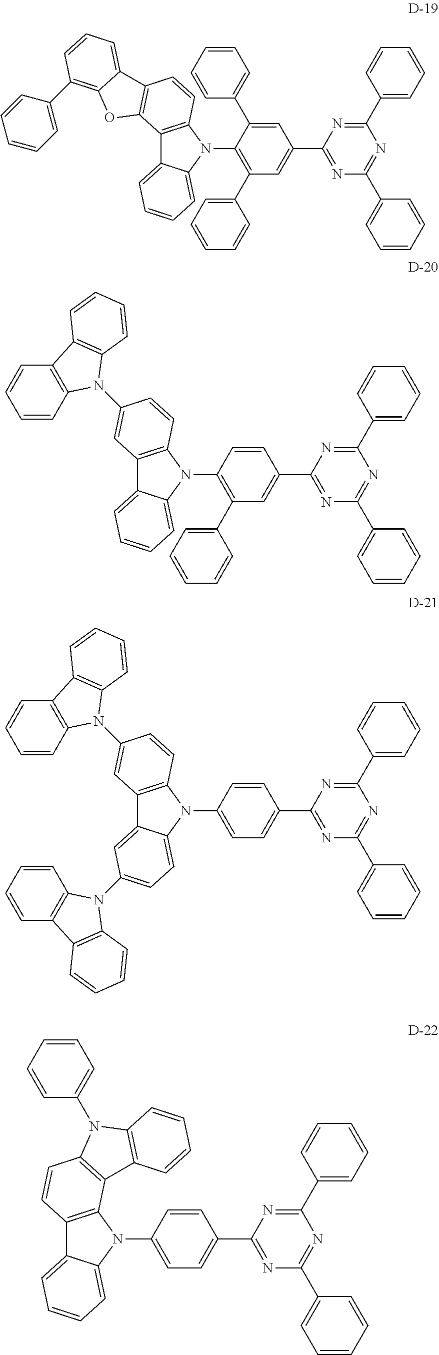 [SMILES: c1ccc(-c2nc(-c3ccccc3)nc(-c3cc(-c4ccccc4)c(-n4c5ccccc5c5c6oc7c(-c8ccccc8)cccc7c6ccc54)c(-c4ccccc4)c3)n2)cc1 ; c1ccc(-c2nc(-c3ccccc3)nc(-c3ccc(-n4c5ccccc5c5cc(-n6c7ccccc7c7ccccc76)ccc54)c(-c4ccccc4)c3)n2)cc1 ; c1ccc(-c2nc(-c3ccccc3)nc(-c3ccc(-n4c5ccc(-n6c7ccccc7c7ccccc76)cc5c5cc(-n6c7ccccc7c7ccccc76)ccc54)cc3)n2)cc1 ; c1ccc(-c2nc(-c3ccccc3)nc(-c3ccc(-n4c5ccccc5c5ccc6c(c7ccccc7n6-c6ccccc6)c54)cc3)n2)cc1]

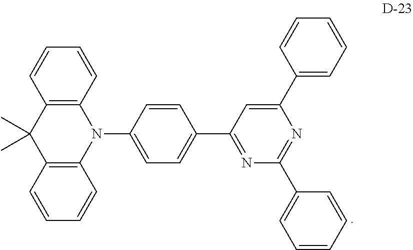 [SMILES: CC1(C)c2ccccc2N(c2ccc(-c3cc(-c4ccccc4)nc(-c4ccccc4)n3)cc2)c2ccccc21]

19. The composition of claim 1, wherein
the composition does not include a transition metal-containing organometallic compound.

20. A thin film comprising the composition of claim 1.

21. An organic light-emitting device comprising:
a first electrode;
a second electrode; and
an organic layer disposed between the first electrode and the second electrode,
wherein the organic layer comprises the thin film of claim 20.

22. The organic light-emitting device of claim 21, wherein
the thin film is an emission layer.
